(19) United States
(12) Patent Application Publication
(10) Pub. No.: US 2024/0405765 A1
(43) Pub. Date: Dec. 5, 2024

(54) GATE DRIVE CIRCUIT, ELECTRIC POWER CONVERSION DEVICE

(71) Applicant: ROHM CO., LTD., Kyoto-shi (JP)

(72) Inventor: Takayuki ATAGO, Kyoto-shi (JP)

(21) Appl. No.: 18/794,044

(22) Filed: Aug. 5, 2024

Related U.S. Application Data
(63) Continuation of application No. PCT/JP2023/003387, filed on Feb. 2, 2023.

(30) Foreign Application Priority Data
Feb. 18, 2022 (JP) 2022-023414

(51) Int. Cl. H03K 17/16; H02M 1/08

(52) U.S. Cl. CPC H03K 17/16; H02M 1/08

(57) ABSTRACT

For instance, a gate drive circuit includes a gate driving circuit configured to generate a gate drive signal for a power device (a power module), and a drive capability switching circuit configured to stepwisely increase gate drive capability of the gate driving circuit during at least one of turn-on transition period and turn-off transition period of the power device.

### CROSS-REFERENCE TO RELATED APPLICATIONS

This application is a continuation under 35 U.S.C. § 120 of PCT/JP2023/003387 filed on Feb. 2, 2023, which is incorporated herein by reference, and which claimed priority to Japanese Application No. 2022-023414, filed Feb. 18, 2022. The present application likewise claims priority under 35 U.S.C. § 119 to Japanese Application No. 2022-023414, filed Feb. 18, 2022, the entire content of which is also incorporated herein by reference.

### TECHNICAL FIELD

The present disclosure relates to a gate drive circuit and an electric power conversion device using the same.

### BACKGROUND ART

A gate drive circuit to drive a power device is mounted in various applications (such as a switching power supply and a motor driver).

Further, as an example of a conventional technique related to the above, there is Patent Document 1.

### LIST OF CITATIONS

### Patent Literature

Patent Document 1: JP-A-2017-183979

### BRIEF DESCRIPTION OF DRAWINGS

FIG. 1 is a diagram illustrating one structure example of an electric power conversion device.

FIG. 2 is a diagram illustrating oscillation behavior of a power module.

FIG. 3 is a diagram illustrating a first example (BAD) of a device layout.

FIG. 4 is a diagram illustrating a second example (GOOD) of the device layout.

FIG. 5 is a diagram illustrating a first example (BAD) of a gate wiring layout.

FIG. 6 is a diagram illustrating a second example (GOOD) of the gate wiring layout.

FIG. 7 is a diagram illustrating an example in which an internal gate resistor is inserted for each chip.

FIG. 8 is a diagram illustrating an example in which the internal gate resistor is inserted adjacent to the chip.

FIG. 9 is a diagram illustrating an example of turn-off behavior.

FIG. 10 is a diagram illustrating basic concept of oscillation countermeasures in a gate drive circuit.

FIG. 11 is a diagram illustrating a first embodiment of the gate drive circuit.

FIG. 12 is a diagram illustrating a conventional turn-off behavior.

FIG. 13 is a diagram illustrating the turn-off behavior of the first embodiment.

FIG. 14 is a diagram illustrating relationship between a threshold voltage at which gate drive capability is switched and oscillation amplitude.

FIG. 15 is a diagram illustrating relationship between the threshold voltage at which gate drive capability is switched and a VDS surge.

FIG. 16 is a diagram illustrating a second embodiment of the gate drive circuit.

FIG. 17 is a diagram illustrating a third embodiment of the gate drive circuit.

FIG. 18 is a diagram illustrating a fourth embodiment of the gate drive circuit.

FIG. 19 is a diagram illustrating turn on/off behavior in the fourth embodiment.

FIG. 20 is a diagram illustrating a fifth embodiment of the gate drive circuit.

FIG. 21 is a diagram illustrating the turn on/off behavior in the fifth embodiment.

FIG. 22 is a diagram illustrating a sixth embodiment of the gate drive circuit.

FIG. 23 is a diagram schematically illustrating the turn-off behavior.

FIG. 24 is a perspective view illustrating a second structure example of the power module.

FIG. 25 is a plan view illustrating the second structure example of the power module.

FIG. 26 is a partial plan view illustrating the second structure example of the power module.

FIG. 27 is a partial enlarged plan view illustrating the second structure example of the power module.

FIG. 28 is a partial enlarged plan view illustrating the second structure example of the power module.

FIG. 29 is a cross-sectional view taken along line XXIX-XXIX in FIG. 25.

FIG. 30 is a perspective view illustrating a first structure example of the power module.

FIG. 31 is a partial plan view illustrating the first structure example of the power module.

FIG. 32 is a cross-sectional view taken along line XXXII-XXXII in FIG. 31.

FIG. 33 is a cross-sectional view taken along line XXXIII-XXXIII in FIG. 31.

FIG. 34 is a cross-sectional view taken along line XXXIV-XXXIV in FIG. 31.

FIG. 35 is a cross-sectional view taken along line XXXV-XXXV in FIG. 31.

FIG. 36 is a cross-sectional view taken along line XXXVI-XXXVI in FIG. 31.

FIG. 37 is a plan view illustrating a third structure example of the power module.

FIG. 38 is a partial plan view illustrating the third structure example of the power module.

FIG. 39 is a partial enlarged plan view illustrating the third structure example of the power module.

FIG. 40 is a partial enlarged plan view illustrating the third structure example of the power module.

FIG. 41 is a plan view illustrating a structure example of a first semiconductor device and a second semiconductor device in the first to third structure examples of the power module.

FIG. 42 is a cross-sectional view taken along line XLII-XLII in FIG. 41.

FIG. 43 is a plan view illustrating a structure example of the power device in the structure example illustrated in FIG. 8.

FIG. 44 is a cross-sectional view taken along line XLIV-XLIV in FIG. 43.

FIG. 45 is a plan view illustrating a layout of a gate electrode and a source electrode of the structure example of the power device in the structure example illustrated in FIG. 8.

FIG. 46 is a plan view illustrating a layout of a first principal surface of the structure example of the power device in the structure example illustrated in FIG. 8.

FIG. 47 is an electrical circuit diagram illustrating a connection configuration of the gate electrode and gate resistor of the structure example of the power device in the structure example illustrated in FIG. 8.

FIG. 48 is a diagram illustrating a vehicle in which the electric power conversion device is mounted.

### DESCRIPTION OF EMBODIMENTS

### <Electric Power Conversion Device>

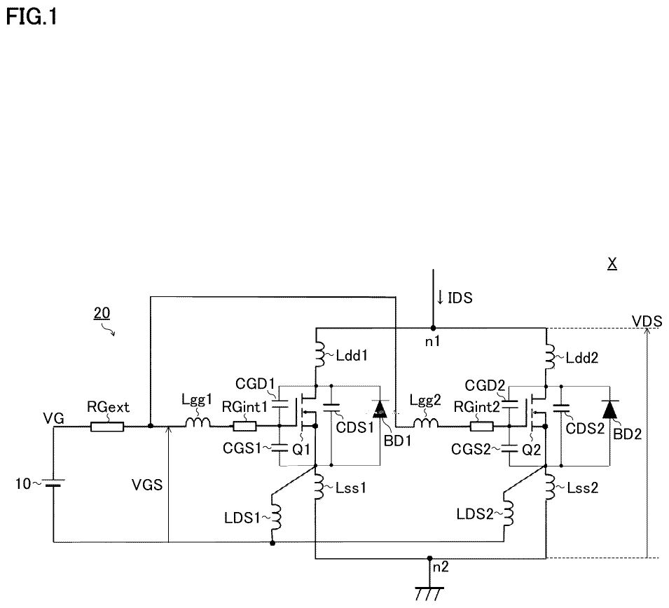

FIG. 1 is a diagram illustrating one structure example of an electric power conversion device. An electric power conversion device X of this structure example includes a gate drive circuit 10 and a power module 20. As the electric power conversion device X, there is a switching power supply, a motor drive circuit, or the like.

The gate drive circuit 10 generates a gate drive signal VG of the power module 20 (accordingly a gate-source voltage VGS of each of power devices Q1 and Q2). Note that an external gate resistor RGext may be connected between the gate drive circuit 10 and the power module 20.

The power module 20 includes at least one power device (the two power devices Q1 and Q2 in this diagram). For instance, the power devices Q1 and Q2 may each be an N-channel metal insulator semiconductor field effect transistor (NMISFET) including an N-channel metal oxide semiconductor field effect transistor (NMOSFET) formed on an SiC substrate. The power devices Q1 and Q2 have a withstand voltage of 100 V or more and 3,500 V or less, for example.

A source terminal (i.e., corresponding to a first main terminal) of each of the power devices Q1 and Q2 is connected to a node n2 (e.g., a ground node). Floating inductances Lss1 and Lss2 are attached between the node n2 and source terminals of the power devices Q1 and Q2, respectively.

A drain terminal (i.e., corresponding to a second main terminal) of each of the power devices Q1 and Q2 is connected to a node n1 (e.g., a power supply node). Floating inductances Ldd1 and Ldd2 are attached between the node n1 and drain terminals of the power devices Q1 and Q2, respectively.

In addition, if the power devices Q1 and Q2 have a source sense terminal (i.e., a gate driving source terminal connected not to the node n2 but to only the gate drive circuit 10), floating inductances LDS1 and LDS2 are attached between the gate drive circuit 10 and the source sense terminals of the power devices Q1 and Q2, respectively.

A gate terminal (i.e., corresponding to a control terminal) of each of the power devices Q1 and Q2 is connected to an application terminal of the gate drive signal VG (i.e., an output terminal of the gate drive circuit 10). Note that a floating inductance Lgg1 and an internal gate resistor RGint1 are attached between a gate terminal of the power device Q1 and the application terminal of the gate drive signal VG. Similarly, a floating inductance Lgg2 and an internal gate resistor RGint2 are attached between a gate terminal of the power device Q2 and the application terminal of the gate drive signal VG. Note that it is arbitrary to dispose the internal gate resistors RGint1 and RGint2 inside the power module 20.

In addition, stray capacitances CGS1, CGD1, and CDS1 are attached between gate and source, between gate and drain, and between drain and source of the power device Q1, respectively. Similarly, stray capacitances CGS2, CGD2, and CDS2 are attached between gate and source, between gate and drain, and between drain and source of the power device Q2, respectively.

Further, body diodes BD1 and BD2 are attached to the power devices Q1 and Q2, respectively, in each of which a drain terminal is a cathode while a source terminal is an anode.

Here, if fast switching performance of each of the power devices Q1 and Q2 is improved, switching loss can be largely reduced. Therefore, in order to reduce total loss of the electric power conversion device X, it is important to design the power module 20 so that the fast switching performances of the power devices Q1 and Q2 (accordingly advantages of SiC device) can be maximized. In addition, design of not only the power module 20 but also the external gate resistor RGext disposed adjacent to the gate drive circuit 10 is important.

Note that it may be possible to use an insulated gate bipolar transistor (IGBT) instead of SiC-NMISFET as the power devices Q1 and Q2. In this case, in the above description, the “source” as the first main terminal of each of the power devices Q1 and Q2 should be read as “emitter”, and the “drain” as the second main terminal of each of the power devices Q1 and Q2 should be read as “collector”.

<Consideration about Self-Oscillation of Power Module>

First, design of the power module 20 is considered. If the power module 20 is a high output module, a plurality of power devices (the two power devices Q1 and Q2 in FIG. 1) are used in parallel. An imbalance of currents flowing in the power devices Q1 and Q2 is apt to occur during switching transition. Oscillation of the power module 20 is caused by this imbalance of currents. In other words, the imbalance of currents is one of root causes.

Next, the oscillation waveform is considered. If a drain-source voltage VDS of the power module 20 increases, oscillation may occur. Note that the oscillation has a frequency of approximately a few hundred MHz.

Further, importance of module design is considered. In order to suppress the oscillation of the power module 20, it is necessary to minimize the imbalance of currents described above.

<Consideration about Module Design>

First, current paths of the power module 20 (source/drain) are considered. If the floating inductances Ldd1 and Lss1 attached to the power device Q1 are different from the floating inductances Ldd2 and Lss2 attached to the power device Q2, respectively, i.e., if Ldd1≠Ldd2 and Lss1≠Lss2 hold, currents respectively flowing in the power devices Q1 and Q2 become imbalanced. In particular, it is necessary to design inductances of main circuit loops with good balance.

Next, impedance adjustment of the gate drive circuit 10 is considered. If the plurality of the power devices Q1 and Q2 are connected in parallel, as described above, oscillation of the power module 20 may occur during switching transition due to the imbalance of currents flowing in the power devices Q1 and Q2. In order to avoid this imbalance of currents, it is necessary to insert the external gate resistor RGext (or a ferrite bead), so as to adjust impedance of the gate drive circuit 10.

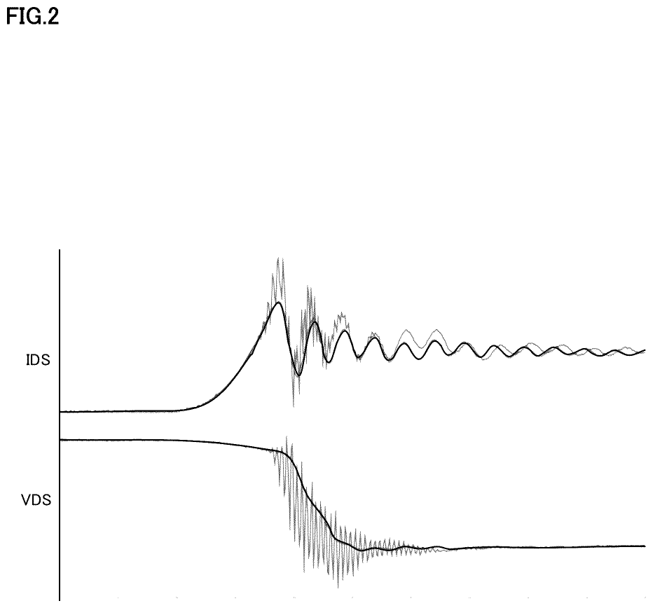

FIG. 2 is a diagram illustrating oscillation behavior of the power module 20 (here, behavior when turning on), in which a drain-source current IDS and the drain-source voltage VDS are shown from top to bottom. In this diagram, there are behavior (black line) when the currents flowing in the power devices Q1 and Q2 are balanced, and behavior (gray line) when they are imbalanced, which are shown in an overlapping manner. Note that the drain-source current IDS of each of the power devices Q1 and Q2 is 10 A or more and 300 A or less, for example.

As described above, if the plurality of the power devices Q1 and Q2 are connected in parallel, a layout of current paths in the power module 20 may be imbalanced. If such an imbalance occurs, the drain-source current IDS and the drain-source voltage VDS are apt to oscillate. For this reason, it is necessary to sufficiently attend a chip layout and a frame layout inside the power module 20.

### <Oscillation Countermeasures for Power Module>

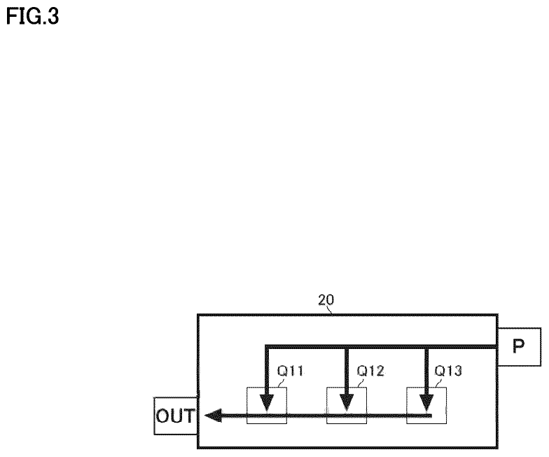

FIG. 3 is a diagram illustrating a first example (BAD) of the device layout. In order to avoid the imbalance of currents (accordingly oscillation of the power module 20) described above, positions of electrodes (a power supply electrode P and an output electrode OUT in this diagram) of the power module 20, and the chip layout of power devices Q11 to Q13 (e.g., SiC-NMISFETs) are important.

In this structure example, the power supply electrode P is disposed at a first side (right side in this diagram) of the power module 20, and the output electrode OUT is disposed at a second side (left side in this diagram) opposed to the first side of the power module 20. The power devices Q11 to Q13 are arranged in a row along a direction perpendicular to the first side of the power module 20.

In this structure example, there is a difference among lengths of current paths from the power supply electrode P to the power devices Q11 to Q13, respectively, and among lengths of current paths from the power devices Q11 to Q13 to the output electrode OUT, respectively (see thick arrow lines in the diagram). This difference can cause a current imbalance.

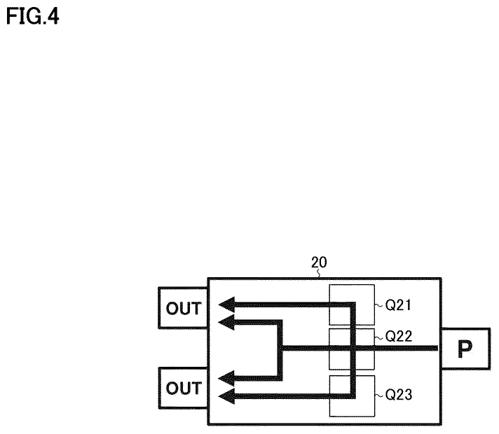

FIG. 4 is a diagram illustrating a second example (GOOD) of the device layout. In this structure example, the power supply electrode P is disposed at the first side (the right side in this diagram) of the power module 20, and a plurality of the output electrodes OUT are arranged side by side at the second side (the left side in this diagram) opposed to the first side. Power devices Q21 to Q23 (e.g., SiC-NMISFETs) are disposed in a row along the direction parallel to the first side and the second side of the power module 20.

In this structure example, it is possible to equalize lengths of current paths from the power supply electrode P to the power devices Q21 to Q23, respectively, and lengths of current paths from the power devices Q21 to Q23 to the output electrode OUT, respectively, as much as possible (see thick arrow lines in the diagram). Therefore, it is possible to suppress the current imbalance described above, and accordingly the oscillation of the power module 20.

In particular, as the floating inductances attached to the sources of the power devices Q21 to Q23 are larger, they affect more the oscillation of the power module 20. For this reason, when designing the power module 20, it is desirable to equalize wires connected to the sources of the power devices Q21 to Q23, respectively (e.g., the current paths from the power devices Q21 to Q23 to the output electrode OUT, respectively) as much as possible.

In addition, it is desirable that the wires connected to the sources of the power devices Q21 to Q23 are thick and short as much as possible. Note that the inductance of a wire can be calculated by the following equation (1), for example. In this equation, L is inductance (H) of the wire, l is length (m) of the wire, a is diameter (m) of the wire, and u is permeability (H/m) of the wire.

L=(μl/2π)×(log(2l/a)−1) (1)

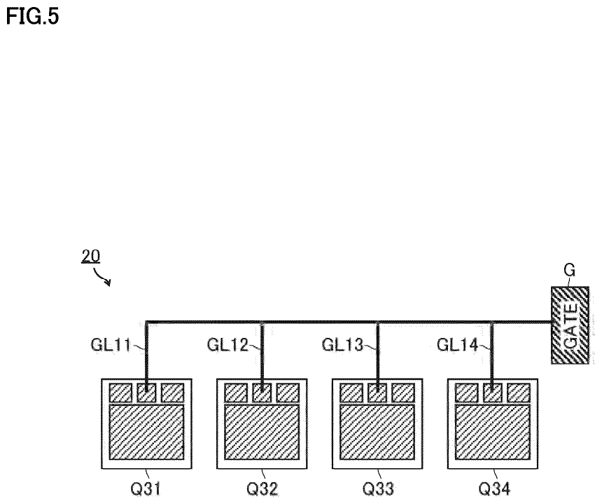

FIG. 5 is a diagram illustrating a first example (BAD) of a gate wiring layout. In this structure example, power devices Q31 to Q34 (e.g., SiC-NMISFETs) are arranged in series with respect to a gate electrode G of the power module 20 (i.e., an external control terminal). Further, gate wirings GL11 to GL14 are respectively laid among the gate terminals of the power devices Q31 to Q34 and the gate electrode G.

In this structure example, there are ON/OFF timing differences among the power devices Q31 to Q34, depending on distances between the gate electrode G and the power devices Q31 to Q34, respectively (i.e., a gate wiring length, a control wiring length). With reference to this diagram, the power devices Q31 to Q34 are sequentially turned on or off, in such a manner that the power device Q34 that is closest to the gate electrode G is turned on (or off) first, and the power device Q31 that is farthest from the gate electrode G is turned on (or off) last. As a result, there occurs an imbalance of currents flowing in the power devices Q31 to Q34, which may cause the oscillation of the power module 20.

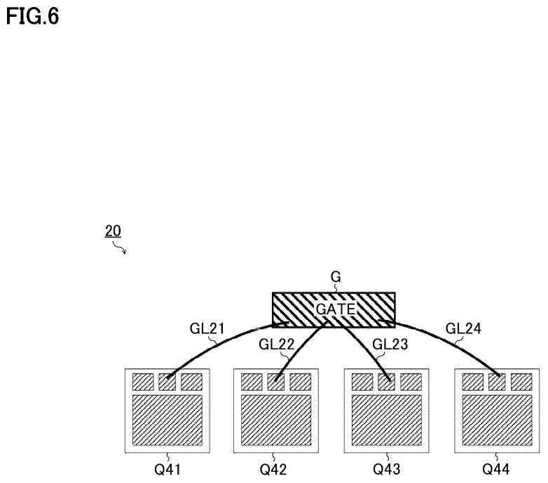

FIG. 6 is a diagram illustrating a second example (GOOD) of the gate wiring layout. In this structure example, power devices Q41 to Q44 (e.g., SiC-NMISFETs) are arranged in parallel with respect to the gate electrode G of the power module 20. Further, gate wirings GL21 to GL24 are laid between the gate electrode G and gate terminals of the power devices Q41 to Q44, respectively.

In this structure example, it is possible to equalize lengths of the gate wirings GL21 to GL24 as much as possible. Therefore, it is possible to suppress the current imbalance described above, and accordingly the oscillation of the power module 20.

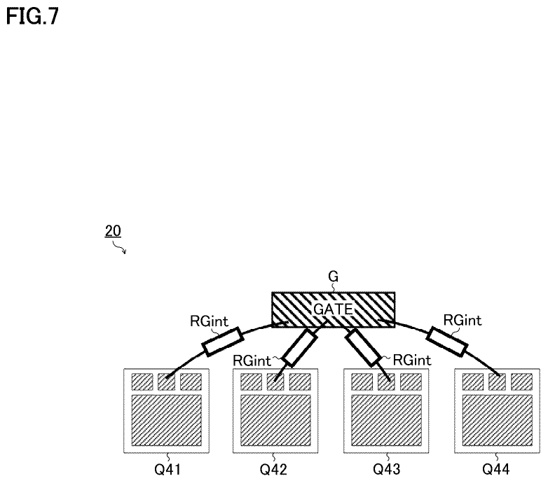

FIG. 7 is a diagram illustrating an example in which the internal gate resistor is inserted for each chip. In this structure example, similarly to the above FIG. 6, the power devices Q41 to Q44 are arranged in parallel with respect to the gate electrode G of the power module 20, and the gate wirings GL21 to GL24 are laid equally. Further, an internal gate resistor RGint is inserted for each of the gate wirings GL21 to GL24.

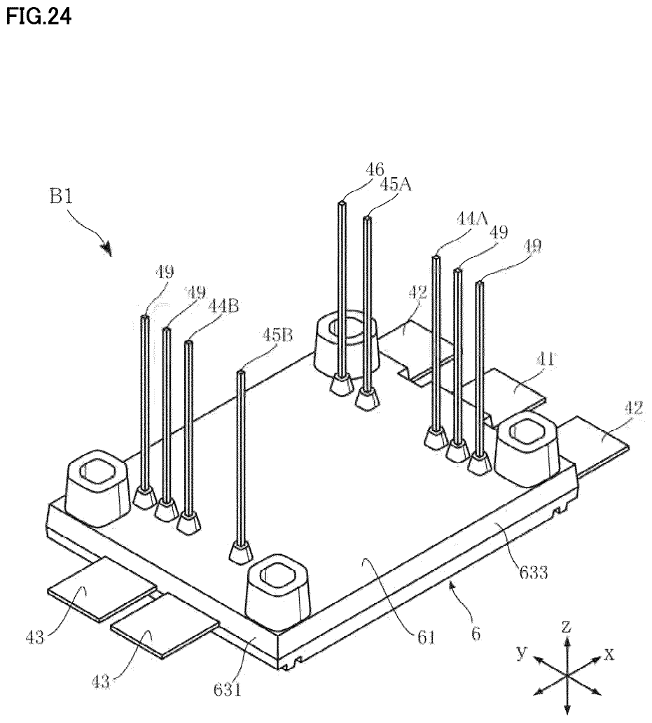

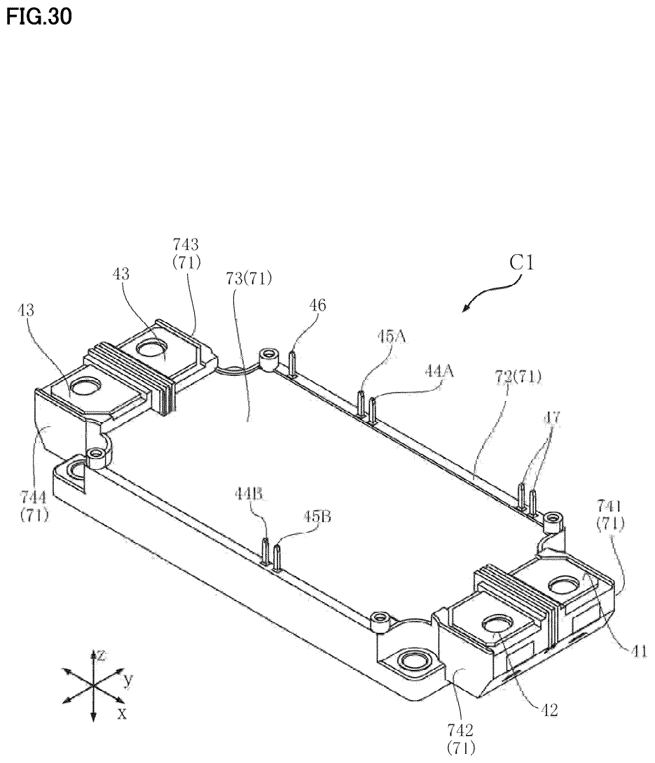

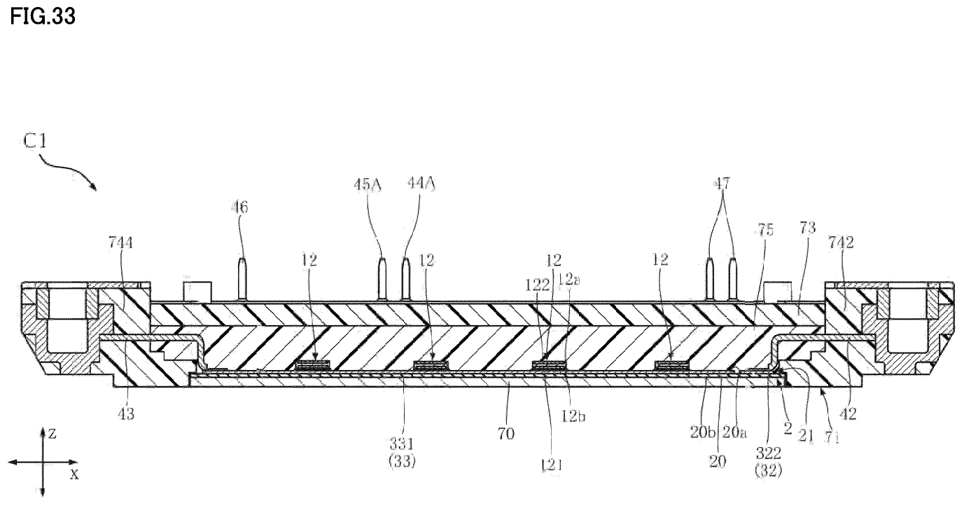

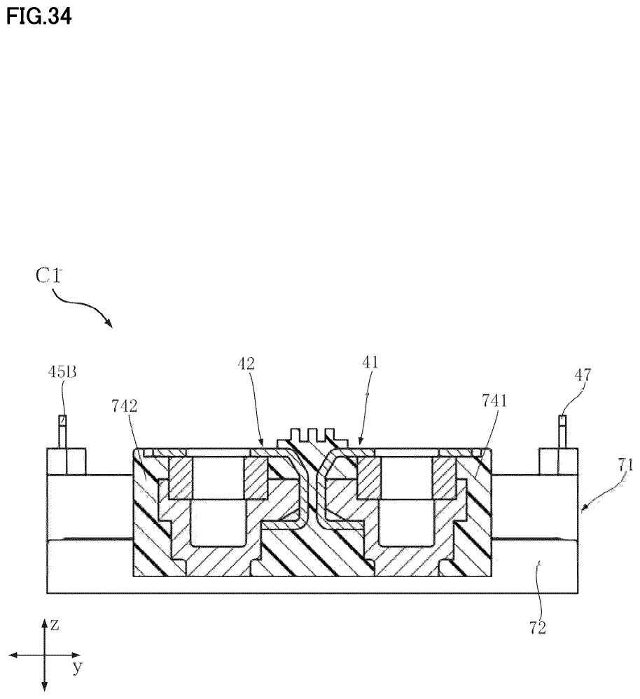

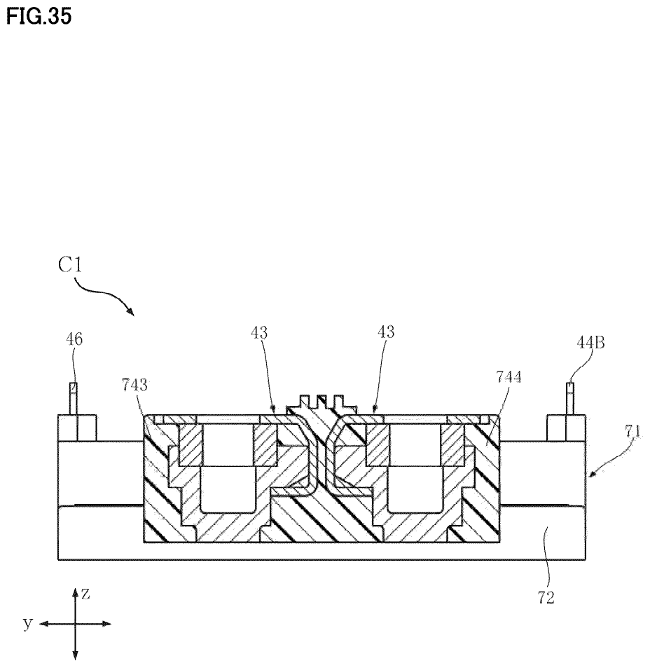

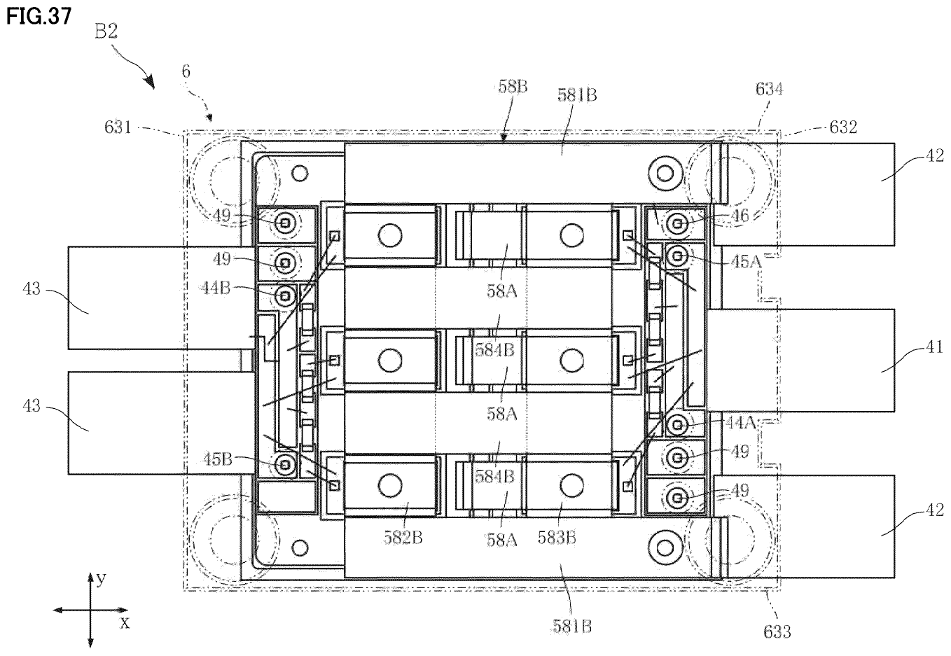

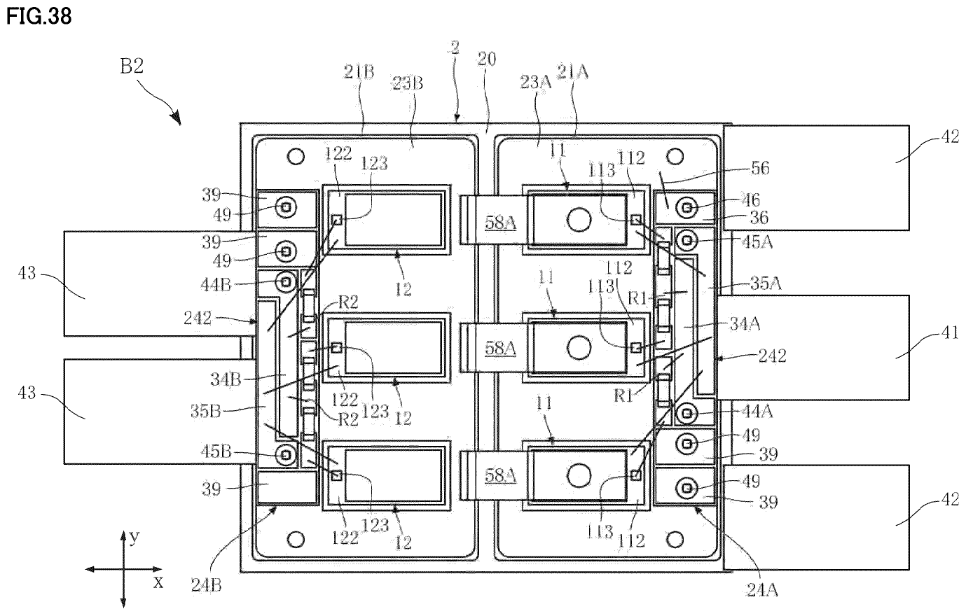

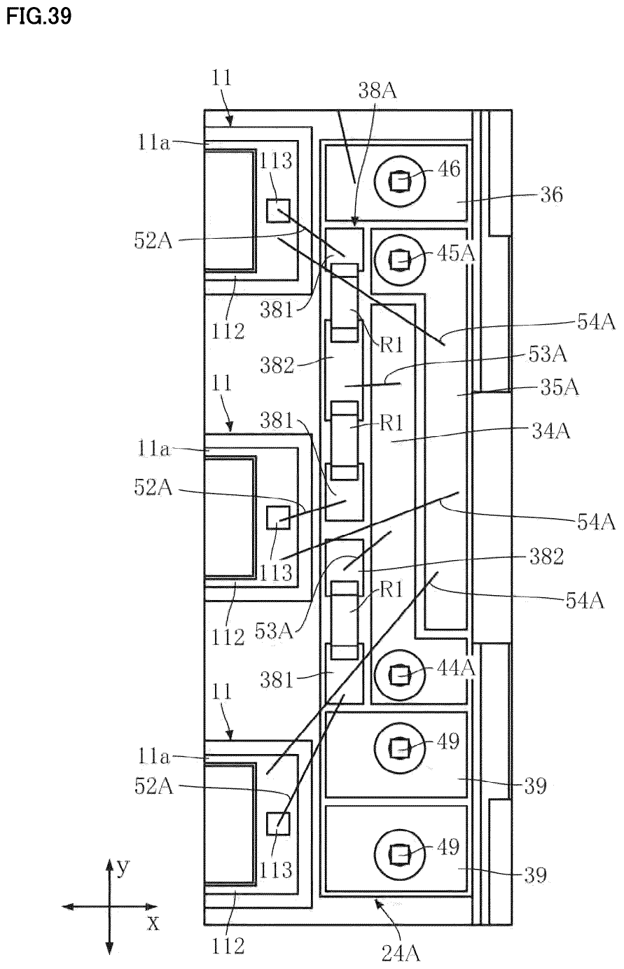

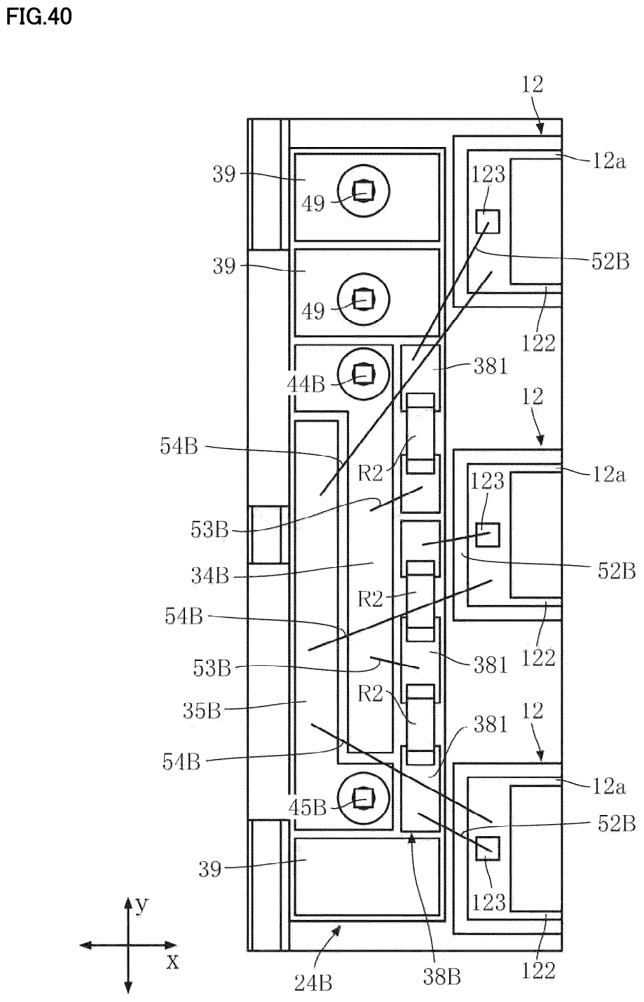

With reference to FIG. 24 to FIG. 40, there will be described later about a power module structure example (a first structure example) including the first example of the device layout illustrated in FIG. 3 and the first example of the gate wiring layout illustrated in FIG. 5, a power module structure example (a second structure example) including the second example of the device layout illustrated in FIG. 4 and the second example of the gate wiring layout illustrated in FIG. 6, and a power module structure example (a third structure example) including the example illustrated in FIG. 7 in which the internal gate resistor is inserted for each chip. The words and symbols defined in FIG. 24 to FIG. 40 and descriptions with reference to these diagrams are applied only to each structure example and are defined independently from other structure examples. Relation between each structure example and other structure examples will be appropriately described separately. Note that the second structure example is first illustrated in FIG. 24 to FIG. 29 for convenience sake of description. Next, the first structure example is illustrated in FIG. 30 to FIG. 36. Further, the third structure example is illustrated in FIG. 37 to FIG. 40.

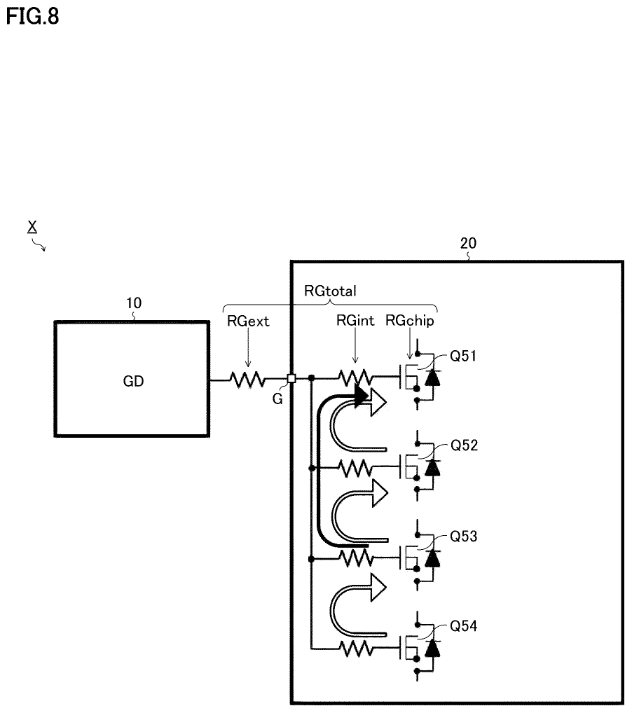

FIG. 8 is a diagram illustrating an example in which the internal gate resistor is inserted adjacent to the chip. In this structure example, similarly to the above FIG. 7, the internal gate resistor RGint is inserted for each of power devices Q51 to Q54 (e.g., SiC-MISFETs). Note that a total gate resistance RGtotal is expressed by the following equation (2). In this equation, RGext is an external gate resistance, RGint is an internal gate resistance of each of the power devices Q51 to Q54, RGchip is a chip gate resistance of each of the power devices Q51 to Q54, and para is the number of the parallel power devices Q51 to Q54 (para=4 in this diagram).

RGtotal=RGext+(RGint+RGchip)/para (2)

The oscillation of the power module 20 occurs due to mutual interference among current loops shown by thick line arrows (black and white). For this reason, the internal gate resistor RGint is inserted adjacent to each of the chips of the power devices Q51 to 54, and hence oscillation suppression effect can be expected.

Note that if the total gate resistance RGtotal is the same, the switching loss of the power module 20 is also the same. Therefore, by reducing the external gate resistance RGext disposed adjacent to the gate drive circuit 10, and by increasing the internal gate resistance RGint disposed adjacent to each of the power devices Q51 to Q54, it is possible to effectively suppress the oscillation of the power module 20 without increasing the switching loss.

For instance, if para=4 holds, by reducing the external gate resistance RGext from 2Ω to 0Ω, and by increasing the internal gate resistance RGint from 0Ω to 8Ω, it is possible to enhance the oscillation suppression effect of the power module 20 while maintaining the total gate resistance RGtotal at 2Ω.

However, although the oscillation countermeasures for the power module 20 proposed above are each effective, there are large structural constraints. For this reason, in addition to the oscillation countermeasures described above, oscillation countermeasures in the gate drive circuit 10 are necessary.

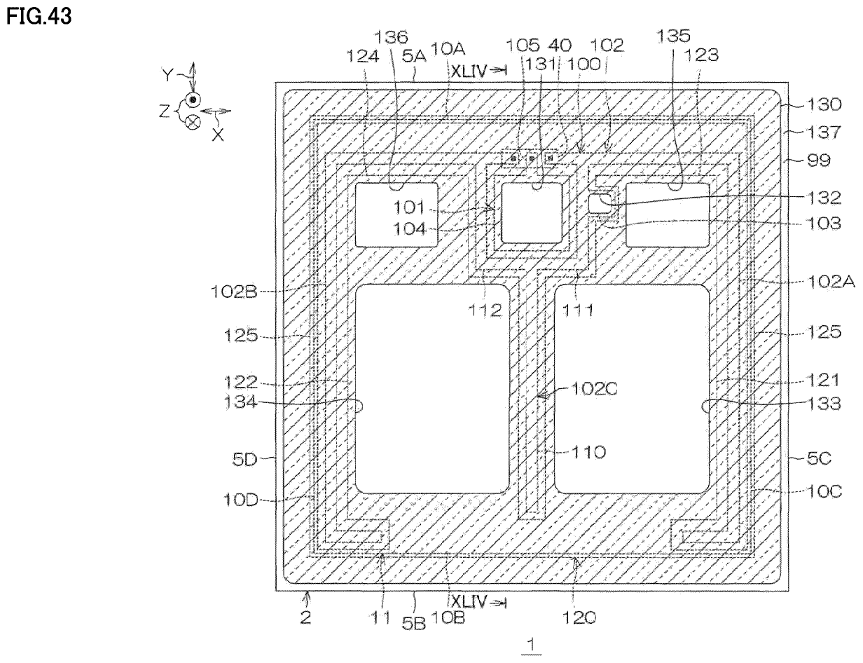

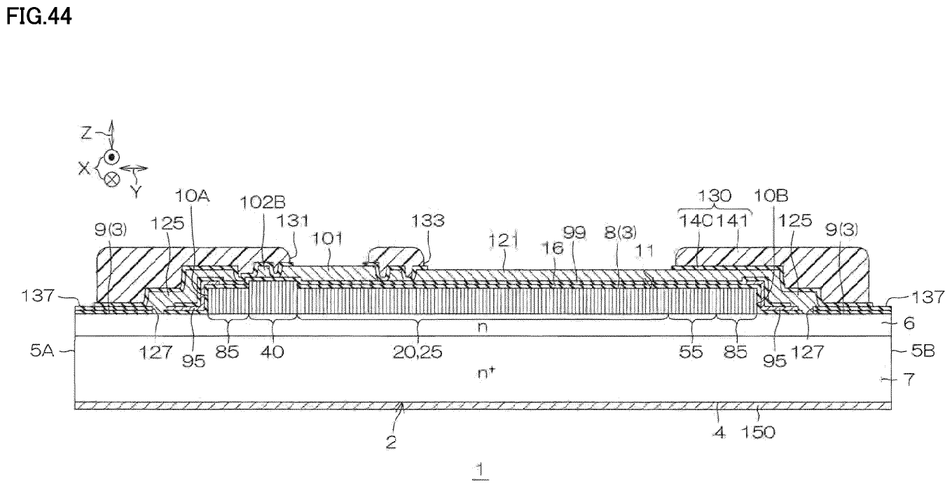

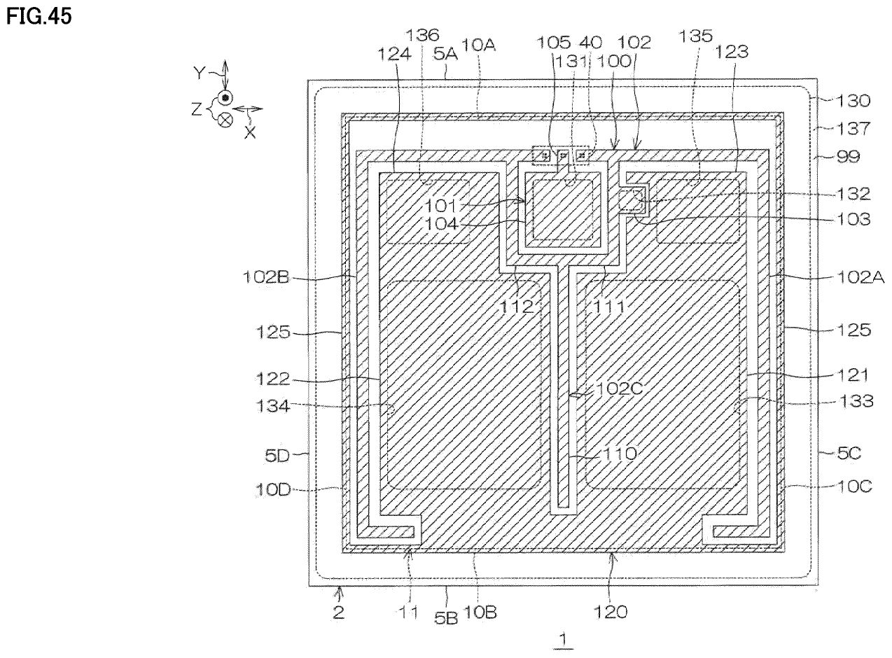

A structure example including the example in which the internal gate resistor is inserted adjacent to the chip as illustrated in FIG. 8 will be described later with reference to FIG. 43 to FIG. 47. The words and symbols defined in FIG. 43 to FIG. 47 and descriptions with reference to these diagrams are applied only to this structure example and are defined independently from other structure examples. Relation between this structure example and other structure examples will be appropriately described separately.

<Consideration about Oscillation Factor>

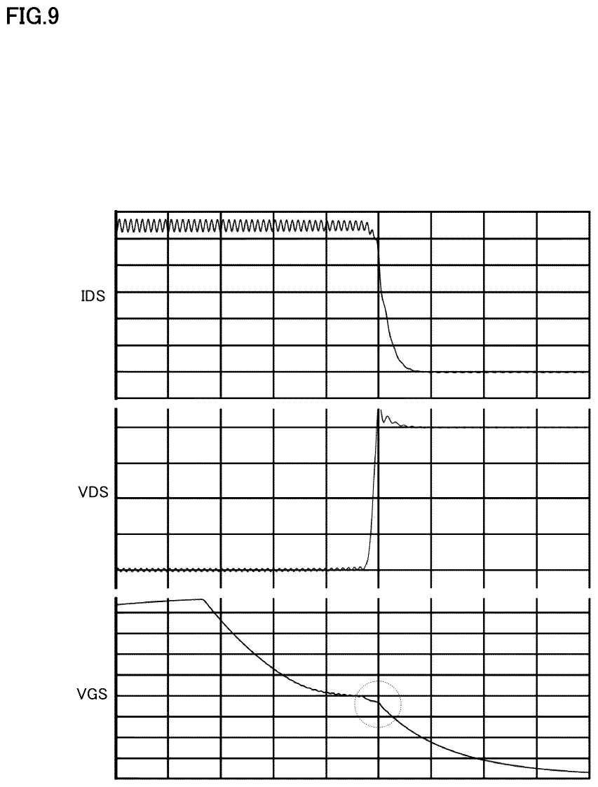

FIG. 9 is a diagram illustrating one example of turn-off behavior in the power module 20 (a power device Q included therein), in which the drain-source current IDS, the drain-source voltage VDS, and the gate-source voltage VGS of the power device Q are shown from top to bottom.

The inventor of this application focused on the question why the oscillation was apt to occur when the power device Q turns off (or turns on) so as to intensively study, and found that the oscillation of the power module 20 was able to be suppressed if the gate-source voltage VGS of the power device Q quickly passed through the unstable region (see an enclosing broken line in the diagram). Note that the current change rate of the drain-source current IDS per unit time when the power module 20 turns on/off is 0.1 A/ns or more and 30 A/ns or less, for example. In addition, the voltage change rate of the drain-source voltage VDS per unit time when the power module 20 turns on/off is 10 V/ns or more and 150 V/ns or less, for example.

Note that in order to realize the oscillation countermeasures described above, the gradient of the gate-source voltage VGS when the power device Q turns off (or turns on) should be steep. However, as the gradient of the gate-source voltage VGS is steeper, the drain-source voltage VDS has a larger surge, which may exceed the withstand voltage of the power device Q. For this reason, it is necessary to dissolve the above contradiction in the oscillation countermeasures in the gate drive circuit 10.

### <Oscillation Countermeasures in Gate Drive Circuit>

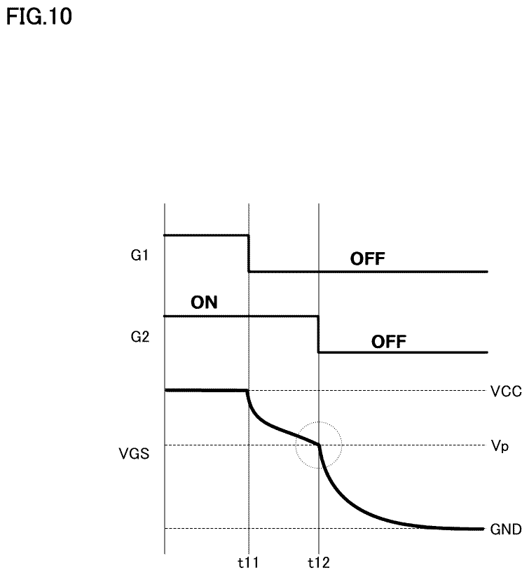

FIG. 10 is a diagram illustrating a basic concept of the oscillation countermeasures in the gate drive circuit 10, in which gate signals G1 and G2 to turn on/off the power device Q, and the gate-source voltage VGS of the power device Q are shown. Note that in this diagram, the gate signals G1 and G2 are each understood as an internal signal of the gate drive circuit 10.

Before time point t11, the gate signals G1 and G2 are each at high level. In this case, the gate drive circuit 10 makes the gate-source voltage VGS of the power device Q at high level (e.g., VCC), so as to turn on the power device Q.

At time point t11, only the gate signal G1 out of the gate signals G1 and G2 is fallen to low level. In this case, the gate drive circuit 10 decreases the gate-source voltage VGS of the power device Q relatively mildly by a first gate drive capability (weak).

At time point t12, following the gate signal G1, the gate signal G2 is also fallen to low level. In this case, the gate drive circuit 10 switches the gate drive capability for decreasing the gate-source voltage VGS of the power device Q to a second gate drive capability (strong) larger than the first gate drive capability (weak). In other words, the gate drive circuit 10 decreases the gate-source voltage VGS of the power device Q more rapidly than before the time point t12.

Note that the time point t12 may be a timing when the gate-source voltage VGS of the power device Q enters the unstable region (see the enclosing broken line in the diagram), for example. In addition, the time point t12 may be a timing when the gate-source voltage VGS of the power device Q falls lower than a plateau voltage Vp (or an approximate value thereof), or may be a timing when the gate-source voltage VGS of the power device Q passes through the plateau region.

In this way, during a turn-off transition period Toff of the power device Q, unlike a structure of having always high gate drive capability, the structure of stepwisely increasing the gate drive capability can allow the gate-source voltage VGS of the power device Q to rapidly pass through the unstable region, while suppressing a surge generated in the drain-source voltage VDS of the power device Q.

In the following description, a specific embodiment for realizing two-step gate drive of this diagram is proposed.

### <Gate Drive Circuit (First Embodiment)>

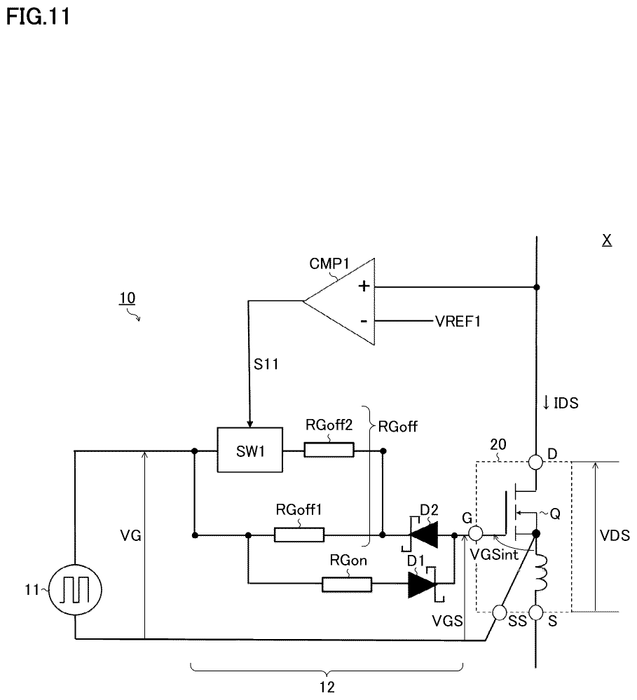

FIG. 11 is a diagram illustrating a first embodiment of the gate drive circuit 10. The gate drive circuit 10 of this embodiment includes a gate driving circuit 11, and a drive capability switching circuit 12.

The gate driving circuit 11 generates the gate drive signal VG of the power device Q (accordingly the gate-source voltage VGS of the power device Q). Note that the gate driving circuit 11 may be an insulation type or may be a non-insulation type. In addition, in this diagram, for convenience sake of illustration, the single power device Q is shown, but a plurality of power devices Q may be connected in parallel similarly as described above. In addition, a reference potential terminal of the gate driving circuit 11 may be connected to a source sense electrode SS of the power module 20.

The drive capability switching circuit 12 stepwisely increases the gate drive capability of the gate driving circuit 11 during the turn-off transition period Toff of the power device Q.

With reference to this diagram, the drive capability switching circuit 12 includes gate resistors RGon and RGoff, a switch SW1, zener diodes D1 and D2, and a comparator CMP1. Note that the gate resistor RGoff can be understood as a combined resistor of gate resistors RGoff1 and RGoff2 (e.g., RGoff1>RGoff2).

First terminals of the gate resistors RGon and RGoff1 and a first terminal of the switch SW1 are connected to the application terminal of the gate drive signal VG (i.e., an output terminal of the gate driving circuit 11). A second terminal of the switch SW1 is connected to a first terminal of the gate resistor RGoff2. A second terminal of the gate resistor RGon is connected to an anode of the zener diode D1. Second terminals of the gate resistors RGoff1 and RGoff2 are connected to a cathode of the zener diode D2. A cathode of the zener diode D1 and an anode of the zener diode D2 are connected to a gate terminal of the power device Q (i.e., the gate electrode G of the power module 20).

When turning on the power device Q, the gate drive signal VG becomes high level. In this case, a gate current IG flows from the gate driving circuit 11 to the gate terminal of the power device Q (i.e., a gate electrode of the power module 20) through the gate resistor RGon and the zener diode D1. This gate current IG charges the stray capacitance attached between gate and source of the power device Q, and the gate-source voltage VGS of the power device Q increases.

When turning off the power device Q, the gate drive signal VG becomes low level. In this case, the gate current IG flows from the gate terminal of the power device Q to the gate driving circuit 11 through the zener diode D2 and the gate resistor RGoff. This gate current IG discharges the stray capacitance attached between gate and source of the power device Q, and the gate-source voltage VGS of the power device Q decreases.

The comparator CMP1 compares the drain-source voltage VDS of the power device Q input to the noninverting input terminal (+) with a predetermined threshold voltage VREF1 input to the inverting input terminal (−), so as to generate a comparison signal S11. Therefore, the comparison signal S11 is high level if VDS>VREF1 holds, and it is low level if VDS<VREF1 holds. Note that if the drain-source voltage VDS of the power device Q is high voltage (e.g., a few hundred V), it may be possible to input a divided voltage of the drain-source voltage VDS to the comparator CMP1.

The switch SW1 is turned on/off responding to the comparison signal S11, so as to switch the gate drive capability of the gate driving circuit 11.

For instance, the switch SW1 is OFF state when the comparison signal S11 is low level, i.e., when the drain-source voltage VDS of the power device Q is lower than the threshold voltage VREF1. In other words, the switch SW1 is OFF state until the gate-source voltage VGS of the power device Q passes through the plateau region.

When the switch SW1 is OFF state, a resistance value of the gate resistor RGoff is equal to a resistance value of the gate resistor RGoff1. This state corresponds to a state where the gate resistor RGoff is increased, i.e., a state where the gate drive capability of the gate driving circuit 11 is set to the first gate drive capability (weak).

On the other hand, the switch SW1 is ON state when the comparison signal S11 is high level, i.e., when the drain-source voltage VDS of the power device Q is higher than the threshold voltage VREF1. In other words, the switch SW1 is turned on when the gate-source voltage VGS of the power device Q passes through the plateau region.

When the switch SW1 is ON state, the resistance value of the gate resistor RGoff is equal to the combined resistance value of the gate resistors RGoff1 and RGoff2 (i.e., RGoff1/RGoff2). This state corresponds to a state where the gate resistor RGoff is decreased, i.e., a state where the gate drive capability of the gate driving circuit 11 is set to the second gate drive capability (high).

In this way, the gate drive circuit 10 of this embodiment can stepwisely increase the gate drive capability of the gate driving circuit 11 during the turn-off transition period Toff of the power device Q, by monitoring the drain-source voltage VDS of the power device Q and by switching the resistance value of the gate resistor RGoff.

Therefore, the gate-source voltage VGS of the power device Q quickly passes through the unstable region, and hence the oscillation of the power module 20 can be suppressed. In addition, the gate drive capability of the gate driving circuit 11 can be decreased just after the power device Q is turned off, and hence it is also possible to suppress the surge generated in the drain-source voltage VDS of the power device Q.

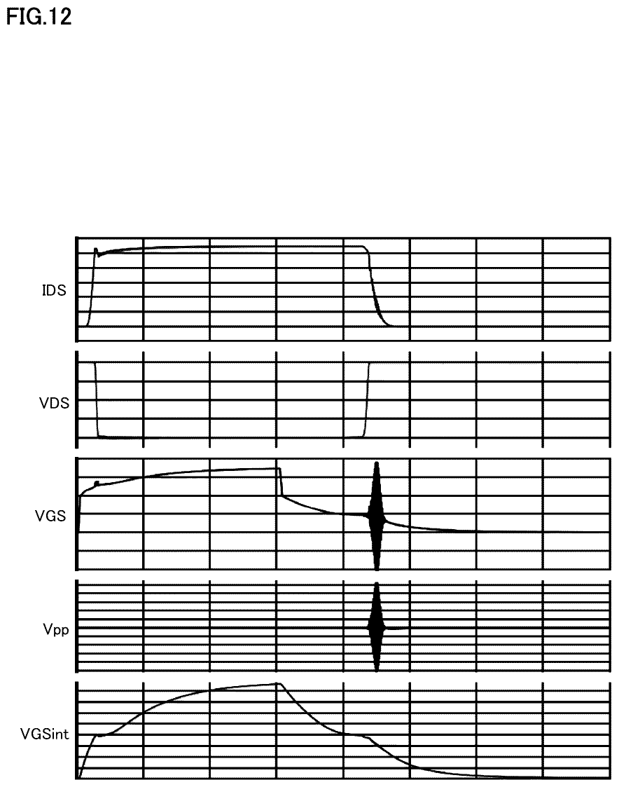

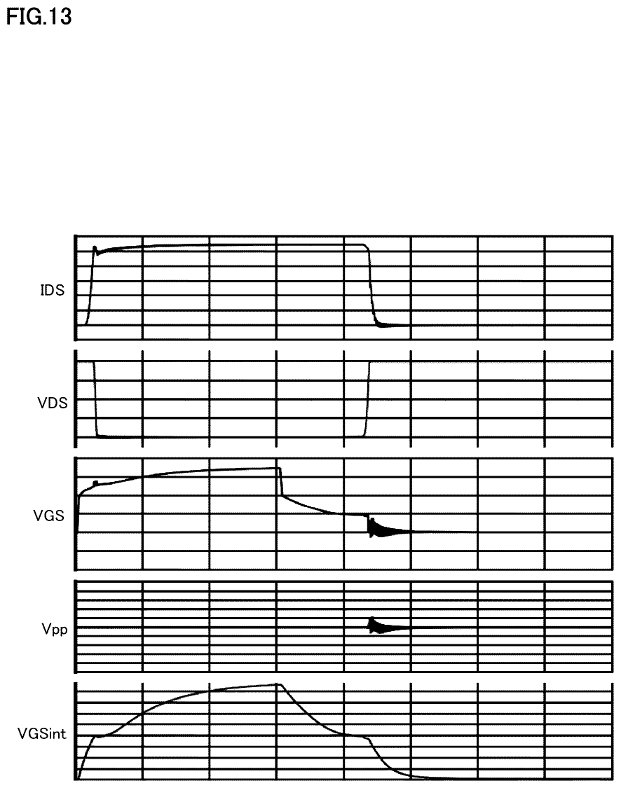

FIG. 12 and FIG. 13 are each a diagram illustrating a turn-off behavior of the power device Q, in which the drain-source current IDS, the drain-source voltage VDS, the gate-source voltage VGS, and an oscillation amplitude Vpp of the power device Q, and a voltage VGSint across a stray capacitance CGS attached between gate and source of the power device Q (i.e., corresponding to an actual gate-source voltage applied to a gate oxide film of the power device Q) are shown from top to bottom.

Note that when the gate current IG is flowing in the power device Q, a voltage (i.e., IG×RGint) across the internal gate resistor RGint is generated, and hence VGS≠VGSint holds. On the other hand, when the gate current IG is not flowing in the power device Q, the voltage across the internal gate resistor RGint is zero, and hence VGS≈VGSint holds.

In addition, FIG. 12 illustrates a conventional turn-off behavior (without the two-step gate drive), and FIG. 13 illustrates a turn-off behavior of the first embodiment (with the two-step gate drive). As clear from comparison between both diagrams, the gate drive circuit 10 of the first embodiment can suppress the oscillation of the power module 20. For instance, focusing on the oscillation amplitude Vpp of the gate-source voltage VGS, it can be largely reduced from a few tens V to a few V.

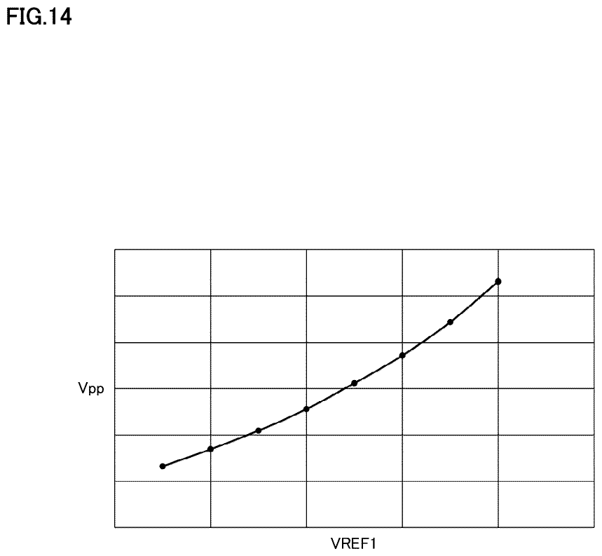

FIG. 14 is a diagram illustrating relationship between the threshold voltage VREF1 at which the gate drive capability is switched and the oscillation amplitude Vpp. As illustrated in this diagram, the oscillation amplitude Vpp is larger as the threshold voltage VREF1 is higher, and it is smaller as the threshold voltage VREF1 is lower.

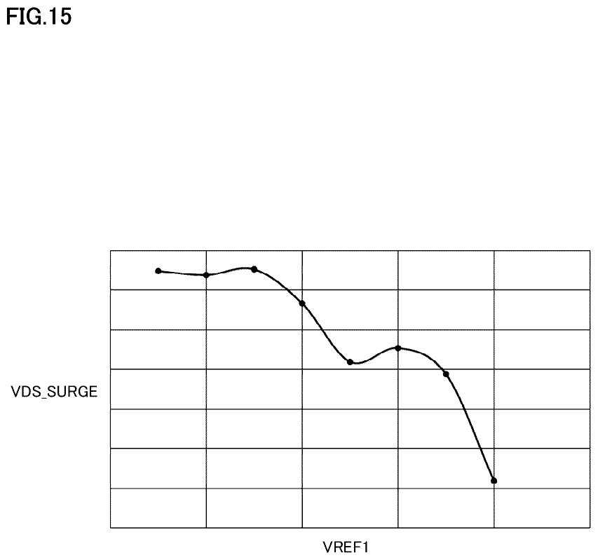

FIG. 15 is a diagram illustrating relationship between the threshold voltage VREF1 at which the gate drive capability is switched and a VDS surge. As illustrated in this diagram, the VDS surge is smaller as the threshold voltage VREF1 is higher, and it is larger as the threshold voltage VREF1 is lower.

As clear from FIG. 14 and FIG. 15, the oscillation amplitude Vpp and the VDS surge have a trade-off relationship. Therefore, it is desirable to set the threshold voltage VREF1 as a variable value, and to set the appropriate threshold voltage VREF1 so as to satisfy required specifications, while checking relationship between oscillation countermeasures of the power module 20 and the VDS surge, for example.

### <Gate Drive Circuit (Second Embodiment)>

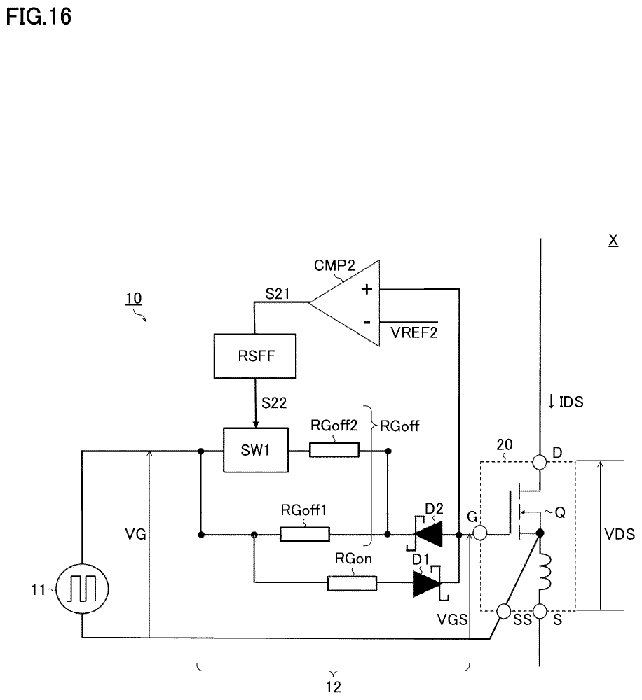

FIG. 16 is a diagram illustrating a second embodiment of the gate drive circuit 10. The gate drive circuit 10 of this embodiment is based on the first embodiment (FIG. 11) described above, and the drive capability switching circuit 12 is modified.

With reference to this diagram, the drive capability switching circuit 12 includes a comparator CMP2 and a latch RSFF, instead of the comparator CMP1 described above.

In the following description, the component described above is denoted by the same numeral or symbol as in FIG. 11 to omit description thereof, and characteristic parts of this embodiment are mainly described.

The comparator CMP2 compares the gate-source voltage VGS of the power device Q input to the noninverting input terminal (+), with a predetermined threshold voltage VREF2 input to the inverting input terminal (−), so as to generate a comparison signal S21. Therefore, the comparison signal S21 is high level if VGS>VREF2 holds, and it is low level if VGS<VREF2 holds.

The latch RSFF receives input of the comparison signal S21 and generates a latch signal S22. For instance, as the latch RSFF, it may be possible to use an RS flip-flop that sets the latch signal S22 to high level when the comparison signal S21 rises to high level. By disposing this latch RSFF, it is possible to suppress malfunction of the switch SW1 due to oscillation of the gate-source voltage VGS.

The switch SW1 is turned on/off according to the latch signal S22, so as to switch the gate drive capability of the gate driving circuit 11. For instance, the switch SW1 is OFF state when the latch signal S22 is high level. This state corresponds to a state where the gate drive capability of the gate driving circuit 11 is set to the first gate drive capability (weak). On the other hand, the switch SW1 is ON state when the latch signal S22 is low level. This state corresponds to a state where the gate drive capability of the gate driving circuit 11 is set to the second gate drive capability (high).

In this way, the gate drive circuit 10 of this embodiment can stepwisely increase the gate drive capability of the gate driving circuit 11 during the turn-off transition period Toff of the power device Q, by monitoring the gate-source voltage VGS of the power device Q and by switching the resistance value of the gate resistor RGoff. Therefore, similarly to the first embodiment (FIG. 11) described above, it is possible to suppress the oscillation of the power module 20 while suppressing a surge generated in the drain-source voltage VDS of the power device Q.

### <Gate Drive Circuit (Third Embodiment)>

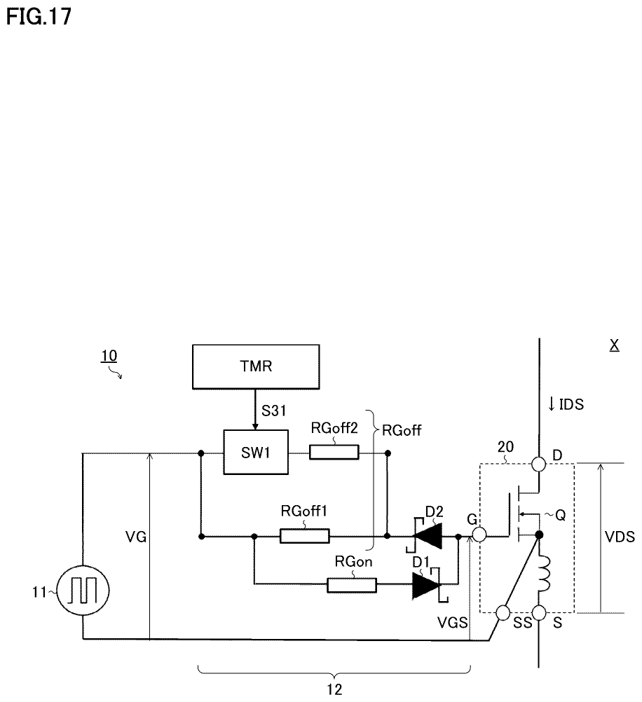

FIG. 17 is a diagram illustrating a third embodiment of the gate drive circuit 10. The gate drive circuit 10 of this embodiment is based on the first embodiment (FIG. 11) described above, and the drive capability switching circuit 12 is modified.

With reference to this diagram, the drive capability switching circuit 12 includes a timer TMR instead of the comparator CMP1 described above.

In the following description, the component described above is denoted by the same numeral or symbol as in FIG. 11 to omit description thereof, and characteristic parts of this embodiment are mainly described.

The timer TMR generates a timer signal S31 that changes its logic level when a predetermined time T has elapsed after the power device Q is turned off. For instance, the timer signal S31 is low level until count expires and becomes high level after the count expires. Note that the predetermined time T may be arbitrarily adjustable using an external capacitor (not shown), for example.

The switch SW1 is turned on/off according to the timer signal S31, so as to switch the gate drive capability of the gate driving circuit 11. For instance, the switch SW1 is OFF state when the timer signal S31 is low level. This state corresponds to a state where the gate drive capability of the gate driving circuit 11 is set to the first gate drive capability (weak). On the other hand, the switch SW1 is ON state when the timer signal S31 is high level. This state corresponds to a state where the gate drive capability of the gate driving circuit 11 is set to the second gate drive capability (high).

In this way, the gate drive circuit 10 of this embodiment can stepwisely increase the gate drive capability of the gate driving circuit 11 during the turn-off transition period Toff of the power device Q, by switching the resistance value of the gate resistor RGoff, when the predetermined time T has elapsed after the power device Q is turned off. Therefore, similarly to the first embodiment (FIG. 11) described above, it is possible to suppress the oscillation of the power module 20 while suppressing a surge generated in the drain-source voltage VDS of the power device Q.

### <Gate Drive Circuit (Fourth Embodiment)>

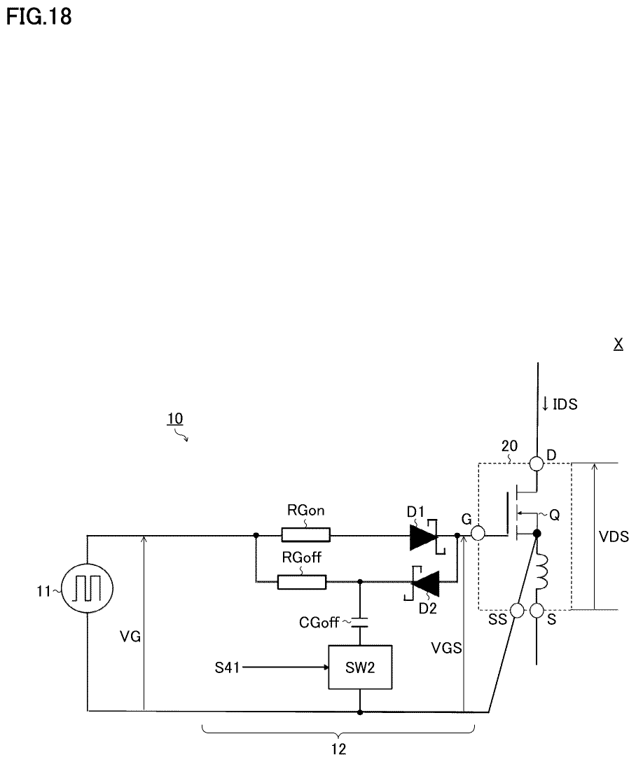

FIG. 18 is a diagram illustrating a fourth embodiment of the gate drive circuit 10. The gate drive circuit 10 of this embodiment is based on the first embodiment (FIG. 11) described above, and the drive capability switching circuit 12 is modified.

With reference to this diagram, the drive capability switching circuit 12 includes a switch SW2 and a gate capacitance CGoff, instead of the comparator CMP1 and the switch SW1 described above. In addition, the gate resistors RGoff1 and RGoff2 described above is replaced with the single gate resistor RGoff.

In the following description, the component described above is denoted by the same numeral or symbol as in FIG. 11 to omit description thereof, and characteristic parts of this embodiment are mainly described.

A first terminal of the gate resistor RGoff is connected to the application terminal of the gate drive signal VG. A second terminal of the gate resistor RGoff and a first terminal of the gate capacitance CGoff are connected to the cathode of the zener diode D2. A second terminal of the gate capacitance CGoff is connected to a first terminal of the switch SW2. A second terminal of the switch SW2 is connected to the reference potential terminal of the gate driving circuit 11 (i.e., the source sense electrode SS of the power module 20).

The switch SW2 is turned on/off according to a control signal S41, so as to switch the gate drive capability of the gate driving circuit 11. When the switch SW2 is ON state, the gate capacitance CGoff is incorporated in the circuit, and hence a time constant t is relatively large (τ≈RGoff×(CGoff+Ciss), where Ciss is an input capacitance of the power device Q). In other words, ON state of the switch SW2 corresponds to a state where the gate drive capability of the gate driving circuit 11 is set to the first gate drive capability (weak). On the other hand, when the switch SW2 is OFF state, the gate capacitance CGoff is separated from the circuit, and hence the time constant t is relatively small (τ˜RGoffxCiss). In other words, OFF state of the switch SW2 corresponds to a state where the gate drive capability of the gate driving circuit 11 is set to the second gate drive capability (high).

Note that the control signal S41 may be any one of the comparison signal S11 (FIG. 11), the latch signal S22 (FIG. 16), and the timer signal S31 (FIG. 17), which are described above.

In this way, the gate drive circuit 10 of this embodiment can stepwisely increase the gate drive capability of the gate driving circuit 11 during the turn-off transition period Toff of the power device Q, by switching between connection and disconnection of the gate capacitance CGoff. Therefore, similarly to the first embodiment (FIG. 11) described above, it is possible to suppress the oscillation of the power module 20 while suppressing a surge generated in the drain-source voltage VDS of the power device Q.

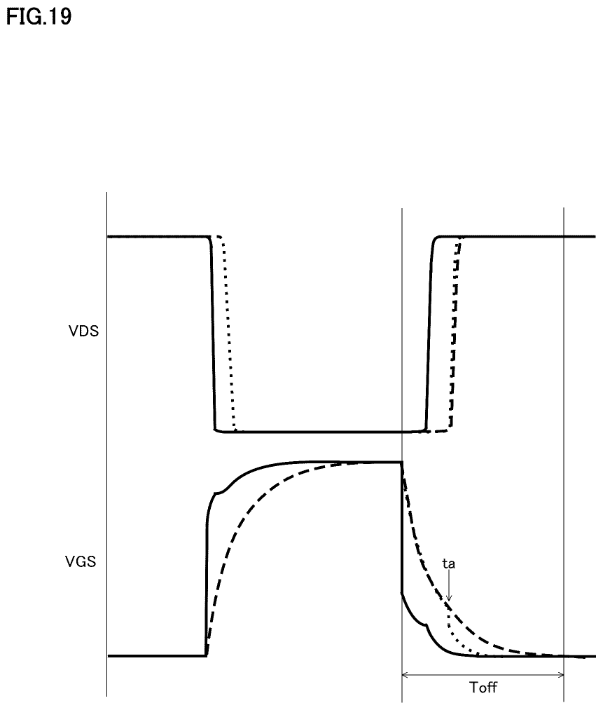

FIG. 19 is a diagram illustrating a turn on/off behavior in the fourth embodiment, in which the drain-source voltage VDS and the gate-source voltage VGS of the power device Q are shown.

Note that a solid line in this diagram illustrates the behavior in the case where the gate capacitance CGoff is always separated from the circuit, and a large broken line in this diagram illustrates the behavior in the case where the gate capacitance CGoff is always incorporated in the circuit. In addition, a small broken line in this diagram illustrates the behavior in the case where the gate capacitance CGoff is separated from the circuit during the turn-off transition period Toff (i.e., at time point ta).

During the turn-off transition period Toff of the power device Q, before the time point ta, the gate capacitance CGoff is incorporated in the circuit, and hence the time constant t is relatively large (τ≈RGoff×(CGoff+Ciss)). Therefore, the gate-source voltage VGS of the power device Q decreases relatively mildly.

On the other hand, after the time point ta, the gate capacitance CGoff is separated from the circuit, and hence the time constant τ is relatively small (τ≈RGoff×Ciss). Therefore, the gate-source voltage VGS of the power device Q falls relatively steeply.

### <Gate Drive Circuit (Fifth Embodiment)>

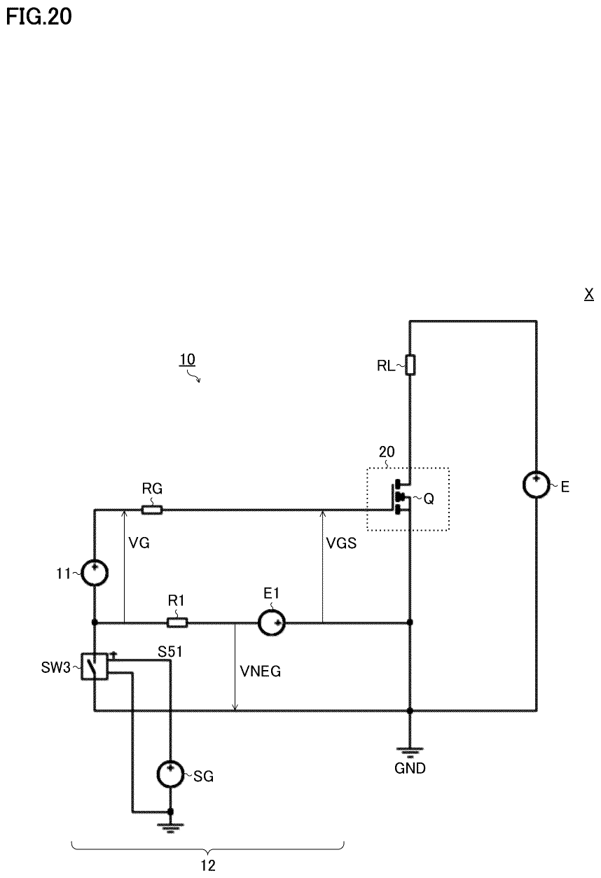

FIG. 20 is a diagram illustrating a fifth embodiment of the gate drive circuit 10. The gate drive circuit 10 of this embodiment is based on the first embodiment (FIG. 11) described above, and the drive capability switching circuit 12 is modified.

With reference to this diagram, the drive capability switching circuit 12 includes a DC voltage source E1, a signal source SG, a switch SW3, a gate resistor RG, and a resistor R1, instead of the comparator CMP1, the switch SW1, the gate resistors RGon, RGoff1, and RGoff2, and the zener diodes D1 and D2 described above. In addition, in this diagram, a DC voltage source E and a load RL, which are connected to the power module 20, are illustrated explicitly.

In the following description, the component described above is denoted by the same numeral or symbol as in FIG. 11 to omit description thereof, and characteristic parts of this embodiment are mainly described.

A first terminal of the gate resistor RG is connected to the application terminal of the gate drive signal VG (i.e., the output terminal of the gate driving circuit 11). A second terminal of the gate resistor RG is connected to the gate terminal of the power device Q. First terminals of the resistor R1 and the switch SW3 are connected to the reference potential terminal of the gate driving circuit 11. A second terminal of the resistor R1 is connected to a negative electrode terminal of the DC voltage source E1 (i.e., an application terminal of a negative potential VNEG). A positive electrode terminal of the DC voltage source E1 and a second terminal of the switch SW3 are connected to the source of the power device Q (i.e., the ground potential GND).

The DC voltage source E1 generates the negative potential VNEG that is lower than the ground potential GND.

The switch SW3 is turned on/off according to a control signal S51, so as to switch the gate drive capability of the gate driving circuit 11. When the switch SW3 is ON state, the reference potential of the gate driving circuit 11 (i.e., corresponding to off potential (low level) of the gate drive signal VG) is the ground potential GND. In other words, ON state of the switch SW3 corresponds to a state where the gate drive capability of the gate driving circuit 11 is set to the first gate drive capability (weak). On the other hand, when the switch SW3 is OFF state, the reference potential of the gate driving circuit 11 is the negative potential VNEG. In other words, OFF state of the switch SW3 corresponds to a state where the gate drive capability of the gate driving circuit 11 is set to the second gate drive capability (high).

Note that the control signal S51 may be any one of the comparison signal S11 (FIG. 11), the latch signal S22 (FIG. 16), and the timer signal S31 (FIG. 17), which are described above.

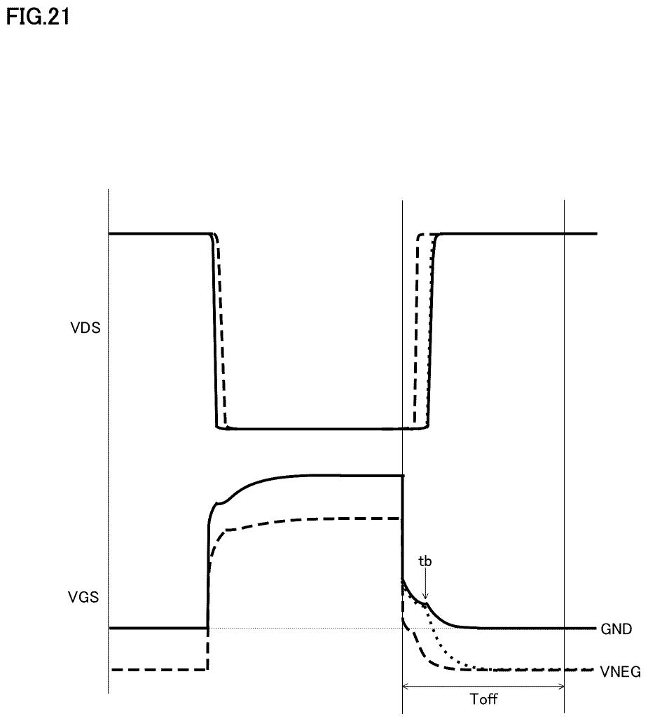

FIG. 21 is a diagram illustrating a turn on/off behavior in the fifth embodiment, in which the drain-source voltage VDS and the gate-source voltage VGS of the power device Q are shown.

Note that a solid line in this diagram illustrates the behavior in the case where the off potential of the gate drive signal VG is always the ground potential GND, and a large broken line in this diagram illustrates the behavior in the case where the off potential of the gate drive signal VG is always the negative potential VNEG. In addition, a small broken line in this diagram illustrates the behavior in the case where the off potential of the gate drive signal VG is switched from the ground potential GND to the negative potential VNEG during the turn-off transition period Toff (i.e., at time point tb).

During the turn-off transition period Toff of the power device Q, before the time point tb, the off potential of the gate drive signal VG is the ground potential GND. Therefore, the gate-source voltage VGS of the power device Q is decreased relatively mildly.

On the other hand, after the time point tb, the off potential of the gate drive signal VG is switched to the negative potential VNEG. Therefore, the gate-source voltage VGS of the power device Q falls relatively steeply.

### <Gate Drive Circuit (Sixth Embodiment)>

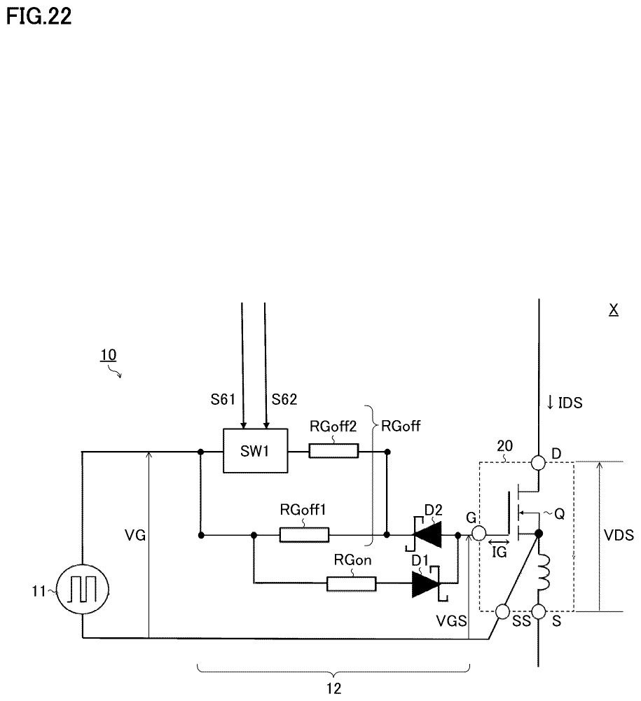

FIG. 22 is a diagram illustrating a sixth embodiment of the gate drive circuit 10. The gate drive circuit 10 of this embodiment is based on the first embodiment (FIG. 11) described above, and the drive capability switching circuit 12 is modified. With reference to this diagram, in the drive capability switching circuit 12, instead of the comparison signal S11 described above, control signals S61 and S62 are input to the switch SW1. In the following description, the component described above is denoted by the same numeral or symbol as in FIG. 11 to omit description thereof, and characteristic parts of this embodiment are mainly described.

The switch SW1 is turned on/off according to the control signals S61 and S62. For instance, the switch SW1 is switched not in two steps as described above but in multiple steps (e.g., three steps like ON to OFF to ON) during the turn-off transition period Toff of the power device Q.

In other words, during the turn-off transition period Toff of the power device Q, the drive capability switching circuit 12 decreases the gate drive capability from the first gate drive capability (strong) to the second gate drive capability (weak), and afterward increases it from the second gate drive capability (weak) to the first gate drive capability (strong) again.

Note that the control signals S61 and S62 may be any one of the comparison signal S11 (FIG. 11), the latch signal S22 (FIG. 16), and the timer signal S31 (FIG. 17), which are described above.

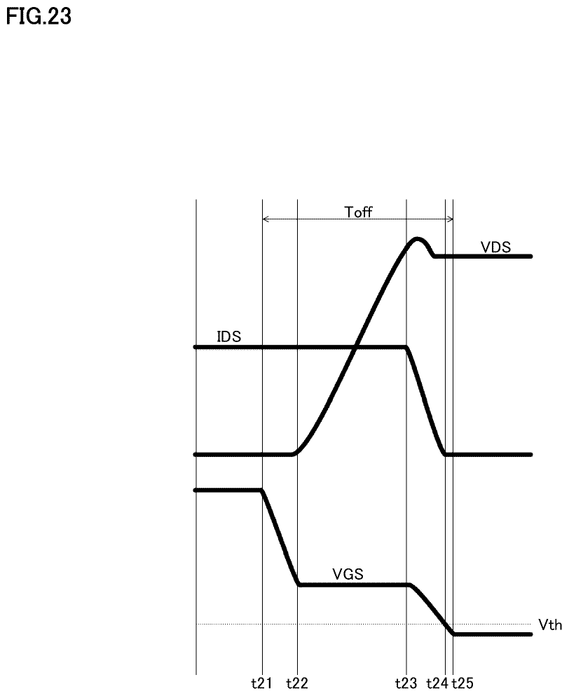

FIG. 23 is a diagram schematically illustrating the turn-off behavior of the power device Q, in which the drain-source current IDS, the drain-source voltage VDS, and the gate-source voltage VGS of the power device Q are shown from top to bottom.

Between time points t21 and t22, the gate-source voltage VGS decreases in the state where the drain-source current IDS is maintained at a predetermined value.

Between time points t22 and t23, the drain-source voltage VDS increases in the state where the gate-source voltage VGS is maintained at a predetermined value (i.e., a voltage value to maintain the drain-source current IDS).

Between time points t23 and t24, the gate-source voltage VGS decreases in the state where the drain-source voltage VDS is maintained at a predetermined value, and the drain-source current IDS decreases along with this.

Between time points t24 and t25, the gate-source voltage VGS becomes lower than an ON threshold voltage Vth of the power device Q1, and the drain-source current IDS does not flow.

During the turn-off transition period Toff of the power device Q described above (i.e., between t21 and t25), just after the power device Q is turned off (e.g., between time points t21 and t22), reduction of switching loss should be prioritized so as to set the gate drive capability to the first gate drive capability (strong).

After that, in an increasing phase of the drain-source voltage VDS (e.g., between time points t22 and t23), suppression of surge should be prioritized so as to decrease the gate drive capability from the first gate drive capability (strong) to the second gate drive capability (weak).

Further, at timing when the gate-source voltage VGS enters the unstable region (e.g., time point t23), suppression of oscillation should be prioritized so as to increase the gate drive capability from the second gate drive capability (weak) to the first gate drive capability (strong) again.

### Variations

Note that the two-step (or three-step) gate driving method described above can be used as oscillation countermeasures not only during the turn-off transition period Toff of the power device Q, but also during a turn-on transition period Ton. In addition, not only implementing each of the embodiment structures solely, but they can also be appropriately combined for implementation within the scope without any contradiction.

### Generalization

In the following description, the various embodiments described above are generalized.

For instance, the gate drive circuit disclosed in this specification includes a gate driving circuit configured to generate a gate drive signal for a power device, and a drive capability switching circuit configured to stepwisely increase gate drive capability of the gate driving circuit, during at least one of a turn-off transition period and a turn-on transition period of the power device (first structure).

In the gate drive circuit having the first structure, it may be possible to adopt a structure (second structure), in which the drive capability switching circuit includes a comparator configured to compare an inter-terminal voltage between main terminals of the power device with a predetermined threshold voltage, so as to generate a comparison signal, and a switch configured to switch the gate drive capability according to the comparison signal.

In addition, in the gate drive circuit according to the second structure described above, it may be possible to adopt a structure (the third structure), in which the threshold voltage is a variable value.

In addition, in the gate drive circuit according to the first structure described above, it may be possible to adopt a structure (fourth structure) in which the drive capability switching circuit includes a comparator configured to compare an inter-terminal voltage between a control terminal and a main terminal of the power device with a predetermined threshold voltage, so as to generate the comparison signal, a latch configured to receive input of the comparison signal so as to generate a latch signal, and a switch configured to switch the gate drive capability according to the latch signal.

In addition, in the gate drive circuit according to the first structure described above, it may be possible to adopt a structure (fifth structure), in which the drive capability switching circuit includes a timer configured to generate a timer signal that changes its logic level when a predetermined time has elapsed after at least one of turn-off timing and turn-on timing of the power device, and a switch configured to switch the gate drive capability according to the timer signal.

In addition, in the gate drive circuit according to any one of the first to fifth structures described above, it may be possible to adopt a structure (sixth structure), in which the drive capability switching circuit further includes a gate resistor, so that the switch switches a resistance value of the gate resistor.

In addition, in the gate drive circuit according to any one of the first to sixth structures described above, it may be possible to adopt a structure (seventh structure), in which the drive capability switching circuit further includes a gate capacitance, so that the switch switches between connection and disconnection of the gate capacitance.

In addition, in the gate drive circuit according to any one of the first to seventh structures described above, it may be possible to adopt a structure (eighth structure), in which the drive capability switching circuit further includes a DC voltage source configured to generate a negative potential lower than a reference potential, so that the switch switches the off potential of the gate drive signal between the negative potential and the reference potential.

In addition, in the gate drive circuit according to any one of the first to eighth structures described above, it may be possible to adopt a structure (ninth structure), in which the drive capability switching circuit decreases the gate drive capability from a first gate drive capability to a second gate drive capability during at least one of the turn-off transition period and the turn-on transition period of the power device, and afterward increases the same from the second gate drive capability to the first gate drive capability again.

In addition, for example, an electric power conversion device disclosed in this specification has a structure (tenth structure), which includes a power module configured to include at least one said power device, and the gate drive circuit according to any one of the first to ninth structures.

FIG. 24 to FIG. 29 illustrate the second structure example of the power module of the present disclosure. A semiconductor device B1 illustrated in these diagrams corresponds to the second structure example of the power module. The words and symbols defined in FIG. 24 to FIG. 29 and descriptions with reference to these diagrams are applied only to this structure example and are defined independently from other structure examples. Relation between this structure example and other structure examples will be appropriately described separately. The semiconductor device B1 includes a plurality of first semiconductor devices 11, a plurality of second semiconductor devices 12, a support substrate 2, a plurality of terminals, a plurality of connection members, and a seal member 6. The plurality of terminals include a plurality of power terminals 41 to 43 and a plurality of signal terminals 44A, 44B, 45A, 45B, 46, and 49. The plurality of connection members include a plurality of connection members 52A, 52B, 54A, 54B, and 56, and a plurality of connection members 58A and 58B.

The power devices Q21 to Q23 of the second example of the device layout illustrated in FIG. 4 correspond to the plurality of first semiconductor devices 11, for example, the power supply electrode P corresponds to the power terminal 41, and the output electrode OUT corresponds to the power terminal 43. In addition, the gate electrode G of the second example of the gate wiring layout illustrated in FIG. 6 corresponds to the signal terminal 44A, the power devices Q41 to Q44 correspond to the plurality of first semiconductor devices 11, and gate wirings GL21 to GL24 correspond to conduction paths between the signal terminal 44A and third electrodes 113 (gates) of the plurality of first semiconductor devices 11, respectively.

Each of the plurality of first semiconductor devices 11 and the plurality of second semiconductor devices 12 is a MISFET including a MOSFET, for example. Each of the plurality of first semiconductor devices 11 and the plurality of second semiconductor devices 12 may be a field effect transistor such as a MISFET including a MOSFET, or may be other switching device such as a bipolar transistor including an IGBT. Each of the plurality of first semiconductor devices 11 and the plurality of second semiconductor devices 12 is made of silicon carbide (SiC). The semiconductor material is not limited to SiC, but may be silicon (Si), gallium arsenide (GaAs), gallium nitride (GaN), gallium oxide (Ga₂O₃), or the like.

Each of the plurality of first semiconductor devices 11 is bonded to the support substrate 2 via a conductive bonding material. The conductive bonding material is solder, a metal paste material, sintered metal, or the like, for example. The plurality of first semiconductor devices 11 are arranged with equal spaces in a second direction y, for example.

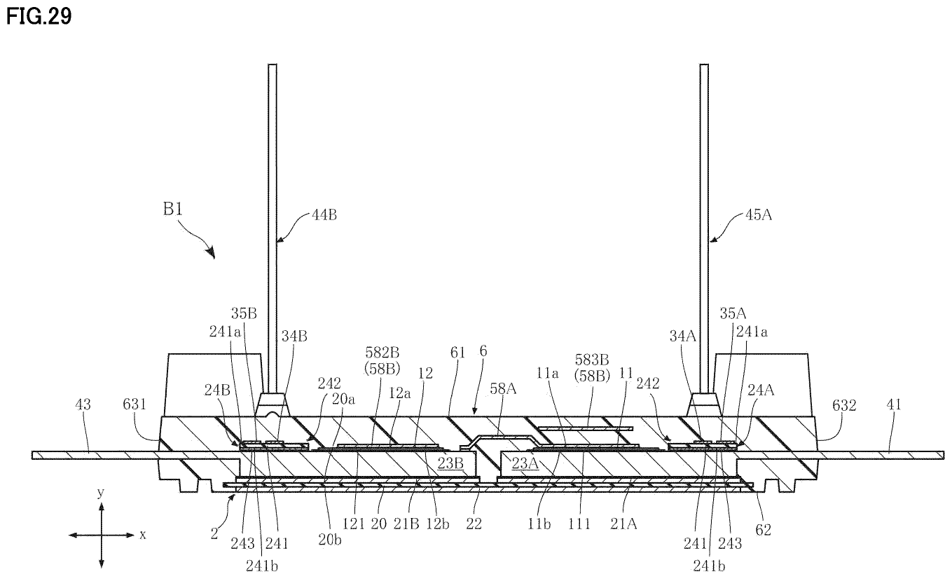

Each of the plurality of first semiconductor devices 11 has a first device principal surface 11a and a first device back surface 11b. As illustrated in FIG. 29, the first device principal surface 11a and the first device back surface 11b are apart from each other in a thickness direction z. The first device principal surface 11a faces one side (upward) in the thickness direction z, and the first device back surface 11b faces the other side (downward) in the thickness direction z. The first device back surface 11b faces the support substrate 2.

Each of the plurality of first semiconductor devices 11 has a first electrode 111, a second electrode 112, and the third electrode 113. In an example in which each first semiconductor device 11 is a MISFET, the first electrode 111 is a drain, the second electrode 112 is a source, and the third electrode 113 is a gate. In each first semiconductor device 11, the first electrode 111 is disposed on the first device back surface 11b, while the second electrode 112 and the third electrode 113 are disposed on the first device principal surface 11a.

In each of the plurality of first semiconductor devices 11, a first drive signal (e.g., a gate voltage) is input to the third electrode 113 (gate). Each of the plurality of first semiconductor devices 11 is switched between ON state (conduction state) and OFF state (cut-off state), in accordance with the first drive signal input. This operation to switch between ON state and OFF state is referred to as a switching operation. In ON state, a forward current flows from the first electrode 111 (drain) to the second electrode 112 (source), while in OFF state, the current does not flow. Each first semiconductor device 11 is controlled on and off, between the first electrode 111 (drain) and the second electrode 112 (source), by the first drive signal (e.g., the gate voltage) input to the third electrode 113 (gate). A switching frequency of each first semiconductor device 11 depends on a frequency of the first drive signal. Although there is no limitation about the switching frequency, it is 1 Hz or more and 1,000 kHz or less, for example.

The plurality of first semiconductor devices 11 are electrically connected in parallel to each other. Specifically, the first electrodes 111 (drains) are electrically connected to each other, and the second electrodes 112 (sources) are electrically connected to each other. The semiconductor device B1 inputs the first drive signal commonly to the plurality of first semiconductor devices 11 connected in parallel, so as to perform parallel operation of the plurality of first semiconductor devices 11.

Each of the plurality of second semiconductor devices 12 is bonded to the support substrate 2 via a conductive bonding material. The conductive bonding material is solder, a metal paste material, sintered metal, or the like, for example. The plurality of second semiconductor devices 12 are arranged with equal spaces in the second direction y.

Each of the plurality of second semiconductor devices 12 has a second device principal surface 12a and a second device back surface 12b. The second device principal surface 12a and the second device back surface 12b are apart from each other in the thickness direction z. The second device principal surface 12a faces one side (upward) in the thickness direction z, while the second device back surface 12b faces the other side (downward) in the thickness direction z. The second device back surface 12b faces the support substrate 2.

Each of the plurality of second semiconductor devices 12 has a fourth electrode 121, a fifth electrode 122, and a sixth electrode 123. In an example in which each second semiconductor device 12 is a MISFET, the fourth electrode 121 is a drain, the fifth electrode 122 is a source, and the sixth electrode 123 is a gate. In each second semiconductor device 12, the fourth electrode 121 is disposed on the second device back surface 12b, while the fifth electrode 122 and the sixth electrode 123 are disposed on the second device principal surface 12a.

In each of the plurality of second semiconductor devices 12, a second drive signal (e.g., the gate voltage) is input to the sixth electrode 123 (gate). Each of the plurality of second semiconductor devices 12 is switched between ON state and OFF state, in accordance with the second drive signal input. In ON state, a forward current flows from the fourth electrode 121 (drain) to the fifth electrode 122 (source), while in OFF state, the current does not flow. Each of the second semiconductor device 12 is controlled on and off, between the fourth electrode 121 (drain) and the fifth electrode 122 (source), by the second drive signal (e.g., the gate voltage) input to the sixth electrode 123 (gate). A switching frequency of each second semiconductor device 12 depends on the frequency of the second drive signal. Although there is no limitation about the switching frequency, it is 10 kHz or more and 100 kHz or less, for example.

The plurality of second semiconductor devices 12 are electrically connected in parallel to each other. Specifically, the fourth electrodes 121 (drains) are electrically connected to each other, and the fifth electrodes 122 (sources) are electrically connected to each other. The semiconductor device B1 inputs the second drive signal commonly to the plurality of second semiconductor devices 12 connected in parallel, so as to perform parallel operation of the plurality of second semiconductor devices 12.

In the semiconductor device B1, the support substrate 2 includes an insulation substrate 20, a principal surface metal layer 21, a back surface metal layer 22, a pair of conductive substrates 23A and 23B, and a pair of signal substrates 24A and 24B. This support substrate 2 has a structure in which the pair of conductive substrates 23A and 23B, and the pair of signal substrates 24A and 24B are disposed on a direct bonded copper (DBC) substrate (or a direct bonded aluminum (DBA) substrate). Note that this DBC substrate (or DBA substrate) is constituted of the insulation substrate 20, a pair of principal surface metal layers 21A and 21B, and the back surface metal layer 22.

As illustrated in FIG. 29, each of the pair of principal surface metal layers 21A and 21B is formed on a substrate principal surface 20a of the insulation substrate 20. The pair of principal surface metal layers 21A and 21B are apart from each other in a first direction x. The conductive substrate 23A is bonded to the principal surface metal layer 21A, and the conductive substrate 23B is bonded to the principal surface metal layer 21B. Each of the pair of principal surface metal layers 21A and 21B has a rectangular shape in a plan view, for example.

Each of the pair of conductive substrates 23A and 23B is made of metal. The metal is copper, a copper alloy, aluminum, an aluminum alloy, or the like.

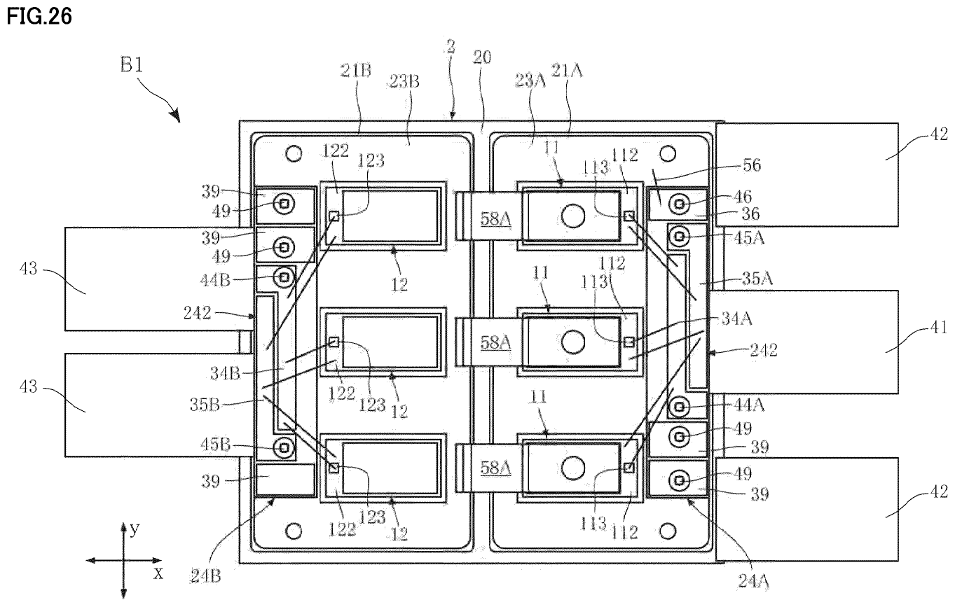

As illustrated in FIG. 29, the conductive substrate 23A is disposed on the principal surface metal layer 21A. As illustrated in FIG. 29, the plurality of first semiconductor devices 11 are mounted on the conductive substrate 23A. As illustrated in FIG. 26, the plurality of first semiconductor devices 11 of the semiconductor device B1 are arranged along the second direction y on the conductive substrate 23A. The conductive substrate 23A faces the first device back surfaces 11b of the plurality of first semiconductor devices 11. The conductive substrate 23A is conductively bonded to the first electrodes 111 (drains) of the plurality of first semiconductor devices 11. The first electrodes 111 of the plurality of first semiconductor devices 11 are electrically connected to each other via the conductive substrate 23A.

As illustrated in FIG. 29, the conductive substrate 23B is disposed on the principal surface metal layer 21B. As illustrated in FIG. 29, the plurality of second semiconductor devices 12 are mounted on the conductive substrate 23B. As illustrated in FIG. 26, the plurality of second semiconductor devices 12 of the semiconductor device B1 are arranged along the second direction y on the conductive substrate 23B. The conductive substrate 23B faces the second device back surfaces 12b of the plurality of second semiconductor devices 12. The conductive substrate 23B is conductively bonded to the fourth electrodes 121 (drains) of the plurality of second semiconductor devices 12. The fourth electrodes 121 of the plurality of second semiconductor devices 12 are electrically connected to each other via the conductive substrate 23B.

The pair of signal substrates 24A and 24B support the plurality of signal terminals 44A, 44B, 45A, 45B, 46, and 49. As illustrated in FIG. 29, the pair of signal substrates 24A and 24B are disposed between the pair of conductive substrates 23A and 23B and the plurality of signal terminals 44A, 44B, 45A, 45B, 46, and 49 in the thickness direction z. Each of the pair of signal substrates 24A and 24B is constituted of a DBC substrate, for example. Unlike this structure, each of the pair of signal substrates 24A and 24B may be constituted of a DBA substrate, for example. In addition, each of the pair of signal substrates 24A and 24B may be constituted of a printed circuit board other than the DBC substrate or the DBA substrate.

As illustrated in FIG. 29, the signal substrate 24A is disposed on the conductive substrate 23A. The signal substrate 24A supports the plurality of signal terminals 44A, 45A, 46, and 49. The signal substrate 24A is bonded to the conductive substrate 23A via a bonding material. This bonding material may be conductive or may be insulative, and solder is used, for example. As illustrated in FIG. 29, the signal substrate 24B is disposed on the conductive substrate 23B. The signal substrate 24B supports the plurality of signal terminals 44B, 45B, and 49. The signal substrate 24B is bonded to the conductive substrate 23B via a bonding material. This bonding material may be conductive or may be insulative, and solder is used, for example.

As illustrated in FIG. 29, each of the pair of signal substrates 24A and 24B includes an insulation substrate 241, a principal surface metal layer 242, and a back surface metal layer 243. In the following description, the insulation substrate 241, the principal surface metal layer 242, and the back surface metal layer 243 are common between the pair of signal substrates 24A and 24B, unless otherwise noted.

The insulation substrate 241 is made of ceramic, for example. This ceramic is AlN, SiN, Al₂O₃, or the like, for example. The insulation substrate 241 has a rectangular shape in a plan view, for example. As illustrated in FIG. 29, the insulation substrate 241 has a principal surface 241a and a back surface 241b. The principal surface 241a and the back surface 241b are apart from each other in the thickness direction z. The principal surface 241a faces upward in the thickness direction z, and the back surface 241b faces downward in the thickness direction z. The principal surface 241a and the back surface 241b are substantially flat.

As illustrated in FIG. 29, the back surface metal layer 243 is formed on the back surface 241b of the insulation substrate 241. The back surface metal layer 243 of the signal substrate 24A is bonded to the conductive substrate 23A via a bonding material. The back surface metal layer 243 of the signal substrate 24B is bonded to the conductive substrate 23B via a bonding material. A structural material of the back surface metal layer 243 is copper or a copper alloy, for example. This structure material may be aluminum or an aluminum alloy instead of copper or a copper alloy.

As illustrated in FIG. 29, the principal surface metal layer 242 is formed on the principal surface 241a of the insulation substrate 241. Each of the plurality of signal terminals 44A, 44B, 45A, 45B, 46, and 49 is disposed to stand on the principal surface metal layer 242 of one of the pair of signal substrates 24A and 24B. A structural material of the principal surface metal layer 242 is copper or a copper alloy, for example. This structure material may be aluminum or an aluminum alloy instead of copper or a copper alloy.

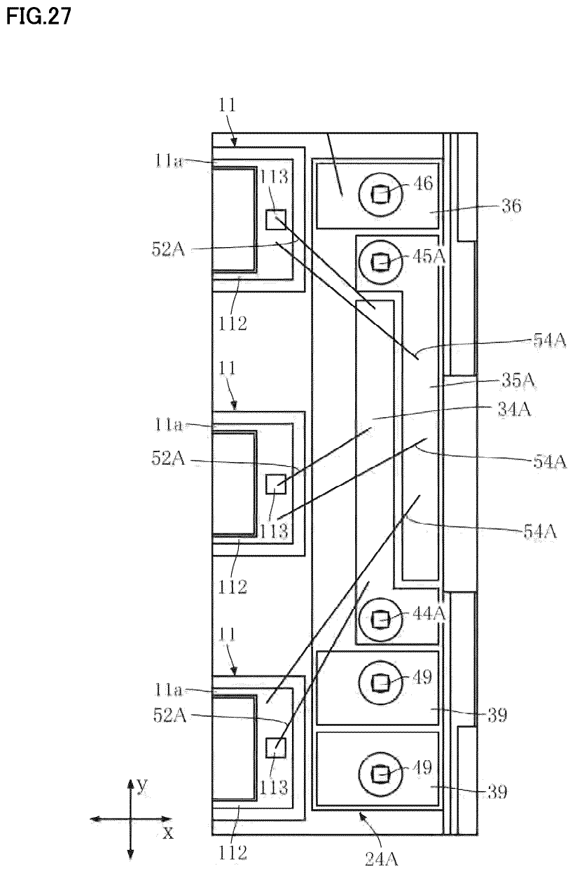

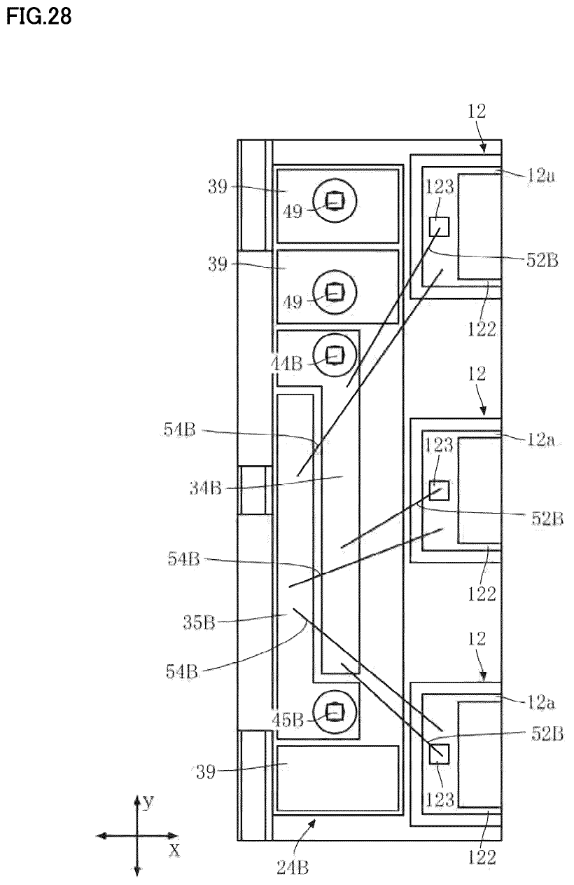

As illustrated in FIG. 26 and FIG. 27, the principal surface metal layer 242 of the signal substrate 24A includes a plurality of signal wiring parts 34A, 35A, 36, and 39. As illustrated in FIG. 26 and FIG. 28, the principal surface metal layer 242 of the signal substrate 24B includes a plurality of signal wiring parts 34B, 35B, and 39.

The plurality of signal wiring parts 34A, 34B, 35A, and 35B constitute a conduction path of each electric signal to control the semiconductor device B1.

The signal wiring part 34A is electrically connected to the third electrodes 113 (gates) of the plurality of first semiconductor devices 11. The signal wiring part 34A transmits the first drive signal. The signal wiring part 34A is bonded to the signal terminal 44A.

The signal wiring part 34B is electrically connected to the sixth electrodes 123 (gates) of the plurality of second semiconductor devices 12. The signal wiring part 34B transmits the second drive signal. The signal terminal 44B is bonded to the signal wiring part 34B.

The signal wiring part 35A is electrically connected to the second electrodes 112 (sources) of the plurality of first semiconductor devices 11. The signal wiring part 35A transmits a first detection signal. The first detection signal is a signal that indicates a conduction state of each first semiconductor device 11 and is a voltage signal corresponding to a current (source current) flowing in each second electrode 112 (source), for example. The signal terminal 45A is bonded to the signal wiring part 35A.

The signal wiring part 35B is electrically connected to the fifth electrodes 122 (sources) of the plurality of second semiconductor devices 12. The signal wiring part 35B transmits a second detection signal. The second detection signal is an electric signal that indicates a conduction state of each second semiconductor device 12, and is a voltage signal corresponding to a current (source current) flowing in each fifth electrode 122 (source), for example. The signal terminal 45B is bonded to the signal wiring part 35B.

Each of the plurality of signal wiring parts 39 is not electrically connected to any one of the plurality of first semiconductor devices 11 and the plurality of second semiconductor devices 12. In other words, neither a main circuit current nor an electric signal flows in any one of the plurality of signal wiring parts 39.

The signal wiring part 36 is bonded to the connection member 56, and is electrically connected to the conductive substrate 23A via the connection member 56. The conductive substrate 23A is electrically connected to the first electrodes 111 (drains) of the plurality of first semiconductor devices 11, and hence the signal wiring part 36 is electrically connected to the first electrodes 111 (drains) of the plurality of first semiconductor devices 11.

The power terminal 41 is formed integrally with the conductive substrate 23A. Unlike this structure, the power terminal 41 may be bonded to the conductive substrate 23A. The power terminal 41 has a smaller size in the thickness direction z than the conductive substrate 23A. The power terminal 41 extends from the conductive substrate 23A to one side in the first direction x. The one side in the first direction x is opposite to the side of the conductive substrate 23A on which the conductive substrate 23B is disposed. The power terminal 41 protrudes from a resin side surface 632. The power terminal 41 is electrically connected to the first electrodes 111 (drains) of the plurality of first semiconductor devices 11 via the conductive substrate 23A.

Each of the two power terminals 42 is apart from the conductive substrate 23A. The two power terminals 42 are disposed on the opposite sides with respect to the power terminal 41 in the second direction y. The two power terminals 42 are disposed on one side in the first direction x with respect to the conductive substrate 23A. The one side in the first direction x is the side on which the power terminal 41 is positioned with respect to the conductive substrate 23A. The two power terminals 42 protrude from the resin side surface 632. The connection member 58B is bonded to each of the two power terminals 42. Each of the two power terminals 42 are electrically connected to the fifth electrodes 122 (sources) of the plurality of second semiconductor devices 12 via the connection member 58B.

Each of the two power terminals 43 is formed integrally with the conductive substrate 23B. Unlike this structure, each of the two power terminals 43 may be bonded to the conductive substrate 23B. Each of the two power terminals 43 has a smaller size in the thickness direction z than the conductive substrate 23B. Each of the two power terminals 43 extends from the conductive substrate 23B to the other side in the first direction x. The other side in the first direction x is the opposite side to the side on which the conductive substrate 23A is positioned with respect to the conductive substrate 23B. The two power terminals 43 protrude from a resin side surface 631. Each of the two power terminals 43 is electrically connected to the second electrodes 112 (sources) of the plurality of first semiconductor devices 11 and the fourth electrodes 121 (drains) of the plurality of second semiconductor devices 12, via the conductive substrate 23B.

The power terminal 41 and the two power terminals 42 are connected to the power supply and are applied with a power supply voltage (e.g., a DC voltage). In this embodiment, the power terminal 41 is a power input terminal of a positive electrode side (a P terminal), and the power terminal 42 is a power input terminal of a negative electrode side (an N terminal), but they may be of opposite polarities. The two power terminals 43 output a voltage (e.g., an AC voltage) after power conversion by switching operations of the plurality of first semiconductor devices 11 and by switching operations of the plurality of second semiconductor devices 12. The power terminal 43 is a power output terminal (an OUT terminal). The main circuit currents in the semiconductor device B1 (a first main circuit current and a second principal surface current) are generated by the power supply voltage described above and the voltage after the conversion described above.

The power terminal 41 is electrically connected to the first electrodes 111 (drains) of the plurality of first semiconductor devices 11.

The power terminal 42 is electrically connected to the fifth electrodes 122 (sources) of the plurality of second semiconductor devices 12.

The power terminal 43 is electrically connected to the second electrodes 112 (sources) of the plurality of first semiconductor devices 11, while it is electrically connected to the fourth electrodes 121 (drains) of the plurality of second semiconductor devices 12.

The power terminal 41 and the two power terminals 42 are apart from each other and are arranged along in the second direction y. The power terminal 41 and two power terminals 42 are disposed on the opposite side to the two power terminals 43 with respect to the support substrate 2 in the first direction x. The two power terminals 43 are arranged along the second direction y.

The plurality of signal terminals 44A, 44B, 45A, and 45B are each an input terminal or an output terminal of an electric signal to control the semiconductor device B1. Each of the plurality of signal terminals 44A, 44B, 45A, 45B, and 49 has a part covered by the seal member 6 and a part exposed from the seal member 6. Each of the plurality of signal terminals 44A, 44B, 45A, 45B, and 49 is a pin-shaped metal member. This metal member contains copper or a copper alloy, for example.

The signal terminal 44A is electrically connected to the signal wiring part 34A. As the signal wiring part 34A is electrically connected to the third electrodes 113 (gates) of the plurality of first semiconductor devices 11, the signal terminal 44A is electrically connected to the third electrodes 113. The signal terminal 44A is an input terminal of the first drive signal.

The signal terminal 44B is electrically connected to the signal wiring part 34B. As the signal wiring part 34B is electrically connected to the sixth electrodes 123 (gates) of the plurality of second semiconductor devices 12, the signal terminal 44B is electrically connected to the sixth electrodes 123. The signal terminal 44B is an input terminal of the second drive signal.

The signal terminal 45A is electrically connected to the signal wiring part 35A. As the signal wiring part 35A is electrically connected to the second electrodes 112 (sources) of the plurality of first semiconductor devices 11, the signal terminal 45A is electrically connected to the second electrodes 112. The signal terminal 45A is an output terminal of the first detection signal.

The signal terminal 45B is electrically connected to the signal wiring part 35B. As the signal wiring part 35B is electrically connected to the fifth electrodes 122 (sources) of the plurality of second semiconductor devices 12, the signal terminal 45B is electrically connected to the fifth electrodes 122. The signal terminal 45B is an output terminal of the second detection signal.

As illustrated in FIG. 24, each of the plurality of signal terminals 44A, 44B, 45A, 45B, 46, and 49 protrudes from a resin principal surface 61. Each of the plurality of signal terminals 44A, 44B, 45A, 45B, 46, and 49 is a press-fit terminal, for example. Each of the plurality of signal terminals 44A, 44B, 45A, 45B, 46, and 49 includes a holder and a metal pin. The holder is a cylindrical member made of a conductive material. The holder is bonded to the principal surface metal layer 242 of the signal substrate 24A or the signal substrate 24B. The metal pin is pressed into the holder, and extends in the thickness direction z.

The signal terminal 46 is disposed to stand on the signal wiring part 36. The signal terminal 46 is electrically connected to the signal wiring part 36. As the signal wiring part 36 is electrically connected to the first electrode 111 of the plurality of first semiconductor devices 11, the signal terminal 46 is electrically connected to the first electrode 111 of the plurality of first semiconductor devices 11.

The plurality of signal terminals 49 are disposed to stand on the signal wiring part 39. The plurality of signal terminals 49 is not electrically connected to the plurality of first semiconductor devices 11 or the plurality of second semiconductor devices 12. The plurality of signal terminals 49 are each a non-connect terminal.

Each of the plurality of connection members 52A, 52B, 54A, and 54B allow two separated parts to electrically connect to each other. In the semiconductor device B1, each of the plurality of connection members 52A, 52B, 54A, and 54B is a bonding wire. Each structure material of the plurality of connection members 52A, 52B, 54A, and 54B contains any one of gold, copper, and aluminum.

The plurality of connection members 52A are respectively bonded to the third electrodes 113 (gates) of the plurality of first semiconductor devices 11 and the signal wiring part 34A of a signal wiring part 38A, so as to allow the third electrode 113 and the signal wiring part 34A of the signal wiring part 38A to electrically connect to each other.

The plurality of connection members 52B are respectively bonded to the sixth electrodes 123 (gates) of the plurality of second semiconductor devices 12 and the signal wiring part 34B of a signal wiring part 38B, so as to allow the sixth electrode 123 and the signal wiring part 34B of the signal wiring part 38B to electrically connect to each other.

The plurality of connection members 54A are respectively bonded to the second electrodes 112 (sources) of the plurality of first semiconductor devices 11 and the signal wiring part 35A, so as to allow the second electrode 112 and the signal wiring part 35A to electrically connect to each other. In this way, as the signal wiring part 35A is electrically connected to the plurality of the second electrodes 112 via the connection member 54A, the signal terminals 45A are electrically connected to the plurality of the second electrodes 112, via the signal wiring part 35A and the plurality of connection members 54A.

As illustrated in FIG. 28, the plurality of connection members 54B are respectively bonded to the fifth electrodes 122 (sources) of the plurality of second semiconductor devices 12 and the signal wiring part 35B, so as to allow the fifth electrode 122 and the signal wiring part 35B to electrically connect to each other. In this way, as the signal wiring part 35B is electrically connected to the plurality of the fifth electrodes 122 via the connection member 54B, the signal terminals 45B are electrically connected to the plurality of the fifth electrodes 122, via the signal wiring part 35B and the plurality of connection members 54B.

The connection member 56 is a bonding wire, for example. A structural material of this bonding wire may be any one of gold, copper, and aluminum. As illustrated in FIG. 26, the connection member 56 is bonded to the signal wiring part 36 and the conductive substrate 23A, so as to allow these to electrically connect to each other.

The plurality of connection members 58A and 58B constitute a path of the main circuit current switched by the plurality of first semiconductor devices 11 and the plurality of second semiconductor devices 12, with the support substrate 2. The plurality of connection members 58A and 58B are constituted of a plate-like member made of metal. This metal is copper or a copper alloy, for example. The plurality of connection members 58A and 58B are partially bent.

The plurality of connection members 58A are respectively bonded to the second electrodes 112 (sources) of the plurality of first semiconductor devices 11 and the conductive substrate 23B, so as to allow the second electrodes 112 of the plurality of first semiconductor devices 11 and the conductive substrate 23B to electrically connect to each other. The connection members 58A and the second electrodes 112 of the plurality of first semiconductor devices 11, as well as the connection members 58A and the conductive substrate 23B are bonded with a conductive bonding material (e.g., solder, a metal paste material, a sintered metal, or the like). As illustrated in FIG. 26, each connection member 58A has a band-like shape extending in the first direction x in a plan view.

In the illustrated example, the number of the connection members 58A is three corresponding to the number of the first semiconductor device 11. Unlike this structure, without depending on the number of the plurality of first semiconductor devices 11, it may be possible to use one connection member 58A for the plurality of first semiconductor devices 11, for example.

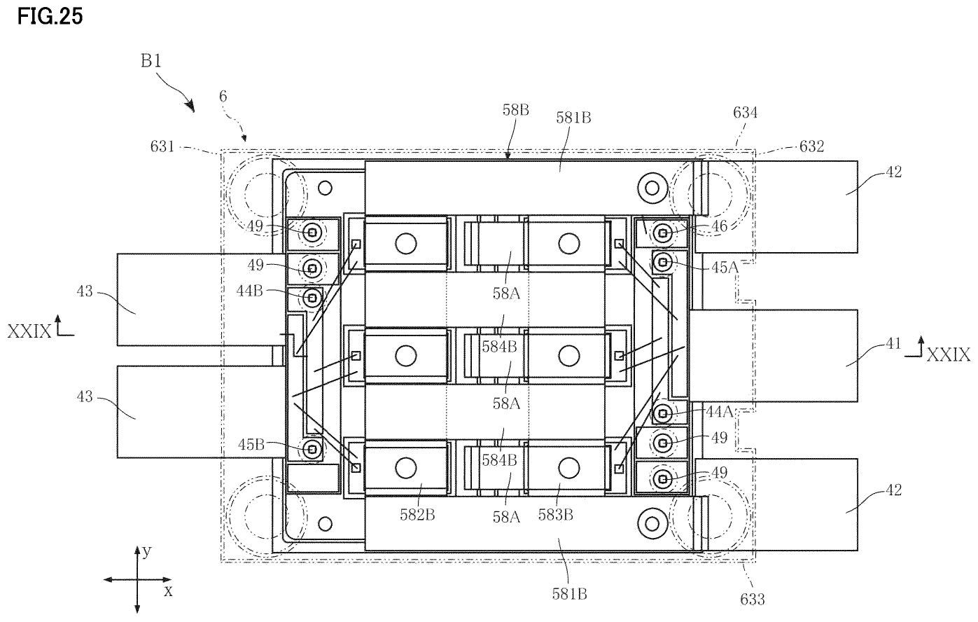

The connection member 58B allows the fifth electrodes 122 (sources) of the plurality of second semiconductor devices 12 and the power terminals 42 to electrically connect to each other. As illustrated in FIG. 25, the connection member 58B includes a pair of first wiring parts 581B, a second wiring part 582B, a third wiring part 583B, and a plurality of fourth wiring parts 584B.

One of the pair of first wiring parts 581B is connected to one of the pair of the power terminals 42, and the other of the pair of first wiring parts 581B is connected to the other of the pair of the power terminals 42. Each first wiring part 581B and each power terminal 42 are bonded to each other with a conductive bonding material (e.g., solder, a metal paste material, a sintered metal, or the like). As illustrated in FIG. 25, each of the pair of first wiring parts 581B has a band-like shape extending in the first direction x in a plan view. The pair of first wiring parts 581B are apart from each other in the second direction y and are disposed in substantially parallel.

As illustrated in FIG. 25, the second wiring part 582B is connected to both the pair of first wiring parts 581B. The second wiring part 582B is a part having a band-like shape extending in the second direction y in a plan view. As understood from FIG. 25 and FIG. 29, the second wiring part 582B overlaps the plurality of second semiconductor devices 12 in a plan view. The second wiring part 582B is connected to each second semiconductor device 12 (the fifth electrode 122) as illustrated in FIG. 29. A part of the second wiring part 582B overlapping each second semiconductor device 12 in a plan view protrudes in the thickness direction z lower than other parts. This part of the second wiring part 582B protruding downward in the thickness direction z is bonded to each fifth electrode 122 of the plurality of second semiconductor devices 12. The second wiring part 582B and each fifth electrode 122 are bonded to each other with a conductive bonding material (e.g., solder, a metal paste material, a sintered metal, or the like), for example.

As illustrated in FIG. 25, the third wiring part 583B is connected to both the pair of first wiring parts 581B. The third wiring part 583B has a band-like shape extending in the second direction y in a plan view. The third wiring part 583B is apart from the second wiring part 582B in the first direction x. The third wiring part 583B is disposed in substantially parallel to the second wiring part 582B. As understood from FIG. 25 and FIG. 29, the third wiring part 583B overlaps the plurality of first semiconductor devices 11 in a plan view. A part of the third wiring part 583B overlapping each first semiconductor device 11 in a plan view protrudes in the thickness direction z upper than the other parts. This part protruding upward in the thickness direction z forms a region to bond to each connection member 58A on each first semiconductor device 11, and the third wiring part 583B is prevented from contacting each connection member 58A.

As illustrated in FIG. 25, each of the plurality of fourth wiring parts 584B is connected to both the second wiring part 582B and the third wiring part 583B. Each fourth wiring part 584B has a band-like shape extending in the first direction x in a plan view. The plurality of fourth wiring parts 584B are apart from each other in the second direction y, and are disposed in substantially parallel to each other in a plan view. Each of the plurality of fourth wiring parts 584B has one end in the first direction x, which is connected to a part of the third wiring part 583B that overlaps between the two first semiconductor devices 11 neighboring in the second direction y in a plan view, and the other end in the first direction x, which is connected to a part of the second wiring part 582B that overlaps between the two second semiconductor devices 12 neighboring in the second direction y in a plan view.

The seal member 6 is a sealing material that protects the plurality of first semiconductor devices 11, the plurality of second semiconductor devices 12, and the like. The seal member 6 covers the plurality of first semiconductor devices 11, the plurality of second semiconductor devices 12, a part of the support substrate 2, individual parts of the plurality of power terminals 41 to 43, individual parts of the plurality of signal terminals 44A, 44B, 45A, 45B, and 49, and the plurality of connection members 52A, 52B, 54A, 54B, 56, 58A, and 58B. The seal member 6 contains an insulative resin material, for example. This insulative material is epoxy resin, for example. The seal member 6 has a black color, for example. The seal member 6 has a rectangular shape in a plan view. The seal member 6 has the resin principal surface 61, a resin back surface 62, and a plurality of resin side surfaces 631 to 634.

The resin principal surface 61 and the resin back surface 62 are apart from each other in the thickness direction z. The resin principal surface 61 faces upward in the thickness direction z, and the resin back surface 62 faces downward in the thickness direction z. Each of the plurality of resin side surfaces 631 to 634 is sandwiched between the resin principal surface 61 and the resin back surface 62 in the thickness direction z, and is connected to them. As illustrated in FIG. 25 and FIG. 29, the pair of resin side surfaces 631 and 632 face opposite directions to each other in the first direction x. The power terminals 41 and 42 protrude from the resin side surface 632, and the power terminal 43 protrudes from the resin side surface 631. As illustrated in FIG. 25, the pair of resin side surfaces 633 and 634 face opposite directions to each other in the second direction y. The plurality of signal terminals 44A, 44B, 45A, 45B, and 49 protrude from the resin principal surface 61.

FIG. 30 to FIG. 36 illustrate the first structure example of the power module of the present disclosure. A semiconductor device C1 illustrated in these diagrams corresponds to the first structure example of the power module. The words and symbols defined in FIG. 30 to FIG. 36 and descriptions with reference to these diagrams are applied only to this structure example and are defined independently from other structure examples. Relation between this structure example and other structure examples will be appropriately described separately. The semiconductor device C1 includes the plurality of first semiconductor devices 11, the plurality of second semiconductor devices 12, the support substrate 2, the plurality of terminals, the plurality of connection members, a heat radiation plate 70, a case 71, and a resin member 75. The plurality of terminals include the plurality of power terminals 41 to 43 and the plurality of signal terminals 44A, 44B, 45A, 45B, 46, and 47. The plurality of connection members include the plurality of connection members 51A, 51B, 52A, 52B, 54A, 54B, 551A, 551B, 552A, 552B, 56, and 57.

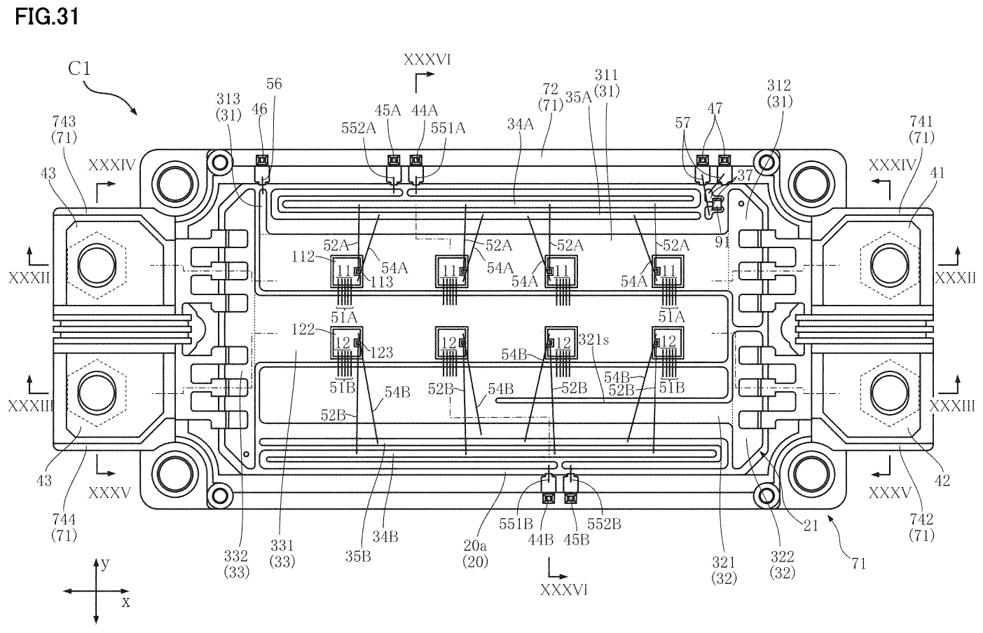

The power devices Q11 to Q13 of the first example of the device layout illustrated in FIG. 3 correspond to the plurality of first semiconductor devices 11, for example, the power supply electrode P corresponds to the power terminal 41, and the output electrode OUT corresponds to the power terminal 43. In addition, the gate electrode G of the first example of the gate wiring layout illustrated in FIG. 5 corresponds to the signal terminal 44A, the power devices Q31 to Q34 correspond to the plurality of first semiconductor devices 11, and gate wirings GL111 to GL14 correspond to conduction paths between the signal terminal 44A and the third electrodes 113 (gates) of the plurality of first semiconductor devices 11, respectively. Note that in FIG. 31, the signal terminal 44A is not positioned apart from the plurality of first semiconductor devices 11 in the first direction x, but due to the shape of the signal wiring part 34A described later, it has a similar structure of arrangement in which the signal terminal 44A is apart from the plurality of first semiconductor devices 11 in the first direction x.

As to the semiconductor device B1, the example shown above has a resin mold type module structure, in which the plurality of first semiconductor devices 11 and the plurality of second semiconductor devices 12 are covered with the seal member 6. In contrast, the semiconductor device C1 has a case type module structure, in which the plurality of first semiconductor devices 11 and the plurality of second semiconductor devices 12 are housed in the case 71.

As understood from FIG. 30 to FIG. 36, the case 71 has a rectangular solid shape, for example. The case 71 is made of a synthetic resin having electrical insulation property and is superior in heat resistance, such as polyphenylene-sulfide (PPS). In a plan view, the case 71 has a rectangular shape of the nearly same size as the heat radiation plate 70. The case 71 includes a frame part 72, a top plate 73, and a plurality of terminal blocks 741 to 744.

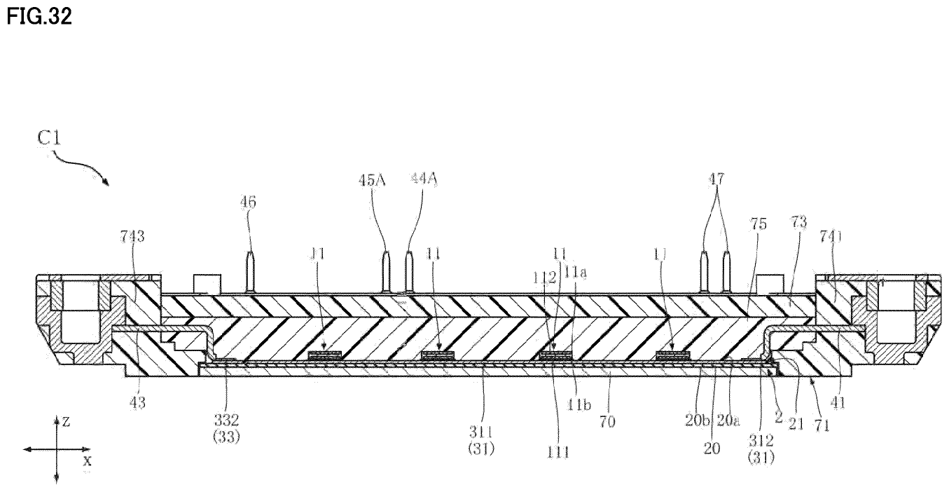

The frame part 72 is fixed to a surface above the heat radiation plate 70 in the thickness direction z. The top plate 73 is fixed to the frame part 72. As illustrated in FIGS. 30, FIG. 32, FIG. 33, and FIG. 36, the top plate 73 closes opening on the upper side of the frame part 72 in the thickness direction z. As illustrated in FIGS. 32, FIG. 33, and FIG. 36, the top plate 73 faces the heat radiation plate 70 that closes the lower side of the frame part 72 in the thickness direction z. The top plate 73, the heat radiation plate 70, and the frame part 72 define a circuit housing space (a space housing the plurality of first semiconductor devices 11, the plurality of second semiconductor devices 12, and the like) inside the case 71. In the following description, this circuit housing space may be referred to as inside of the case 71.

The two terminal blocks 741 and 742 are disposed on one side of the frame part 72 in the first direction x and is formed integrally with the frame part 72. The two terminal blocks 743 and 744 are disposed on the other side of the frame part 72 in the first direction x and is formed integrally with the frame part 72. The two terminal blocks 741 and 742 are arranged along the second direction y on a side wall of the frame part 72 on one side in the first direction x. The terminal block 741 covers a part of the power terminal 41, and as illustrated in FIG. 30, a part of the power terminal 41 is disposed on the upper surface in the thickness direction z. The terminal block 742 covers a part of the power terminal 42, and as illustrated in FIG. 30, a part of the power terminal 42 is disposed on the upper surface in the thickness direction z. The two terminal blocks 743 and 744 are arranged along the second direction y on a side wall of the frame part 72 on the other side in the first direction x. The terminal block 743 covers a part of the two power terminals 43 on one side, and as illustrated in FIG. 30, a part of the power terminal 43 is disposed on the upper surface in the thickness direction z. The terminal block 744 covers a part of the two power terminals 43 on the other side, and as illustrated in FIG. 30, a part of the power terminal 43 is disposed on the upper surface in the thickness direction z.

As illustrated in FIGS. 32, FIG. 33, and FIG. 36, the resin member 75 is filled in a space enclosed by the top plate 73, the heat radiation plate 70, and the frame part 72 (the circuit housing space described above). The resin member 75 covers the plurality of first semiconductor devices 11, the plurality of second semiconductor devices 12, and the like. The resin member 75 is made of black epoxy resin, for example. A structural material of the resin member 75 may be other insulation material such as silicone gel instead of epoxy resin. The semiconductor device C1 is not limited to the structure with the resin member 75, but may be without the resin member 75. In addition, in the structure with the resin member 75, the case 71 may not include the top plate 73.

The support substrate 2 of the semiconductor device C1 is bonded to the heat radiation plate 70. The support substrate 2 of the semiconductor device C1 includes the insulation substrate 20 and the principal surface metal layer 21. Unlike this structure, the support substrate 2 may include the back surface metal layer 22.

The principal surface metal layer 21 includes a plurality of power wiring parts 31 to 33 and the plurality of signal wiring parts 34A, 34B, 35A, 35B, 37, 38A, and 38B. The principal surface metal layer 21 of the semiconductor device C1 further includes the signal wiring part 37.

The plurality of power wiring parts 31, 32, and 33 form a conduction path of the main circuit current in the semiconductor device C1. The main circuit current includes the first main circuit current and the second main circuit current. The first main circuit current is current flowing between the power terminal 41 and the power terminal 43. The second main circuit current is current flowing between the power terminal 43 and the power terminal 42.

The power wiring part 31 is electrically connected to the first electrodes 111 (drains) of the plurality of first semiconductor devices 11. The power wiring part 31 is electrically connected to the power terminal 41. The power wiring part 31 includes pad parts 311 and 312. The two pad parts 311 and 312 are connected to each other, and are formed integrally with each other.

The plurality of first semiconductor devices 11 are mounted on the pad part 311. The pad part 311 is bonded to the first electrodes 111 (drains) of the plurality of first semiconductor devices 11. In the illustrated example, the pad part 311 has a rectangular shape whose longitudinal direction is the first direction x in a plan view. The pad part 311 extends from the pad part 312 along the first direction x.

The pad part 312 is bonded to the power terminal 41. In the illustrated example, the pad part 312 has a band-like shape whose longitudinal direction is the second direction y in a plan view. The pad part 312 is connected to the pad part 311 at an end edge on one side in the first direction x (on the side where the power terminal 41 is positioned). The power wiring part 32 includes the two pad parts 321 and 322. The two pad parts 321 and 322 are connected to each other, and are formed integrally with each other.

The power wiring part 32 is electrically connected to the fifth electrodes 122 (sources) of the plurality of second semiconductor devices 12. The power wiring part 32 is electrically connected to the power terminal 42. The power wiring part 32 includes the two pad parts 321 and 322. The two pad parts 321 and 322 are connected to each other, and are formed integrally with each other.

The pad part 321 is bonded to the plurality of connection members 51B, and are electrically connected to the fifth electrodes 122 (sources) of the plurality of second semiconductor devices 12, via the plurality of connection members 51B. The pad part 321 extends from the pad part 322 along the first direction x. In the illustrated example, the pad part 321 has a band-like shape whose longitudinal direction is the first direction x in a plan view. The pad part 321 is positioned on one side of the pad part 311 in the second direction y.

The pad part 322 is bonded to the power terminal 42. As illustrated in FIG. 31, the pad part 322 has a band-like shape whose longitudinal direction is the second direction y in a plan view. The pad part 322 is connected to an end edge of the pad part 321 on one side in the first direction x (the side where the power terminal 42 is positioned). The pad part 322 is positioned on one side of the pad part 321 in the second direction y.

The power wiring part 33 is electrically connected to the second electrodes 112 (sources) of the plurality of first semiconductor devices 11, and is electrically connected to the fourth electrodes 121 (drains) of the plurality of second semiconductor devices 12. The power wiring part 33 is electrically connected to the two power terminals 43. The power wiring part 33 includes pad parts 331 and 332.

The plurality of second semiconductor devices 12 are mounted on the pad part 331. The pad part 331 is bonded to the fourth electrodes 121 (drains) of the plurality of second semiconductor devices 12. In the illustrated example, the pad part 331 has a rectangular shape whose longitudinal direction is the first direction x in a plan view. The pad part 331 is positioned between the pad part 311 and the pad part 321 in the second direction y.

As illustrated in FIG. 31, the pair of signal wiring parts 37 are apart from each other in the second direction y. Each of the pair of signal wiring parts 37 is bonded to a thermistor 91, for example. The thermistor 91 is disposed over the pair of signal wiring parts 37. In an example different from the semiconductor device C1, the thermistor 91 may not be bonded to the pair of signal wiring parts 37. As illustrated in FIG. 31, the pair of signal wiring parts 37 is disposed in a vicinity of a corner of the insulation substrate 20. The pair of signal wiring parts 37 are disposed between the pad part 311 and the two signal wiring parts 34A and 35A in the first direction x.

The power wiring part 31 of the semiconductor device C1 includes the two pad parts 311 and 312, and further includes an extending part 313. As illustrated in FIG. 31, the extending part 313 extends in the second direction y from an end part of the pad part 311 on the other side in the first direction x (the opposite side of the side where the power terminal 41 is positioned). In the example illustrated in FIG. 31, the extending part 313 is positioned between the pad part 332 (the power wiring part 33) and the signal wiring parts 34A and 35A in a plan view.

As illustrated in FIG. 31, a slit 321s is formed in the pad part 321 of the power wiring part 32. In a plan view, the slit 321s extends along the first direction x from an end edge of the pad part 321 on one side in the first direction x (the side where the pad part 322 is positioned). A distal end of the slit 321s is positioned in the middle part of the pad part 321 in the first direction x.

As illustrated in FIG. 31, the signal terminal 46 is bonded to the connection member 56. The signal terminal 47 is electrically connected to the power wiring part 31 via the connection member 56. In this way, the signal terminal 46 is electrically connected to the first electrodes 111 (drains) of the plurality of first semiconductor devices 11. The signal terminal 46 is an output terminal of a third detection signal. The third detection signal is a voltage signal corresponding to current flowing in the power wiring part 31 (i.e., current (drain current) flowing in the first electrodes 111 (drains) of the plurality of first semiconductor devices 11). In the semiconductor device B1, the signal terminal 46 is the press-fit terminal, while in the semiconductor device C1, it is a pin-shaped metal member similarly to the other signal terminals 44A, 44B, 45A, 45B, and the like.

As illustrated in FIG. 31, the pair of signal terminals 47 are bonded to the pair of connection members 57, respectively. The pair of signal terminals 47 are electrically connected to the pair of signal wiring parts 37 via the pair of connection members 57, respectively. In this way, the pair of signal terminals 47 are electrically connected to the thermistor 91. The pair of signal terminals 47 are terminals to detect temperature inside the case 71. If the thermistor 91 is not bonded to the pair of signal wiring parts 37, the pair of signal terminals 47 are each a non-connect terminal.

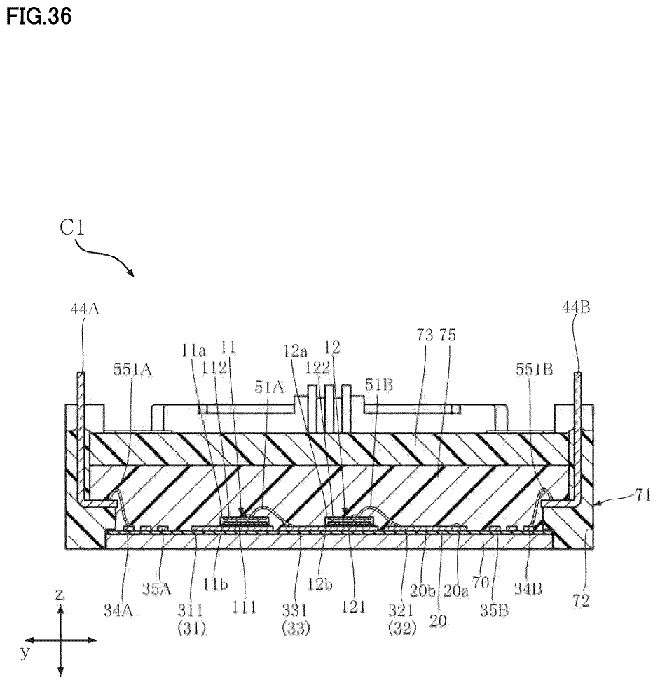

As illustrated in FIG. 31 and FIG. 36, the connection member 551A is bonded to the signal wiring part 34A and the signal terminal 44A, so as to allow these to electrically connect to each other.

As illustrated in FIG. 31 and FIG. 36, the connection member 551B is bonded to the signal wiring part 34B and the signal terminal 44B, so as to allow these to electrically connect to each other.

As illustrated in FIG. 31, the connection member 552A is bonded to the signal wiring part 35A and the signal terminal 45A, so as to allow these to electrically connect to each other.

As illustrated in FIG. 31, the connection member 552B is bonded to the signal wiring part 35B and the signal terminal 45B, so as to allow these to electrically connect to each other.

As illustrated in FIG. 31, the connection member 56 is bonded to the extending part 313 and the signal terminal 47, so as to allow the power wiring part 31 and the signal terminal 47 to electrically connect to each other. Therefore, the signal terminal 47 is electrically connected to the first electrodes 111 (drains) of the plurality of first semiconductor devices 11, via the connection member 56 and the power wiring part 31.

As illustrated in FIG. 31, the pair of connection members 57 are bonded to the pair of signal wiring parts 37 and the pair of signal terminals 47, respectively, so as to allow these to electrically connect to each other. Therefore, the pair of signal terminals 47 are electrically connected to the thermistor 91 via the pair of connection members 57 and the pair of signal wiring parts 37, respectively. If the thermistor 91 is not bonded to the pair of signal wiring parts 37, the pair of connection members 57 are not necessary.

FIG. 37 to FIG. 40 illustrate the third structure example of the power module of the present disclosure. A semiconductor device B2 illustrated in these diagrams corresponds to the third structure example of the power module. The semiconductor device B2 includes the plurality of first semiconductor devices 11, the plurality of second semiconductor devices 12, the support substrate 2, the plurality of terminals, the plurality of connection members, and the seal member 6. The plurality of terminals include the plurality of power terminals 41 to 43 and the plurality of signal terminals 44A, 44B, 45A, 45B, 46, and 49. The plurality of connection members include the plurality of connection members 52A, 52B, 53A, 53B, 54A, 54B, and 56, and the plurality of connection members 58A and 58B.

In the example (the third structure example) illustrated in FIG. 7, in which the internal gate resistor is inserted for each chip, the gate electrode G corresponds to the signal terminal 44A, the power devices Q41 to Q44 correspond to the plurality of first semiconductor devices 11, the plurality of internal gate resistors RGint correspond to the plurality of resistor elements R1, and the gate wirings GL21 to GL24 correspond to conduction paths between the signal terminal 44A and the third electrodes 113 (gates) of the plurality of first semiconductor devices 11.

The principal surface metal layer 21 of the semiconductor device B1 includes the signal wiring parts 38A and 38B.

The signal wiring part 38A is electrically connected to the third electrodes 113 (gates) of the plurality of first semiconductor devices 11.

The signal wiring part 38B is electrically connected to the sixth electrodes 123 (gates) of the plurality of second semiconductor devices 12.

Each of the signal wiring parts 38A and 38B is divided into a plurality of parts, so as to include a plurality of divided parts 381 and 382. In the following description, the plurality of divided parts 381 and 382 are common to the signal wiring parts 38A and 38B, unless otherwise noted. The plurality of divided parts 381 and 382 are apart from each other. The plurality of divided parts 381 and 382 are arranged along the second direction y.

The signal wiring part 38A includes the three divided parts 381. Each divided part 381 is connected to the connection member 52A. In this way, each divided part 381 is electrically connected to one of the third electrodes 113 (gates) of the first semiconductor devices 11.

The signal wiring part 38A includes the two divided parts 382. Each divided part 382 is disposed between the neighboring divided parts 381. The resistor elements R1 are connected to the neighboring divided parts 381 and the divided parts 382. In addition, the connection members 53A are connected to the divided parts 382 and the signal wiring part 34A. In this way, the third electrodes 113 (gates) of the plurality of first semiconductor devices 11 are electrically connected to the signal terminal 44A, via the connection member 52A, the divided part 381, the resistor element R1, the divided part 382, the connection member 53A, and the signal wiring part 34A. A specific structure of the resistor element R1 is not limited, but is a surface mount type chip resistor, for example.

The signal wiring part 38B includes the three divided parts 381. Each divided part 381 is connected to the connection member 52B. In this way, each divided part 381 is electrically connected to the sixth electrodes 123 (gates) of one of the second semiconductor devices 12.

The signal wiring part 38B includes the two divided parts 382. Each divided parts 382 is disposed between the neighboring divided parts 381. Resistor elements R2 are connected to the neighboring divided parts 381 and the divided parts 382. In addition, the connection members 53B are connected to the divided parts 382 and the signal wiring part 34B. In this way, the sixth electrodes 123 (gates) of the plurality of second semiconductor devices 12 are electrically connected to the signal terminal 44B, via the connection member 52B, the divided part 381, the resistor element R2, the divided part 382, the connection member 53B, and the signal wiring part 34B. A specific structure of the resistor element R2 is not limited, but is a surface mount type chip resistor, for example.

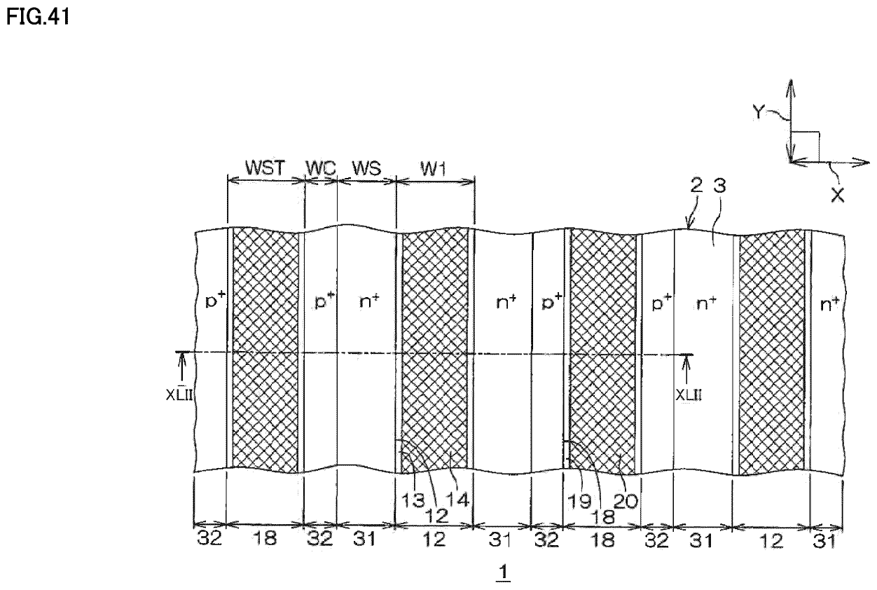

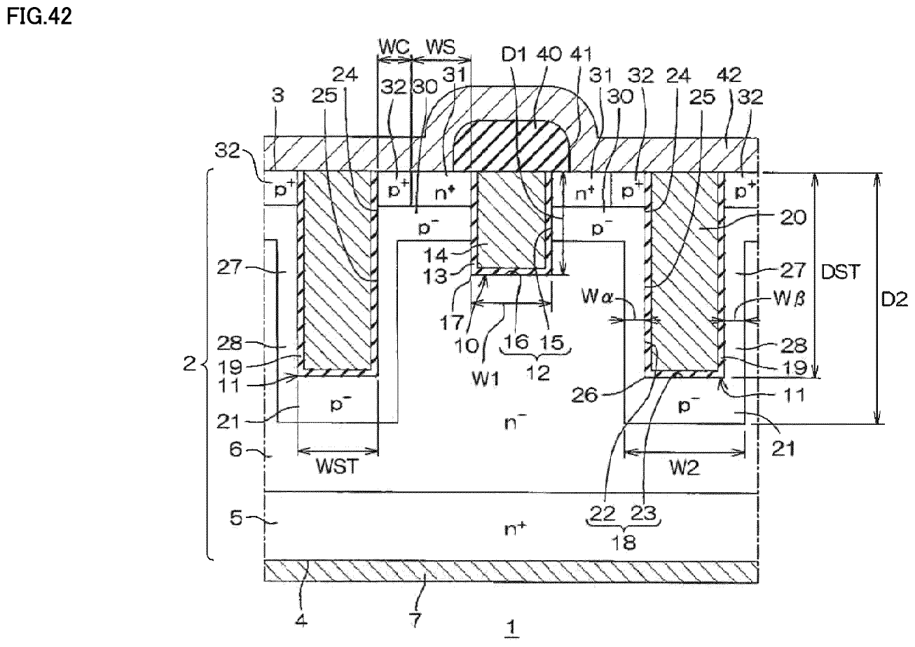

FIG. 41 and FIG. 42 illustrate the semiconductor device 1 corresponding to the structure examples of the first semiconductor device 11 and the second semiconductor device 12 of the first to third structure examples illustrated in FIG. 24 to FIG. 40. The words and symbols defined in FIG. 41 and FIG. 42 and descriptions with reference to these diagrams are applied only to this structure example and are defined independently from other structure examples. Relation between this structure example and other structure examples will be appropriately described separately.

The semiconductor device 1 is a switching device including a vertical type MISFET. With reference to FIG. 41 and FIG. 42, the semiconductor device 1 includes an n-type SiC semiconductor layer 2 containing single-crystal silicon carbide (SIC).

The SiC semiconductor layer 2 includes a first principal surface 3 on one side and a second principal surface 4 on the other side. In this embodiment, the SiC semiconductor layer 2 has a laminated structure including an SiC semiconductor substrate 5 containing single-crystal SiC and an n-minus type SiC epitaxial layer 6 containing single-crystal SiC. The SiC semiconductor substrate 5 forms the second principal surface 4 of the SiC semiconductor layer 2. The SiC epitaxial layer 6 forms the first principal surface 3 of the SiC semiconductor layer 2.

The second principal surface 4 of the SiC semiconductor layer 2 is connected to a drain electrode 7. The SiC semiconductor substrate 5 is formed as an n-plus type drain region. The SiC epitaxial layer 6 is formed as an n-minus type drain drift region. An n-type impurity concentration in the SiC semiconductor substrate 5 may be 1.0×10¹⁸ cm⁻³ or more and 1.0×10²¹ cm⁻³ or less. An n-type impurity concentration in the SiC epitaxial layer 6 may be 1.0×10¹⁵ cm⁻³ or more and 1.0×10¹⁷ cm⁻³ or less. Hereinafter, in this specification, the “impurity concentration” means a peak value of the impurity concentration.

With reference to FIG. 41 and FIG. 42, a plurality of trench gate structures 10 and a plurality of trench source structures 11 are formed in the first principal surface 3 of the SiC semiconductor layer 2. The trench gate structures 10 and the trench source structures 11 are formed alternately along an arbitrary first direction X with spaces. The trench gate structure 10 and the trench source structure 11 are each formed in a band-like shape extending in a second direction Y perpendicular to the first direction X. It is preferred that the first direction X be the [11-20] direction, and that the second direction Y be the [1-100] direction.

The first principal surface 3 of the SiC semiconductor layer 2 has a stripe structure including the plurality of trench gate structures 10 and the plurality of trench source structures 11. In the first direction X, a distance between the trench gate structure 10 and the trench source structure 11 may be 0.3 μm or more and 1.0 μm or less.

Each trench gate structure 10 includes a gate trench 12, a gate insulation layer 13, and a gate electrode layer 14. In FIG. 41, for clear illustration, the gate electrode layer 14 is shown by hatching.

The gate trench 12 is formed by digging the first principal surface 3 of the SiC semiconductor layer 2 toward the side of the second principal surface 4. The gate trench 12 includes a first side wall 15 and a first bottom wall 16.

The gate insulation layer 13 is formed in a film shape along the first side wall 15 of the gate trench 12, the first bottom wall 16, and a corner part 17 connecting the first side wall 15 and the first bottom wall 16. The gate insulation layer 13 defines a recess space in the gate trench 12.

The gate insulation layer 13 may contain silicon oxide. The gate insulation layer 13 may contain, in addition to silicon oxide, at least one of silicon without impurities, silicon nitride, aluminum oxide, aluminum nitride, and aluminum oxide nitride.

The gate electrode layer 14 is embedded in the gate trench 12 so as to sandwich the gate insulation layer 13. More specifically, the gate electrode layer 14 is embedded in the recess space defined by the gate insulation layer 13.

The gate electrode layer 14 may contain conductive polysilicon. The gate electrode layer 14 may contain, in addition to conductive polysilicon, at least one of titanium, nickel, copper, aluminum, silver, gold, titanium nitride, and tungsten.

Each trench source structure 11 includes a source trench 18, a barrier forming layer 19, a source electrode layer 20, and a p-type deep well region 21. In FIG. 41, for clear illustration, the source electrode layer 20 is shown by hatching. The deep well region 21 is also referred to as a withstand voltage holding region.

The source trench 18 is formed by digging the first principal surface 3 of the SiC semiconductor layer 2 toward the side of the second principal surface 4. The source trench 18 includes a second side wall 22 and a second bottom wall 23.

The second side wall 22 of the source trench 18 includes a first wall part 24 and a second wall part 25. The first wall part 24 of the source trench 18 is disposed on the side of the first principal surface 3 of the SiC semiconductor layer 2 with respect to the first bottom wall 16 of the gate trench 12. In other words, the first wall part 24 is a part overlapping the gate trench 12 in a lateral direction parallel to the first principal surface 3 of the SiC semiconductor layer 2.

The second wall part 25 of the source trench 18 is positioned on the side of the second principal surface 4 of the SiC semiconductor layer 2 with respect to the second bottom wall 23 of the gate trench 12. In other words, the second wall part 25 is a part positioned in a region on the side of the second principal surface 4 of the SiC semiconductor layer 2 with respect to the second bottom wall 23 of the gate trench 12, in the source trench 18.

In the thickness direction of the SiC semiconductor layer 2, a length of the second wall part 25 of the source trench 18 is more than the length of the first wall part 24 of the source trench 18. In the thickness direction of the SiC semiconductor layer 2, the second bottom wall 23 of the source trench 18 is positioned in a region between the first bottom wall 16 of the gate trench 12 and the second principal surface 4 of the SiC semiconductor layer 2.

In this embodiment, the second bottom wall 23 of the source trench 18 is positioned in the SiC epitaxial layer 6. The second bottom wall 23 of the source trench 18 may be positioned in the SiC semiconductor substrate 5.

The barrier forming layer 19 is formed in a film shape along the second side wall 22 of the source trench 18, the second bottom wall 23, and a corner part 26 connecting the second side wall 22 and the second bottom wall 23. The barrier forming layer 19 defines a recess space in the source trench 18.

The barrier forming layer 19 is made of a material different from the conductive material of the source electrode layer 20. The barrier forming layer 19 has a potential barrier higher than a potential barrier between the source electrode layer 20 and the deep well region 21.

A conductive barrier forming layer may be adopted as the barrier forming layer 19. The conductive barrier forming layer may contain at least one of conductive polysilicon, tungsten, platinum, nickel, cobalt, and molybdenum.

An insulative barrier forming layer may be adopted as the barrier forming layer 19. The insulative barrier forming layer may contain at least one of silicon without impurities, silicon oxide, silicon nitride, aluminum oxide, aluminum nitride, and aluminum oxide nitride. FIG. 42 shows an example in which the insulative barrier forming layer is formed as the barrier forming layer 19.

More specifically, the barrier forming layer 19 is silicon oxide. It is preferred that the barrier forming layer 19 and the gate insulation layer 13 are formed of the same material. In this case, it is preferred that the barrier forming layer 19 and the gate insulation layer 13 have the same thickness. If the barrier forming layer 19 and the gate insulation layer 13 are formed of silicon oxide, the barrier forming layer 19 and the gate insulation layer 13 can be formed simultaneously by a thermal oxidation treatment method.

The source electrode layer 20 is embedded in the recess space of the source trench 18 so as to sandwich the barrier forming layer 19. The source electrode layer 20 may contain conductive polysilicon. The source electrode layer 20 may be n-type polysilicon with n-type impurities, or p-type polysilicon with p-type impurities. The source electrode layer 20 may contain, in addition to conductive polysilicon, at least one of titanium, nickel, copper, aluminum, silver, gold, titanium nitride, and tungsten.

The source electrode layer 20 may be formed of the same conductive material as the gate electrode layer 14. In this case, the gate electrode layer 14 and the source electrode layer 20 can be formed simultaneously. Of course it may be possible to form the source electrode layer 20 of a conductive material different from that of the gate electrode layer 14.

The deep well region 21 is formed in a region along the source trench 18 in the SiC semiconductor layer 2. A p-type impurity concentration in the deep well region 21 may be 1.0×10¹⁷ cm⁻³ or more and 1.0×10¹⁹ cm⁻³ or less.

The deep well region 21 is formed in a region along the second side wall 22 of the source trench 18 in the SiC semiconductor layer 2. The deep well region 21 is formed in a region along the second bottom wall 23 of the source trench 18 in the SiC semiconductor layer 2.

In this embodiment, the deep well region 21 is continuously formed in a region along the second side wall 22 of the source trench 18, the corner part 26, and the second bottom wall 23 in the SiC semiconductor layer 2. The deep well region 21 includes a first region 27 and a second region 28 in a part of the source trench 18 along the second side wall 22.

The first region 27 of the deep well region 21 is formed along the second side wall 22 of the first wall part 24 of the source trench 18. The second region 28 of the deep well region 21 is formed along the second side wall 22 of the second wall part 25 of the source trench 18. In the thickness direction of the SiC semiconductor layer 2, the length of the second region 28 of the deep well region 21 is more than the length of the first region 27 of the deep well region 21.

The thickness of a part of the source trench 18 along the second bottom wall 23 in the deep well region 21 may be more than or equal to the thickness of the part of the source trench 18 along the second side wall 22 in the deep well region 21. The part of the source trench 18 along the second bottom wall 23 in the deep well region 21 may cross a boundary region between the SiC semiconductor substrate 5 and the SiC epitaxial layer 6, and may be positioned inside the SiC semiconductor substrate 5.

In the part of the source trench 18 along the second bottom wall 23 in the SiC semiconductor layer 2, p-type impurities are injected along the normal direction of the first principal surface 3 of the SiC semiconductor layer 2. On the other hand, the part of the source trench 18 along the second side wall 22 in the SiC semiconductor layer 2, p-type impurities are injected in a state inclined from the first principal surface 3 of the SiC semiconductor layer 2.

For this reason, in the part of the source trench 18 along the second bottom wall 23 in the SiC semiconductor layer 2, p-type impurities are injected into a deeper position than in the part of the source trench 18 along the second side wall 22. As a result, in the deep well region 21, there is a difference of thickness between the part of the source trench 18 along the second bottom wall 23 and the part of the source trench 18 along the second side wall 22.

A p-type body region 30 is formed in a surface layer part of the first principal surface 3 of the SiC semiconductor layer 2. The body region 30 is formed in a region between the gate trench 12 and the source trench 18. The body region 30 is formed in a band-like shape extending along the second direction Y in a plan view.

The body region 30 is exposed from the first side wall 15 of the gate trench 12 and the second side wall 22 of the source trench 18. The body region 30 is connected to the first region 27 of the deep well region 21.

A p-type impurity concentration in the body region 30 may be 1.0×10¹⁶ cm⁻³ or more and 1.0×10¹⁹ cm⁻³ or less. The p-type impurity concentration in the body region 30 may be substantially equal to the p-type impurity concentration in the deep well region 21. The p-type impurity concentration in the body region 30 may be more than the p-type impurity concentration in the deep well region 21.

An n-plus type source region 31 is formed in the surface layer part of the body region 30. The source region 31 is formed in a region along the first side wall 15 of the gate trench 12 in the surface layer part of the body region 30. The source region 31 is exposed from the first side wall 15 of the gate trench 12.

The source region 31 may be formed in a band-like shape extending along the second direction Y in a plan view. Although not illustrated, the source region 31 may include a part exposed from the second side wall 22 of the source trench 18.

A width WS of the source region 31 may be 0.2 μm or more and 0.6 μm or less (e.g., approximately 0.4 μm). In this embodiment, the width WS is a width along the first direction X in the source region 31. An n-type impurity concentration in the source region 31 may be 1.0×10¹⁸ cm⁻³ or more and 1.0×10²¹ cm⁻³ or less.

A p+ type contact region 32 is formed in the surface layer part of the body region 30. The contact region 32 is formed in a region along the second side wall 22 of the source trench 18 in the surface layer part of the body region 30. The contact region 32 is exposed from the second side wall 22 of the source trench 18.

The contact region 32 may be connected to the source region 31. The contact region 32 may be formed in a band-like shape extending along the second direction Y in a plan view. The contact region 32 may include a part exposed from the first side wall 15 of the neighboring gate trench 12.

A width WC of the contact region 32 may be 0.1 μm or more and 0.4 μm or less (e.g., approximately 0.2 μm). In this embodiment, the width WC is a width along the first direction X in the contact region 32. A p-type impurity concentration in the contact region 32 may be 1.0×10¹⁸ cm⁻³ or more and 1.0×10²¹ cm⁻³ or less.

An insulation layer 40 is formed on the first principal surface 3 of the SiC semiconductor layer 2. The insulation layer 40 covers all the plurality of trench gate structures 10. The contact hole 41 is formed in the insulation layer 40. The contact hole 41 selectively exposes the trench source structure 11, the source region 31, and the contact region 32.

A principal surface source electrode 42 is formed on the insulation layer 40. The principal surface source electrode 42 enters from the insulation layer 40 into the contact hole 41. Inside the contact hole 41, the principal surface source electrode 42 is electrically connected to the source electrode layer 20, the source region 31, and the contact region 32.

The principal surface source electrode 42 may be formed of the same conductive material as the source electrode layer 20. The principal surface source electrode 42 may be formed of a conductive material different from that of the source electrode layer 20.

In this embodiment, the source electrode layer 20 contains n-type polysilicon or p-type polysilicon, and the principal surface source electrode 42 contains aluminum or a metal material that mainly contains aluminum. The principal surface source electrode 42 may contain at least one of conductive polysilicon, titanium, nickel, copper, aluminum, silver, gold, titanium nitride, and tungsten.

The principal surface source electrode 42 may be constituted of an electrode layer formed integrally with the source electrode layer 20. In this case, the source electrode layer 20 and the principal surface source electrode 42 may be formed by a common process.

Hereinafter, a size of the trench gate structure 10 and a size of the trench source structure 11 are specifically described.

The trench gate structure 10 has an aspect ratio D1/W1. The aspect ratio D1/W1 of the trench gate structure 10 is defined as a ratio of a depth D1 of the trench gate structure 10 to a width W1 of the trench gate structure 10.

In this embodiment, the width W1 is a width along the first direction X in the trench gate structure 10. The aspect ratio D1/W1 of the trench gate structure 10 is also an aspect ratio of the gate trench 12.

The aspect ratio D1/W1 of the trench gate structure 10 may be 0.25 or more and 15.0 or less. The width W1 of the trench gate structure 10 may be 0.2 μm or more and 2.0 μm or less (e.g., approximately 0.4 μm). The depth D1 of the trench gate structure 10 may be 0.5 μm or more and 3.0 μm or less (e.g., approximately 1.0 μm).

The trench source structure 11 has an aspect ratio D2/W2. The aspect ratio D2/W2 of the trench source structure 11 is a ratio of the depth D2 of the trench source structure 11 to the width W2 of the trench source structure 11.

The width W2 of the trench source structure 11 is the sum of a width WST of the source trench 18, a first width Wa of the deep well region 21, and a second width WB of the deep well region 21 (W2=WST+Wα+Wβ).

In this embodiment, the width WST is a width along the first direction X in the source trench 18. In this embodiment, the first width Wa is a width along the first direction X of a part of the source trench 18 along the second side wall 22 on one side in the deep well region 21. In this embodiment, the second width WB is a width along the first direction X of a part of the source trench 18 along the second side wall 22 on the other side in the deep well region 21.

The aspect ratio D2/W2 of the trench source structure 11 is larger than the aspect ratio D1/W1 of the trench gate structure 10. The aspect ratio D2/W2 of the trench source structure 11 may be 0.5 or more and 18.0 or less.

A ratio D2/D1 of the depth D2 of the trench source structure 11 to the depth D1 of the trench gate structure 10 may be 1.5 or more and 4.0 or less. By increasing the depth D2 of the trench source structure 11, it is also possible to enhance withstand voltage holding effect by a super junction (SJ) structure.

The width W2 of the trench source structure 11 may be 0.6 μm or more and 2.4 μm or less (e.g., approximately 0.8 μm). The depth D2 of the trench source structure 11 may be 1.5 μm or more and 11 μm or less (e.g., approximately 2.5 μm). The width W2 of the trench source structure 11 may be equal to the width W1 of the trench gate structure 10. The width W2 of the trench source structure 11 may be different from the width W1 of the trench gate structure 10.

In the trench source structure 11, the source trench 18 has an aspect ratio DST/WST. The aspect ratio DST/WST of the source trench 18 is a ratio of the depth DST of the source trench 18 to the width WST of the source trench 18.

The aspect ratio DST/WST of the source trench 18 is larger than the aspect ratio D1/W1 of the trench gate structure 10. The aspect ratio DST/WST of the source trench 18 may be 0.5 or more and 18.0 or less.

The width WST of the source trench 18 may be 0.2 μm or more and 2.0 μm or less (e.g., approximately 0.4 μm). The width WST of the source trench 18 may be equal to the width W1 of the gate trench 12 (WST=W1).

If the width WST of the source trench 18 or the width W1 of the gate trench 12 varies along the depth direction, the width WST or the width W1 is defined as a width at an opening part. The depth DST of the source trench 18 may be 1.0 μm or more and 10 μm or less (e.g., approximately 2.0 μm).

A ratio of the depth DST of the source trench 18 to the depth D1 of the trench gate structure 10 (the gate trench 12) is preferably 2 or more. A ratio DST/D1 of the depth DST of the source trench 18 to the depth D1 of the trench gate structure 10 may be more than 4.0. In this case, it is necessary to pay attention to durability of a resist mask that is used when forming the source trench 18 by an etching method.

For instance, if the depth D1 of the trench gate structure 10 is approximately 3.0 μm and if the ratio DST/D1 is more than 4, it is predicted that the resist mask will be close to or exceed its endurance limit due to etching. If the resist mask exceeds its endurance limit, undesired etching of the SiC semiconductor layer 2 may be caused. Therefore, the ratio DST/D1 of the depth DST of the source trench 18 to the depth D1 of the trench gate structure 10 is preferably more than 1.0 and less than or equal to 4.0. If the ratio DST/D1 is within this range, the source trench 18 can be appropriately formed.

FIG. 43 to FIG. 47 illustrates the semiconductor device 1 corresponding to the structure example including the example in which the internal gate resistor is inserted adjacent to the chip illustrated in FIG. 8. The words and symbols defined in FIG. 43 to FIG. 47 and descriptions with reference to these diagrams are applied only to this structure example and are defined independently from other structure examples. Relation between this structure example and other structure examples will be appropriately described separately. The power device Q51 to Q54 of the example, in which the internal gate resistor is inserted adjacent to the chip illustrated in FIG. 8, corresponds to the semiconductor device 1 (chip 2), for example, and RGint corresponds to a gate resistor 40.

With reference to FIG. 43 to FIG. 46, the semiconductor device 1 is a semiconductor switching device including a MISFET.

In this embodiment, the semiconductor device 1 includes the chip 2, which contains a single-crystal wide bandgap semiconductor, and is formed in a hexahedron shape (specifically a rectangular solid shape). In other words, the semiconductor device 1 is a “wide bandgap semiconductor device”. The chip 2 may be referred to as a “semiconductor chip” or a “wide bandgap semiconductor chip”. The wide bandgap semiconductor is a semiconductor having a band gap larger than that of silicon (Si). Gallium nitride (GaN), silicon carbide (SiC), and diamond (C) are examples of the wide bandgap semiconductor.

In this embodiment, the chip 2 is a “SiC chip” containing hexagonal single-crystal SiC as an example of the wide bandgap semiconductor. In other words, the semiconductor device 1 is a “SiC semiconductor device”. The semiconductor device 1 may be referred to as an “SiC-MISFET”. The hexagonal single-crystal SiC includes a plurality of polytypes such as 2H (Hexagonal)-single-crystal SiC, 4H-single-crystal SiC, and 6H-single-crystal SiC. This embodiment shows an example where the chip 2 contains 4H-single-crystal SiC, but the chip 2 may contain other polytypes.

The chip 2 has the first principal surface 3 on one side, the second principal surface 4 on the other side, and first to fourth side surfaces 5A to 5D that connect the first principal surface 3 and the second principal surface 4. The first principal surface 3 and the second principal surface 4 are formed in a rectangular shape in a plan view, i.e., viewed from the normal direction Z (hereinafter, simply referred to as a “plan view”). The normal direction Z is also a thickness direction of the chip 2. The first principal surface 3 and the second principal surface 4 are preferably formed by the c-surface of single-crystal SiC.

In this case, it is preferred that the first principal surface 3 be formed by the silicon surface ((0001) surface) of single-crystal SiC, and that the second principal surface 4 be formed by the carbon surface ((000-1) surface) of the single-crystal SiC. The first principal surface 3 and the second principal surface 4 may have an off angle inclined from the c-surface in a predetermined off direction by a predetermined angle. The off direction is preferably the a-axis direction ([11-20] direction) of the single-crystal SiC. The off angle may be more than 0 degrees and less than or equal to 10 degrees. The off angle is preferably 5 degrees or less.

The first side surface 5A and the second side surface 5B extend in the first direction X along the first principal surface 3, and face each other in the second direction Y crossing (specifically perpendicular to) the first direction X. The third side surface 5C and the fourth side surface 5D extend in the second direction Y, and face each other in the first direction X. The first direction X may be the m-axis direction ([1-100] direction) of single-crystal SiC, and the second direction Y may be the a-axis direction of single-crystal SiC. Of course the first direction X may be the a-axis direction of single-crystal SiC, while the second direction Y is the m-axis direction of single-crystal SiC.

The chip 2 may have a thickness of 5 μm or more and 200 μm or less. The thickness of the chip 2 may be set to a value within any one of ranges of 5 μm or more and 100 μm or less, 100 μm or more and 125 μm or less, 125 μm or more and 150 μm or less, 150 μm or more and 175 μm or less, and 175 μm or more and 200 μm or less. The thickness of the chip 2 is preferably 100 μm or less.

The first to fourth side surface 5A to 5D may have a length of 0.5 mm or more and 20 mm or less, in a plan view. The length of the first to fourth side surface 5A to 5D may be set to a value within any one of ranges of 0.5 mm or more and 5 mm or less, 5 mm or more and 10 mm or less, 10 mm or more and 15 mm or less, and 15 mm or more and 20 mm or less. The length of the first to fourth side surface 5A to 5D is preferably 5 mm or more.

The semiconductor device 1 includes an n-type first semiconductor region 6 formed in a region (surface layer part) on the side of the first principal surface in the chip 2. The first semiconductor region 6 is formed in a layer shape extending along the first principal surface 3, and is exposed from the first principal surface 3 and the first to fourth side surfaces 5A to 5D. In this embodiment, the first semiconductor region 6 is constituted of an epitaxial layer (specifically the SiC epitaxial layer). The first semiconductor region 6 may have a thickness of 1 μm or more and 50 μm or less. The thickness of the first semiconductor region 6 is preferably 3 μm or more and 30 μm or less. It is particularly preferred that the thickness of the first semiconductor region 6 be 5 μm or more and 25 μm or less.

The semiconductor device 1 includes an n-type second semiconductor region 7 formed in a region (surface layer part) on the side of the second principal surface 4 in the chip 2. The second semiconductor region 7 is formed in a layer shape extending along the second principal surface 4 and is exposed from the second principal surface 4 and the first to fourth side surfaces 5A to 5D. The second semiconductor region 7 has an n-type impurity concentration higher than that of the first semiconductor region 6, and is electrically connected to the first semiconductor region 6.

In this embodiment, the second semiconductor region 7 is constituted of a semiconductor substrate (specifically SiC semiconductor substrate). In other words, the chip 2 has a laminated structure including a semiconductor substrate and an epitaxial layer. The second semiconductor region 7 has a thickness of 1 μm or more and 200 μm or less. The thickness of the second semiconductor region 7 may be 150 μm or less, 100 μm or less, 50 μm or less, or 40 μm or less. The thickness of the second semiconductor region 7 may be 5 μm or more. The thickness of the second semiconductor region 7 is preferably 10 μm or more. In this embodiment, the second semiconductor region 7 has a thickness more than that of the first semiconductor region 6.

The semiconductor device 1 has an active surface 8, an outer surface 9, and first to fourth connecting surfaces 10A to 10D, which are formed on the first principal surface 3. The active surface 8, the outer surface 9, and the first to fourth connecting surfaces 10A to 10D define an active plateau 11 on the first principal surface 3. The active surface 8 may be referred to as a “first surface part”, the outer surface 9 may be referred to as a “second surface part”, and the first to fourth connecting surfaces 10A to 10D may be referred to as a “connecting surface part”. The active surface 8, the outer surface 9, and the first to fourth connecting surfaces 10A to 10D (i.e., the active plateau 11) may be regarded as components of the chip 2 (the first principal surface 3).

The active surface 8 is formed inside a periphery of the first principal surface 3 (the first to fourth side surfaces 5A to 5D) with a space between them. The active surface 8 has a flat surface extending in the first direction X and in the second direction Y. In this embodiment, the active surface 8 is formed by the c-surface (Si surface). In this embodiment, the active surface 8 is formed in a rectangular shape having four sides parallel to the first to fourth side surfaces 5A to 5D, respectively, in a plan view.

The outer surface 9 is positioned outside the active surface 8 and is recessed from the active surface 8 in the thickness direction of the chip 2 (toward the side of the second principal surface 4). Specifically, the outer surface 9 is recessed by a depth less than the thickness of the first semiconductor region 6, so as to expose the first semiconductor region 6. The outer surface 9 extends in a band-like shape along the active surface 8, and is formed in a ring shape (specifically in a rectangular ring shape) surrounding the active surface 8, in a plan view.

The outer surface 9 has a flat surface extending in the first direction X and in the second direction Y and is formed substantially in parallel to the active surface 8. In this embodiment, the outer surface 9 is formed by the c-surface (Si surface). The outer surface 9 is connected to the first to fourth side surfaces 5A to 5D. The outer surface 9 has an outer periphery depth DO. The outer periphery depth DO may be 0.1 μm or more and 5 μm or less. The outer periphery depth DO is preferably 2.5 μm or less.

The first to fourth connecting surfaces 10A to 10D extend in the normal direction Z, so as to connect the active surface 8 and the outer surface 9. The first connecting surface 10A is positioned on the side of the first side surface 5A, the second connecting surface 10B is positioned on the side of the second side surface 5B, the third connecting surface 10C is positioned on the side of the third side surface 5C, and the fourth connecting surface 10D is positioned on the fourth side surface 5D. The first connecting surface 10A and the second connecting surface 10B extend in the first direction X, and face each other in the second direction Y. The third connecting surface 10C and the fourth connecting surface 10D extend in the second direction Y, and face each other in the first direction X.

The first to fourth connecting surfaces 10A to 10D may extend substantially vertically between the active surface 8 and the outer surface 9, so as to define the active plateau 11 having a quadrangular prism shape. The first to fourth connecting surfaces 10A to 10D may be inclined diagonally downward from the active surface 8 to the outer surface 9, so as to define the active plateau 11 having a square pyramid shape. In this way, the semiconductor device 1 has the active plateau 11 defined in a protruding shape in the first semiconductor region 6 on the first principal surface 3. The active plateau 11 is formed only in the first semiconductor region 6 and is not formed in the second semiconductor region 7.

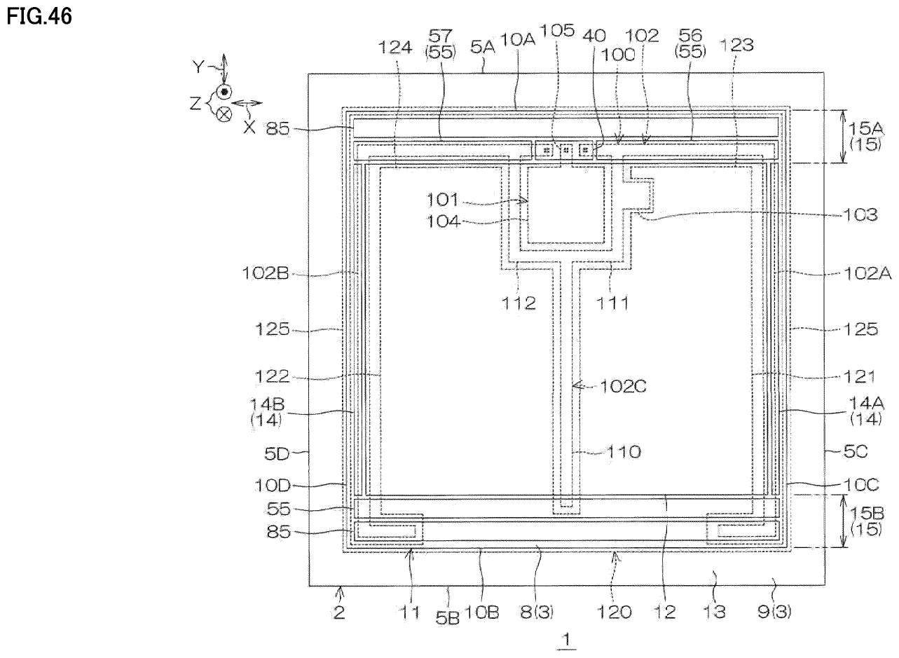

With reference to FIG. 46, the semiconductor device 1 has an active region 12, an outer periphery region 13, a periphery region 14, and a termination region 15. The active region 12 is disposed on the active surface 8. Specifically, the active region 12 is disposed at an inside part of the active surface 8 with a space from the periphery of the active surface 8 (the first to fourth connecting surfaces 10A to 10D). In this embodiment, the active region 12 is formed in a rectangular shape having four sides parallel to the first to fourth side surfaces 5A to 5D in a plan view. The outer periphery region 13 is disposed on the outer surface 9. In this embodiment, the outer periphery region 13 is disposed in a ring shape (specifically in a rectangular ring shape) surrounding the active surface 8 (the active plateau 11), in a plan view.

The periphery region 14 is disposed on the active surface 8 in a region between the active region 12 and the outer periphery region 13. The periphery region 14 is disposed so as to sandwich the active region 12 from both sides in the first direction X, and extends in the second direction Y in a band-like shape. The periphery region 14 includes a first periphery region 14A and a second periphery region 14B. The first periphery region 14A is disposed on the side of the third side surface 5C (on the side of the third connecting surface 10C) with respect to the active region 12, and the second periphery region 14B is disposed on the side of the fourth side surface 5D (on the side of the fourth connecting surface 10D) with respect to the active region 12.

The termination region 15 is disposed on the active surface 8 in the region between the active region 12 and the outer periphery region 13. The termination region 15 is disposed to sandwich the active region 12 from both sides in the second direction Y and extends in the first direction X in a band-like shape. The termination region 15 includes a first termination region 15A and a second termination region 15B. The first termination region 15A is disposed on the side of the first side surface 5A (on the side of the first connecting surface 10A) with respect to the active region 12, and the second termination region 15B is disposed on the side of the second side surface 5B (on the side of the second connecting surface 10B) with respect to the active region 12.

The semiconductor device 1 includes a principal surface insulation film 16 that covers the first principal surface 3. The principal surface insulation film 16 selectively covers the active surface 8, the outer surface 9, and the first to fourth connecting surfaces 10A to 10D. The principal surface insulation film 16 may include at least one of silicon oxide film, silicon nitride film, and silicon oxide nitride film.

In this embodiment, the principal surface insulation film 16 has a single layer structure constituted of silicon oxide film. It is particularly preferred that the principal surface insulation film 16 include silicon oxide film made of the oxide of the chip 2. In this embodiment, the principal surface insulation film 16 is connected to the first to fourth side surfaces 5A to 5D. Of course, the wall part of the principal surface insulation film 16 may be formed inside the periphery of the outer surface 9 with a space between them, so as to expose the first semiconductor region 6 from the periphery part of the outer surface 9.

The semiconductor device 1 includes the gate resistor 40 formed on the first principal surface 3 (the active surface 8) in the first termination region 15A. The gate resistor 40 is incorporated in the chip 2 (the first termination region 15A) as a resistor that is electrically connected to the gate of the MISFET.

The gate resistor 40 is disposed in a region on the side of the first side surface 5A (on the side of the first connecting surface 10A) with respect to the active region 12, and faces the active region 12 in the second direction Y. The gate resistor 40 is disposed with a space in the first direction X from the periphery region 14, so as not to face the periphery region 14 in the second direction Y. In this embodiment, the gate resistor 40 is disposed between the middle part of the first side surface 5A (the first connecting surface 10A) and the active region 12.

The gate resistor 40 includes at least one (a plurality in this embodiment) of trench resistor structures formed on the first principal surface 3 (the active surface 8) in the first termination region 15A. The plurality of trench resistor structures are applied with a gate potential VG as a first potential, but the plurality of trench resistor structures do not contribute to channel control.

The gate resistor 40 includes a resistor film that covers at least one of (in this embodiment, a plurality of) the trench resistor structures on the first principal surface 3 (the active surface 8). The resistor film includes at least one of conductive polysilicon film and alloy crystal film. The alloy crystal film contains alloy crystals made of a metal element and a non-metal element. The alloy crystal film may include at least one of CrSi film, CrSiN film, CrSiO film, TaN film, and TiN film. In this embodiment, the resistor film contains conductive polysilicon. The resistor film may be formed by a CVD method, for example.

The resistor film has a resistor thickness in the normal direction Z. The resistor thickness is appropriately adjusted in accordance with a resistance value to be obtained. In other words, the resistance value of the resistor film is adjusted by increasing or decreasing the resistor thickness and by increasing or decreasing the length in the first direction X.

According to a resistor thickness TR satisfying this condition, when forming the conductive polysilicon film that covers the first principal surface 3 (the active surface 8) by filling a first trench 44 and a second trench 47 by the CVD method, the first embedded electrode 46, the second embedded electrode 49, and the resistor film can be formed using a part of the conductive polysilicon film.

The semiconductor device 1 includes a dummy structure 55 formed on the first principal surface 3 (the active surface 8) in the first termination region 15A. The dummy structure 55 is incorporated in the active surface 8 (the first termination region 15A), for a purpose of easing local electric field concentration in a vicinity of the gate resistor 40, so as to improve the withstand voltage (e.g., breakdown voltage). Presence or absence of the dummy structure 55 is arbitrary, and it may be possible to adopt an embodiment without the dummy structure 55.

The dummy structure 55 includes a first dummy structure 56 and a second dummy structure 57. The first dummy structure 56 is disposed in a region on the side of the third side surface 5C (on the side of the third connecting surface 10C) with respect to the gate resistor 40. The second dummy structure 57 faces the first dummy structure 56 in the first direction X with the gate resistor 40 between them, and faces the active region 12 and the second periphery region 14B in the second direction Y.

The semiconductor device 1 includes a termination dummy structure 85 formed on the first principal surface 3 (the active surface 8) in the first termination region 15A. The termination dummy structure 85 is incorporated in the active surface 8 (the first termination region 15A), for a purpose of easing local electric field concentration in a vicinity of the gate resistor 40, so as to improve the withstand voltage (e.g., breakdown voltage). Presence or absence of the termination dummy structure 85 is arbitrary, and it may be possible to adopt an embodiment without the termination dummy structure 85.

With reference to FIG. 46 again, the semiconductor device 1 includes the dummy structure 55 and the termination dummy structure 85, which are formed on the first principal surface 3 (the active surface 8) in the second termination region 15B. The semiconductor device 1 does not include the gate resistor 40 in the second termination region 15B. The dummy structure 55 on the side of the second termination region 15B is formed in a region on the side of the fourth side surface 5D (on the side of the fourth connecting surface 10D) with respect to the active region 12, and faces the active region 12 and the periphery region 14 in the second direction Y.

The semiconductor device 1 includes a side wall wiring 95 formed on the outer surface 9 so as to cover at least one of the first to fourth connecting surfaces 10A to 10D. Specifically, the side wall wiring 95 is disposed on the principal surface insulation film 16. The side wall wiring 95 functions also as a side wall structure that eases a step difference formed between the active surface 8 and the outer surface 9.

The semiconductor device 1 includes an inter-layer insulation film 99 that covers the principal surface insulation film 16. The inter-layer insulation film 99 covers the active surface 8, the outer surface 9, and the first to fourth connecting surfaces 10A to 10D, sandwiching the principal surface insulation film 16.

The inter-layer insulation film 99 covers the resistor film in the first termination region 15A. The inter-layer insulation film 99 covers the side wall wiring 95 in the first to fourth connecting surfaces 10A to 10D.

In this embodiment, the inter-layer insulation film 99 is connected to the first to fourth side surfaces 5A to 5D. Of course, it is possible to form the wall part of the inter-layer insulation film 99 inside the periphery of the outer surface 9 with a space between them, so as to expose the first semiconductor region 6 from the periphery part of the outer surface 9. The inter-layer insulation film 99 may include at least one of silicon oxide film, silicon nitride film, and silicon oxide nitride film. In this embodiment, the inter-layer insulation film 99 includes silicon oxide film.

The semiconductor device 1 includes a gate electrode 100 disposed on the inter-layer insulation film 99. The gate electrode 100 has a resistance value less than that of the gate resistor 40. In addition, the gate electrode 100 has a resistance value less than that of the resistor film.

The gate electrode 100 may include at least one of Ti film, TiN film, W film, Al film, Cu film, Al alloy film, Cu alloy film, and conductive polysilicon film. The gate electrode 100 may include at least one of pure Cu film (Cu film having a purity of 99% or more), pure Al film (Al film having a purity of 99% or more), Al—Cu alloy film, Al—Si alloy film, and Al—Si—Cu alloy film. In this embodiment, the gate electrode 100 has a laminated structure including Ti film and Al alloy film (Al—Si—Cu alloy film in this embodiment) laminated in this order from the side of the chip 2. The gate electrode 100 may be referred to as a “gate metal”.

In this embodiment, the gate electrode 100 includes a gate pad 101, a gate wiring 102, and a gate sub pad 103. The gate pad 101 is applied with the gate potential VG from the outside. In this embodiment, the gate pad 101 is disposed in a region along the middle part of the first connecting surface 10A in a plan view.

The gate pad 101 is positioned in a region that overlaps with the gate resistor 40 in a plan view. In this embodiment, the gate pad 101 is formed with a space from the dummy structure 55 and the termination dummy structure 85 in a plan view. Of course it may be possible to dispose the gate pad 101 in a region that overlaps with one of or both of the dummy structure 55 and the termination dummy structure 85 in a plan view.

The gate pad 101 penetrates the inter-layer insulation film 99 in the first termination region 15A, so as to be electrically connected to the gate resistor 40. Specifically, the gate pad 101 penetrates the inter-layer insulation film 99 and is connected to the resistor film. In this embodiment, the gate pad 101 penetrates the inter-layer insulation film 99 and is connected to the middle part of the resistor film.

In this embodiment, the gate pad 101 includes a pad main body part 104 and a lead-out part 105. The pad main body part 104 is a part to which the gate potential VG is applied from the outside. In this embodiment, the pad main body part 104 is disposed on a part of the inter-layer insulation film 99 that covers the active region 12 and faces the gate resistor 40 in the second direction Y in a plan view.

In this embodiment, the pad main body part 104 is formed to have a larger width than the gate resistor 40 (a trench gate structure 20) in the first direction X.

In this embodiment, the pad main body part 104 is formed in a rectangular shape in a plan view. The pad main body part 104 is preferably has a plane area of 25% or less of that of the first principal surface 3. The plane area of the pad main body part 104 is preferably 10% or less of that of the first principal surface 3.

The lead-out part 105 is a part that electrically connects the pad main body part 104 to the gate resistor 40. The lead-out part 105 is led out in a band-like shape from the pad main body part 104 to a part of the inter-layer insulation film 99 that covers the gate resistor 40. In this embodiment, the lead-out part 105 is formed to have a smaller width than the pad main body part 104 in the first direction X. Specifically, the lead-out part 105 is formed to have a smaller width than the gate resistor 40 in the first direction X.

The lead-out part 105 is connected to the gate resistor 40 via a first resistor opening 106 formed in the inter-layer insulation film 99. Specifically, the lead-out part 105 is connected to the resistor film in the first resistor opening 106.

In this way, the pad main body part 104 is electrically connected to the resistor film via the lead-out part 105.

The gate wiring 102 is selectively wired from the first termination region 15A to the active region 12, so as to transmit the gate potential VG applied to the gate pad 101 to the gate of the MISFET. In this embodiment, the gate wiring 102 is disposed on an inner part of the active surface 8 with a space from the periphery of the active surface 8 and is not disposed on the outer surface 9.

In this embodiment, the gate wiring 102 is disposed on the inter-layer insulation film 99 with a space from the gate pad 101 in the first termination region 15A. The gate wiring 102 penetrates the inter-layer insulation film 99 at a position different from the gate pad 101 and is electrically connected to the gate resistor 40. Specifically, the gate wiring 102 penetrates the inter-layer insulation film 99 and is connected to the resistor film.

In this embodiment, the gate wiring 102 includes a first gate wiring 102A, a second gate wiring 102B, and a third gate wiring 102C. The first gate wiring 102A is disposed in a region on the side of the third connecting surface 10C with respect to the gate pad 101 and extends in a line shape along the first connecting surface 10A and the third connecting surface 10C. The first gate wiring 102A is electrically connected to the gate pad 101 via the gate resistor 40 in the first termination region 15A and is electrically connected to the gate of the MISFET in the active region 12.

The second gate wiring 102B is disposed in a region on the side of the fourth connecting surface 10D with respect to the gate pad 101 and extends in a line shape along the first connecting surface 10A and the fourth connecting surface 10D. The second gate wiring 102B is electrically connected to the gate pad 101 via the gate resistor 40 in the first termination region 15A and is electrically connected to the gate of the MISFET in the active region 12.

The third gate wiring 102C is disposed in a region on the side of the second connecting surface 10B with respect to the gate pad 101 and extends in a line shape along the second direction Y in a region between the gate pad 101 and the second connecting surface 10B. In this embodiment, the third gate wiring 102C is connected to the first gate wiring 102A and the second gate wiring 102B in the first termination region 15A and is electrically connected to the gate of the MISFET in the active region 12.

The third gate wiring 102C includes a line part 110, a first branch part 111, and a second branch part 112. The line part 110 extends in a line shape along the second direction Y in the region between the gate pad 101 and the second connecting surface 10B. The line part 110 includes a first terminal part on the side of the gate pad 101, and a second terminal part on the side of the second connecting surface 10B. The first terminal part is formed with a space from the gate pad 101 to the side of the second connecting surface 10B. The second terminal part is formed with a space from the second connecting surface 10B to the side of the gate pad 101.

The line part 110 is electrically connected to the plurality of trench gate structures 20 via a plurality of gate opening 108 formed in the inter-layer insulation film 99. A plurality of gate connecting electrode films 39 may be formed, which cover inner parts of the plurality of trench gate structures 20. In this case, the line part 110 is electrically connected to the gate of the MISFET via the plurality of gate connecting electrode films 39.

The first branch part 111 connects the line part 110 and the first gate wiring 102A. The first branch part 111 is led out from the first terminal part of the line part 110 to one side (the side of the third connecting surface 10C) and extends in a band-like shape along the gate pad 101. The first branch part 111 is connected to a part of the first gate wiring 102A that covers the dummy structure 55 (the first dummy structure 56).

The second branch part 112 connects the line part 110 and the second gate wiring 102B. The second branch part 112 is led out from the first terminal part of the line part 110 to the other side (the side of the fourth connecting surface 10D) and extends in a band-like shape along the periphery of the gate pad 101. The second branch part 112 faces the first branch part 111 in the first direction X so as to sandwich the gate pad 101. The second branch part 112 is connected to the part of the second gate wiring 102B that covers the dummy structure 55 (the second dummy structure 57).

The gate sub pad 103 is disposed on the inter-layer insulation film 99 so as to be electrically connected to the gate pad 101 via the gate resistor 40. In this embodiment, the gate sub pad 103 is disposed with a space from the gate pad 101 to the side of the third connecting surface 10C, and faces the gate pad 101 in the first direction X.

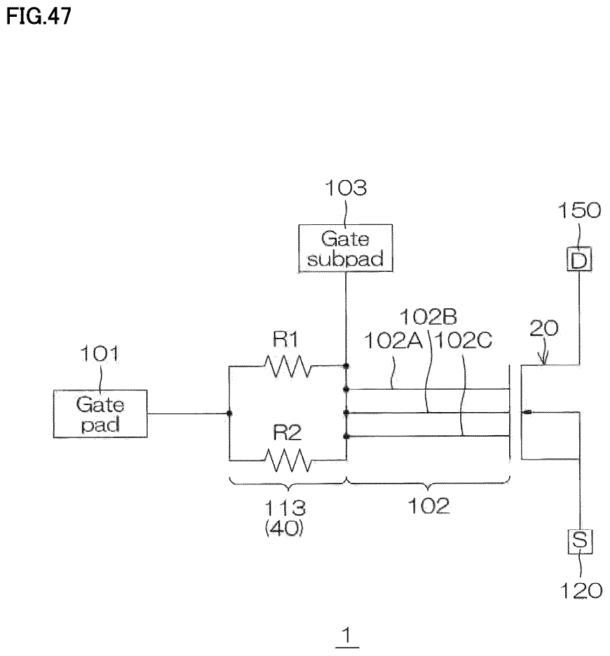

Hereinafter, with reference to FIG. 47, a connection configuration of the gate electrode 100 and the gate resistor 40 is described. FIG. 47 is an electrical circuit diagram illustrating the connection configuration of the gate electrode 100 and the gate resistor 40. In FIG. 47, the trench gate structure 20 is shown by a circuit symbol indicating the MISFET.

With reference to FIG. 47, the gate wiring 102 is electrically connected to the gate pad 101 via the gate resistor 40. In this embodiment, the gate resistor 40 includes a resistor parallel circuit 113 constituted of a first resistor part R1 and a second resistor part R2. The first resistor part R1 is formed of a part of the gate resistor 40 that is positioned between a connection part of the gate pad 101 and a connection part of the first gate wiring 102A. On the other hand, the second resistor part R2 is formed of a part of the gate resistor 40 that is positioned between a connection part of the gate pad 101 and a connection part of the second gate wiring 102B.

In other words, the first gate wiring 102A is electrically connected to the gate pad 101 via the first resistor part R1, and the second gate wiring 102B is electrically connected to the gate pad 101 via the second resistor part R2. The resistance value of the first resistor part R1 is adjusted by increasing or decreasing the distance between the connection part of the gate pad 101 and the connection part of the first gate wiring 102A.

The resistance value of the second resistor part R2 is adjusted by increasing or decreasing the distance between the connection part of the gate pad 101 and the connection part of the second gate wiring 102B. The resistance value of the second resistor part R2 may be more than or equal to the resistance value of the first resistor part R1 or may be less than the resistance value of the first resistor part R1, or may be substantially the same as the resistance value of the first resistor part R1.

In this embodiment, the second gate wiring 102B is electrically connected to the trench gate structure 20 that is electrically connected to the first gate wiring 102A. Therefore, the second resistor part R2 is connected in parallel to the first resistor part R1, and thus the resistor parallel circuit 113 is formed. In this embodiment, the third gate wiring 102C is electrically connected to the trench gate structure 20 that is electrically connected to the first gate wiring 102A and the second gate wiring 102B.

Therefore, one gate wiring 102 including the first to third gate wirings 102A to 102C is electrically connected to the resistor parallel circuit 113 and the gate of the MISFET. The resistance value of the gate resistor 40 (i.e., the resistance value between the gate pad 101 and the gate wiring 102) is indirectly measured by measuring the resistance value between the gate pad 101 and the gate sub pad 103.

The gate resistor 40 delays switching speed in the switching operation so as to suppress surge current. In other words, the gate resistor 40 suppress noise due to the surge current. The gate resistor 40 is formed in the first principal surface 3 (the active surface 8), and hence is not externally connected to the semiconductor device 1. Therefore, by incorporating the gate resistor 40 in the first principal surface 3, the number of components mounted on the circuit substrate can be reduced.

The gate resistor 40 has the trench resistor structure incorporated in the thickness of the chip 2 direction, and hence an occupation area of the gate resistor 40 in the first principal surface 3 is limited. Therefore, reduction of the area of the active region 12 due to introduction of the gate resistor 40 is suppressed. In particular, as the gate resistor 40 is disposed in the termination region 15, the reduction of the area of the active region 12 is appropriately suppressed.

In this embodiment, the gate resistor 40 has the same structure as the side of the active region 12. Therefore, electrical influence of the gate resistor 40 on the active region 12 is suppressed, and electrical influence of the active region 12 on the gate resistor 40 is suppressed. In this way, fluctuation of electrical characteristics on the side of the active region 12 is suppressed, and fluctuation of electrical characteristics on the side of the gate resistor 40 is suppressed.

The gate resistor 40 is not necessarily required to have the resistor parallel circuit 113 including the first resistor part R1 and the second resistor part R2. Therefore, the gate resistor 40 may be constituted of only the first resistor part R1 or the second resistor part R2. This form is achieved by changing connection configuration of the gate wiring 102 to the gate resistor 40.

For instance, if the gate resistor 40 is constituted of only the first resistor part R1, the gate wiring 102 (the second gate wiring 102B) should be electrically separated from the gate resistor 40. In addition, if the gate resistor 40 is constituted of only the second resistor part R2, the gate wiring 102 (the first gate wiring 102A) should be electrically separated from the gate resistor 40. The gate wiring 102 is not required to simultaneously include all the first to third gate wirings 102A to 102C, but it is sufficient to include at least one of the first to third gate wirings 102A to 102C.

The semiconductor device 1 includes a source electrode 120 disposed on the inter-layer insulation film 99 with a space from the gate electrode 100. The source electrode 120 has a resistance value lower than the resistance value of the gate resistor 40. The source electrode 120 is preferably thicker than the resistor film. The source electrode 120 is preferably thicker than the inter-layer insulation film 99. The source electrode 120 may have a thickness of 0.5 mm or more and 10 μm or less. The thickness of the source electrode 120 is preferably 1 μm or more and 5 μm or less. It is preferred that the thickness of the source electrode 120 be substantially equal to the thickness of the gate electrode 100.

The source electrode 120 may include at least one of Ti film, TiN film, W film, Al film, Cu film, Al alloy film, Cu alloy film, and conductive polysilicon film. The source electrode 120 may include at least one of pure Cu film (Cu film having a purity of 99% or more), pure Al film (Al film having a purity of 99% or more), Al—Cu alloy film, Al—Si alloy film, and Al—Si—Cu alloy film. In this embodiment, the source electrode 120 has a laminated structure including Ti film and Al alloy film (Al—Si—Cu alloy film in this embodiment), which are laminated in this order from the side of the chip 2. The source electrode 120 may be referred to as a “source metal”.

In this embodiment, the source electrode 120 includes a first source pad 121, a second source pad 122, a first source sub pad 123, a second source sub pad 124, and a source wiring 125. The first source pad 121 is applied with a source potential VS for a main source from the outside. The first source pad 121 is disposed in a region between the first gate wiring 102A and the third gate wiring 102C on a part of the inter-layer insulation film 99 that covers the active region 12.

The semiconductor device 1 includes an upper insulation film 130 that selectively covers the gate electrode 100, the source electrode 120, and the inter-layer insulation film 99 on the first principal surface 3. The upper insulation film 130 includes a gate pad opening 131 that exposes an inner part of the gate pad 101, and a gate sub pad opening 132 that exposes an inner part of the gate sub pad 103.

The upper insulation film 130 covers a periphery part of the gate pad 101, a periphery part of the gate sub pad 103, and all region of the gate wiring 102. The gate pad opening 131 is formed in a rectangular shape in a plan view. The gate sub pad opening 132 is formed in a rectangular shape in a plan view. The gate sub pad opening 132 has a plane area smaller than that of the gate pad opening 131.

The upper insulation film 130 includes a first source pad opening 133 that exposes an inner part of the first source pad 121, a second source pad opening 134 that exposes an inner part of the second source pad 122, a first source sub pad opening 135 that exposes an inner part of the first source sub pad 123, and a second source sub pad opening 136 that exposes an inner part of the second source sub pad 124. The upper insulation film 130 covers a periphery part of the first source pad 121, a periphery part of the second source pad 122, a periphery part of the first source sub pad 123, a periphery part of the second source sub pad 124, and all region of the source wiring 125.

The upper insulation film 130 is formed inside the periphery of the chip 2 (the first to fourth side surfaces 5A to 5D) with a space between them, so as to define a dicing street 137 between itself and the periphery of the chip 2. The dicing street 137 is formed in a band-like shape extending along the periphery of the chip 2 in a plan view. In this embodiment, the dicing street 137 is formed in a ring shape (specifically in a rectangular ring shape) surrounding the active surface 8 in a plan view. In this embodiment, the dicing street 137 exposes the inter-layer insulation film 99.

Of course, if the principal surface insulation film 16 and the inter-layer insulation film 99 expose the outer surface 9, the dicing street 137 may expose the outer surface 9. The dicing street 137 may have a width of 1 μm or more and 200 μm or less. The width of the dicing street 137 is a width in the direction perpendicular to the extending direction of the dicing street 137. The width of the dicing street 137 is preferably 5 μm or more and 50 μm or less.

The upper insulation film 130 preferably has a thickness more than the thickness of the gate electrode 100 and the thickness of the source electrode 120. The thickness of the upper insulation film 130 is preferably less than the thickness of the chip 2. The thickness of the upper insulation film 130 may be 3 μm or more and 35 μm or less. The thickness of the upper insulation film 130 is preferably 25 μm or less.

In this embodiment, the upper insulation film 130 has a laminated structure including an inorganic insulation film 140 and an organic insulation film 141 laminated in this order from the side of the chip 2. The upper insulation film 130 is sufficient to include at least one of the inorganic insulation film 140 and the organic insulation film 141, and is not required to simultaneously include the inorganic insulation film 140 and the organic insulation film 141.

The inorganic insulation film 140 may also include at least one of silicon oxide film, silicon nitride film, and silicon oxide nitride film. The inorganic insulation film 140 preferably includes an insulation material different from the inter-layer insulation film 99. The inorganic insulation film 140 is preferably includes silicon nitride film. The inorganic insulation film 140 preferably has a thickness less than the thickness of the inter-layer insulation film 99. The thickness of the inorganic insulation film 140 may be 0.1 μm or more and 5 μm or less.

The organic insulation film 141 is preferably constituted of a resin film other than thermosetting resin film. The organic insulation film 141 may be made of translucent resin or transparent resin. The organic insulation film 141 may be constituted of a photosensitive resin film of a negative type or a positive type. The organic insulation film 141 is preferably constituted of a polyimide film, a polyamide film, or a polybenzoxazole film. In this embodiment, the organic insulation film 141 includes polybenzoxazole film.

The semiconductor device 1 includes a drain electrode 150 that covers the second principal surface 4. The drain electrode 150 forms ohmic contact with the second semiconductor region 7 exposed from the second principal surface 4. The drain electrode 150 may cover all region of the second principal surface 4, so as to connect to the periphery of the chip 2 (the first to fourth side surfaces 5A to 5D). The breakdown voltage that can be applied between the source electrode 120 and the drain electrode 150 (between the first principal surface 3 and the second principal surface 4) may be 500 V or more and 3000 V or less.

In FIG. 41 and FIG. 42, a plurality of trench structures are formed on the first principal surface 3 of the SiC semiconductor layer 2, but a planar structure may be used instead of the trench structure. In addition, a single trench structure may be used instead of a double trench structure.

In addition, in the semiconductor device 1 described above, a zig-zag structure or a grid-like structure including the plurality of trench gate structures 10 and the plurality of trench source structures 11 may be formed on the first principal surface 3 of the n-type SiC semiconductor layer 2, which contains silicon carbide (SiC) single-crystal. In the first direction X, the distance between the trench gate structure 10 and the trench source structure 11 may be 0.3 μm or more and 1.0 μm or less.

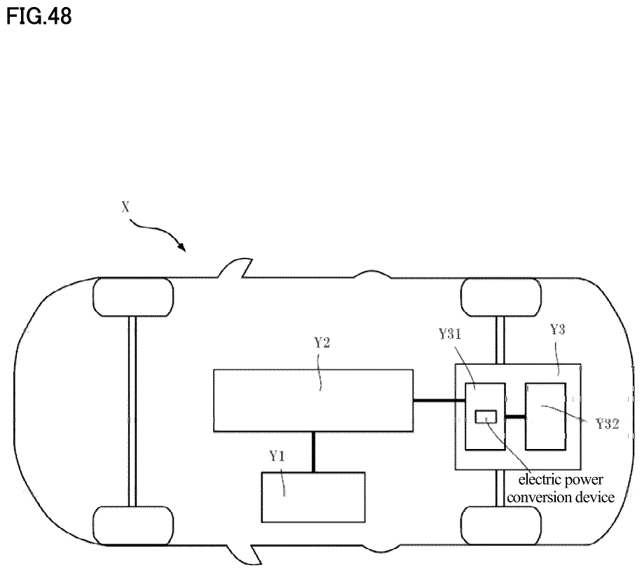

Next, with reference to FIG. 48, a vehicle X in which the electric power conversion device described above is mounted is described. The vehicle X is an electric vehicle (EV), for example.

As illustrated in FIG. 48, the vehicle X includes a vehicle-mounted charger Y1, a battery Y2, and a drive system Y3. The vehicle-mounted charger Y1 including the electric power conversion device is wirelessly fed with power from a power feeding facility (not shown) installed outdoors. Other than that, means for feeding the power from the power feeding facility to the vehicle-mounted charger Y1 may be a wired one. The vehicle-mounted charger Y1 is equipped with a step-up type DC-DC converter. The voltage of the power supplied to the vehicle-mounted charger Y1 is stepped up by the converter and then is fed to the battery Y2. The stepped-up voltage is 600 V, for example.

The drive system Y3 drives the vehicle X. The drive system Y3 includes an inverter Y31 and a drive source Y32. The electric power conversion device described above constitutes a part of the inverter Y31. The power stored in the battery Y2 is supplied to the inverter Y31. The power supplied from the battery Y2 to the inverter Y31 is a DC power. Other than that, unlike the power system illustrated in FIG. 48, it may be possible to provide another step-up type DC-DC converter between the battery Y2 and the inverter Y31. The inverter Y31 converts the DC power into an AC power. The inverter Y31 including the electric power conversion device is electrically connected to the drive source Y32. The drive source Y32 includes an AC motor and a transmission. When the AC power converted by the inverter Y31 is supplied to the drive source Y32, the AC motor rotates, and its rotation is transmitted to the transmission. The transmission appropriately reduces the rotational frequency transmitted from the AC motor, and rotate a drive shaft of the vehicle X. In this way, the vehicle X is driven. When driving the vehicle X, it is necessary to flexibly operate the rotational frequency of the AC motor on the basis of information such as a change amount of an accelerator pedal. Therefore, the electric power conversion device of the inverter Y31 described above is necessary for outputting AC power whose frequency is appropriately changed, so as to correspond to the required rotational frequency of the AC motor.

### Other Variations

Note that the various technical features disclosed in this specification can be variously modified within the scope of the technical creation without deviating from the spirit thereof, other than the embodiments and structure examples described above. In other words, the embodiments and the structure examples described above are merely examples and should not be interpreted as limitations. The technical scope of the present disclosure is defined by the claims, and should be understood to include all modifications within meaning and scope equivalent to the claims.

### Note 1

A gate drive circuit comprising:
a gate driving circuit configured to generate a gate drive signal for a power device; and
a drive capability switching circuit configured to stepwisely increase gate drive capability of the gate driving circuit, during at least one of a turn-off transition period and a turn-on transition period of the power device.

### Note 2

The gate drive circuit according to Note 1, wherein the drive capability switching circuit includes a comparator configured to compare an inter-terminal voltage between main terminals of the power device with a predetermined threshold voltage, so as to generate a comparison signal, and a switch configured to switch the gate drive capability according to the comparison signal.

### Note 3

The gate drive circuit according to Note 2, wherein the threshold voltage is a variable value.

### Note 4

The gate drive circuit according to Note 1, wherein the drive capability switching circuit includes a comparator configured to compare an inter-terminal voltage between a control terminal and a main terminal of the power device with a predetermined threshold voltage, so as to generate the comparison signal, a latch configured to receive input of the comparison signal so as to generate a latch signal, and a switch configured to switch the gate drive capability according to the latch signal.

### Note 5

The gate drive circuit according to Note 1, wherein the drive capability switching circuit includes a timer configured to generate a timer signal that changes its logic level when a predetermined time has elapsed after at least one of turn-off timing and turn-on timing of the power device, and a switch configured to switch the gate drive capability according to the timer signal.

### Note 6

The gate drive circuit according to any one of Notes 2 to 5, wherein the drive capability switching circuit further includes a gate resistor, so that the switch switches a resistance value of the gate resistor.

### Note 7

The gate drive circuit according to any one of Notes 2 to 6, wherein the drive capability switching circuit further includes a gate capacitance, so that the switch switches between connection and disconnection of the gate capacitance.

### Note 8

The gate drive circuit according to any one of Notes 2 to 7, wherein the drive capability switching circuit further includes a DC voltage source configured to generate a negative potential lower than a reference potential, so that the switch switches the off potential of the gate drive signal between the negative potential and the reference potential.

### Note 9

The gate drive circuit according to any one of Notes 1 to 8, wherein the drive capability switching circuit decreases the gate drive capability from a first gate drive capability to a second gate drive capability during at least one of the turn-off transition period and the turn-on transition period of the power device, and afterward increases the same from the second gate drive capability to the first gate drive capability again.

### Note 10

An electric power conversion device comprising:
a power module configured to include at least one said power device; and
the gate drive circuit according to any one of Notes 1 to 9.

### Note 11

The electric power conversion device according to Note 10, wherein the power module includes a plurality of the power devices connected in parallel to each other.

### Note 12

The electric power conversion device according to Note 11, comprising an external control terminal electrically connected to control terminals of the plurality of power devices, wherein
control wiring lengths, which are connection path lengths between the external control terminal and the control terminals of the plurality of power devices, are different from each other.

### Note 13

The electric power conversion device according to Note 11 or 12, wherein current flowing between the main terminals of each of the power devices is 10 A or more and 300 A or less.

### Note 14

The electric power conversion device according to any one of Notes 11 to 13, wherein the power device is a MISFET including an SiC substrate.

### Note 15

The electric power conversion device according to any one of Notes 11 to 13, wherein the power device is an IGBT.

### Note 16

The electric power conversion device according to any one of Notes 11 to 15, wherein the power device has a withstand voltage of 100 V or more and 3,500 V or less.

### Note 17

The electric power conversion device according to any one of Notes 11 to 16, wherein the power device has a switching frequency of 1 Hz or more and 1,000 kHz or less.

### Note 18

The electric power conversion device according to any one of Notes 11 to 17, wherein a current change amount per unit time of current flowing between the main terminals during turn on/off is 0.1 A/ns or more and 30 A/ns or less.

### Note 19

The electric power conversion device according to any one of Notes 11 to 18, wherein a voltage change amount per unit time of voltage between the main terminals during turn on/off is 10 V/ns or more and 150 V/ns or less.

### Note 20

A vehicle comprising:
a drive source; and
the electric power conversion device according to any one of Notes 10 to 19, wherein the electric power conversion device is electrically connected to the drive source.

### Note 21

The electric power conversion device according to any one of Notes 11 to 13, wherein the power device has a single trench structure.

### Note 22

The electric power conversion device according to any one of Notes 11 to 13, wherein the power device has a planer structure.

According to the present disclosure, it is possible to provide a gate drive circuit that can suppress switching oscillation, and an electric power conversion device using the same.

1. A gate drive circuit comprising:
a gate driving circuit configured to generate a gate drive signal for a power device; and
a drive capability switching circuit configured to stepwisely increase gate drive capability of the gate driving circuit, during at least one of a turn-off transition period and a turn-on transition period of the power device.

2. The gate drive circuit according to claim 1, wherein the drive capability switching circuit includes a comparator configured to compare an inter-terminal voltage between main terminals of the power device with a predetermined threshold voltage, so as to generate a comparison signal, and a switch configured to switch the gate drive capability according to the comparison signal.

3. The gate drive circuit according to claim 2, wherein the threshold voltage is a variable value.

4. The gate drive circuit according to claim 1, wherein the drive capability switching circuit includes a comparator configured to compare an inter-terminal voltage between a control terminal and a main terminal of the power device with a predetermined threshold voltage, so as to generate the comparison signal, a latch configured to receive input of the comparison signal so as to generate a latch signal, and a switch configured to switch the gate drive capability according to the latch signal.

5. The gate drive circuit according to claim 1, wherein the drive capability switching circuit includes a timer configured to generate a timer signal that changes its logic level when a predetermined time has elapsed after at least one of turn-off timing and turn-on timing of the power device, and a switch configured to switch the gate drive capability according to the timer signal.

6. The gate drive circuit according to claim 2, wherein the drive capability switching circuit further includes a gate resistor, so that the switch switches a resistance value of the gate resistor.

7. The gate drive circuit according to claim 2, wherein the drive capability switching circuit further includes a gate capacitance, so that the switch switches between connection and disconnection of the gate capacitance.

8. The gate drive circuit according to claim 2, wherein the drive capability switching circuit further includes a DC voltage source configured to generate a negative potential lower than a reference potential, so that the switch switches the off potential of the gate drive signal between the negative potential and the reference potential.

9. The gate drive circuit according to claim 1, wherein the drive capability switching circuit decreases the gate drive capability from a first gate drive capability to a second gate drive capability during at least one of the turn-off transition period and the turn-on transition period of the power device, and afterward increases the same from the second gate drive capability to the first gate drive capability again.

10. An electric power conversion device comprising:
a power module configured to include at least one said power device; and
the gate drive circuit according to claim 1.

11. The electric power conversion device according to claim 10, wherein the power module includes a plurality of the power devices connected in parallel to each other.

12. The electric power conversion device according to claim 11, comprising an external control terminal electrically connected to control terminals of the plurality of power devices, wherein
control wiring lengths, which are connection path lengths between the external control terminal and the control terminals of the plurality of power devices, are different from each other.

13. The electric power conversion device according to claim 11, wherein current flowing between the main terminals of each of the power devices is 10 A or more and 300 A or less.

14. The electric power conversion device according to claim 11, wherein the power device is a MISFET including an SiC substrate.

15. The electric power conversion device according to claim 11, wherein the power device is an IGBT.

16. The electric power conversion device according to claim 11, wherein the power device has a withstand voltage of 100 V or more and 3,500 V or less.

17. The electric power conversion device according to claim 11, wherein the power device has a switching frequency of 1 Hz or more and 1,000 kHz or less.

18. The electric power conversion device according to claim 11, wherein a current change amount per unit time of current flowing between the main terminals during turn on/off is 0.1 A/ns or more and 30 A/ns or less.

19. The electric power conversion device according to claim 11, wherein a voltage change amount per unit time of voltage between the main terminals during turn on/off is 10 V/ns or more and 150 V/ns or less.

20. A vehicle comprising:
a drive source; and
the electric power conversion device according to claim 10, wherein
the electric power conversion device is electrically connected to the drive source.
